(19) United States
(12) Patent Application Publication
(10) Pub. No.: US 2013/0215683 A1
(43) Pub. Date: Aug. 22, 2013

(54) Three-Dimensional Flash-Based Combo Memory and Logic Design

(71) Applicants: Peter Wung Lee, Saratoga, CA (US); Hsing-Ya Tsao, San Jose, CA (US)

(72) Inventors: Peter Wung Lee, Saratoga, CA (US); Hsing-Ya Tsao, San Jose, CA (US)

(73) Assignee: APLUS FLASH TECHNOLOGY, INC., San Jose, CA (US)

(21) Appl. No.: 13/586,451

(22) Filed: Aug. 15, 2012

Related U.S. Application Data
(60) Provisional application No. 61/575,126, filed on Aug. 15, 2011.

(51) Int. Cl. G11C 16/04; H01L 27/088

(52) U.S. Cl. CPC G11C 16/0466; H01L 27/088
USPC 365/185.29; 257/205

(57) ABSTRACT

A three-dimensional NAND-based NOR nonvolatile memory cell has two three-dimensional SONOS-type charge-retaining transistors arranged in a series string such that one of the charge-retaining transistors functions as a select gate transistor to prevent leakage current through the charge-retaining transistors when the charge-retaining transistors is not selected for determining a data state of the three-dimensional NAND-based NOR nonvolatile memory cell. The first charge retaining transistor's drain is connected to a bit line parallel to the charge retaining transistors and the second charge retaining transistor's source is connected to a source line and is parallel to the bit line. The three-dimensional NAND-based NOR nonvolatile memory cell may be reconfigured to function as a PLD cell, an FPGA switching cell, and an EEPROM cell

This application claims priority under 35 U.S.C. §119 to U.S. Provisional Patent Application U.S. Provisional Patent Application Ser. 61/575,126, filed on Aug. 15, 2011, assigned to the same assignee as the present disclosure, and incorporated herein by reference in its entirety.

### TECHNICAL FIELD

This disclosure relates generally to nonvolatile memory and programmable logic array structures and operation. More particularly, this disclosure relates to a NAND based NOR flash nonvolatile memory circuit and array structure and operation and a NAND based NOR flash nonvolatile programmable logic circuit and array and operation. Even more particularly, this disclosure relates to a NAND based NOR flash nonvolatile memory circuit and array structure and operation and a NAND based NOR flash nonvolatile programmable logic circuit and array and operation formed three-dimensionally on a substrate.

### BACKGROUND

Nonvolatile memory is well known in the art. The different types of nonvolatile memory cells and cell arrays include the Read-Only-Memory (ROM), Electrically Programmable Read Only Memory (EPROM), Electrically Erasable Programmable Read Only Memory (EEPROM), NOR Flash Memory, and NAND Flash Memories and nonvolatile programmable logic circuits that includes the programmable logic devices (PLD) for regular “AND” and “OR” arrays and the low-resistance switch clusters for the field programmable gate array (FPGA) fast connection applications.

In current applications such as personal digital assistants, cellular telephones, notebook and laptop computers, voice recorders, global positioning systems, etc., the two-dimensional NAND-based Flash Memory and Logic has become one of the more popular types of nonvolatile memory. This market requires an extremely high density that approaches 256 Gb on a single die that has a size of approximately 100 mm². When the density-level requirement exceeds 1 Tb for instance in a Disk Drive storage with an acceptable die size and cost, the small die size of 3-dimensional Flash Memory and Logic is becoming the trend. This provides the combined advantages of the extremely high density of more than 1 Tb, extremely small silicon area, low cost, and repeated programmability and erasability. Further, the technology will allow a single low-voltage power supply voltage source of approximately 1.2V without any on-chip high current voltage boosting circuits. This allows the full integration of flash memory and flash-based combination system on chip (SOC) designs. This has a large advantage for the future mobile integrated circuit design.

There are two kinds of two-dimensional planar storage mechanisms for today's Flash Memory cell and Flash-based Logic cells. The storage structures known in the art employ a charge-retaining mechanism such as a double-polycrystalline silicon floating-gate type charge storage and a single-polycrystalline silicon charge-trapping type storage. The charge storage mechanism, as with a floating gate nonvolatile memory, the charge representing digital data is stored on a floating gate of the device. The stored charge modifies the threshold voltage of the floating gate memory cell determine that digital data stored. In a charge-trapping mechanism, as in a Silicon-Oxide-Nitride-Oxide-Silicon (SONOS) or Metal-Oxide-Nitride-Oxide-Silicon (MONOS) type cell, the charge is trapped in a charge-trapping layer between two insulating layers. The charge-trapping layer in the SONOS/MONOS devices has a relatively high dielectric constant (k) such Silicon Nitride (SiNₓ).

FIGS. 1a-1e, 2a-2b, 3, and 4 describes the structure of U.S. Pat. Nos. 7,940,573 and 7,940,574 (Masuoka, et al.). Masuoka et al. provides a 3D NOR-type nonvolatile semiconductor memory cell and array that can inject electric charge into a charge accumulation layer through the use of an FN tunnel current. FIG. 1a is a top plan layout view of single one-transistor/one-bit three-dimensional NMOS NOR flash transistor 100 of the prior art. The three-dimensional NMOS NOR flash transistor 100 is formed as a cylindrical doped silicon structure. The source is an N+ active diffusion layer 3 formed on a source line SL that is an N+ active diffusion layer 2 within the surface of the substrate 1 and connected to column control circuitry. The bulk is formed of the P− diffusion layer 4 that is formed immediately above the source N+ active diffusion 3. The drain is then formed immediately above as a second N+ active diffusion layer 5 on the bulk P− diffusion layer 4. An insulating SONOS layer 6 is formed to surround the bulk is formed of the P− diffusion layer 4 with a polycrystalline silicon layer 7 forming the control gate and is merged with the word line WL as a polycrystalline layer extending from row control circuitry.

A metal layer 13 is the bit line BL that is placed on top of the three-dimensional NMOS NOR flash transistor 100 to connect to the drain N+ active diffusion layer 5. The bit line BL is connected to the column control circuitry (not shown). The three-dimensional NMOS NOR flash transistor 100 is structured to store a single bit and is referred as one-transistor/one-bit NOR cell.

FIG. 1b is a schematic diagram of single 3D NMOS NOR flash transistor 100 in accordance with the layout shown in FIG. 1a of the prior art. The three-dimensional NMOS NOR flash transistor 100 has four terminals that include the top drain node connected to a bit line BL, the bottom source node connected to the source line SL, the middle gate node connected to a word line WL, and the bulk of P-substrate unseen for simpler circuit description. The flash cell can be made of either as a double poly-crystalline floating-gate charge storing transistor or a single poly-crystalline charge-trapping transistor.

FIG. 1c is a 3D cross sectional view of single one-transistor/one-bit three-dimensional NMOS NOR flash transistor 100 in 1c-1c′ axis shown in FIG. 1a. The three-dimensional NMOS NOR flash transistor 100 can be divided into three portions the top drain N+ active layer 5 and the bottom source N+ active diffusion layer 3, the bulk is a P− cylinder 4 formed between the top drain N+ active diffusion layer 5 and the bottom source N+ active diffusion layer 3. The polycrystalline silicon region 7 is the control gate of the flash transistor 100 that surrounds the vertical P− silicon cylinder between the top N+ active diffusion layer 5 to the bottom N+ active layer 3.

FIG. 1d is a cross sectional view of single one-transistor/one-bit 3D NMOS NOR flash transistor 100 shown in 1d-1d′ axis in FIG. 1a. The bottom source N+ active layer 3 is placed on top of the diffusion 2 that forms the local source line SL. The top drain N+ active diffusion layer 5 is connected to the metal line 13 that forms the bit line BL. The SONOS charge-trapping layer 6 is formed between the floating P− silicon cylinder 4 and the polycrystalline control gate 7. The polycrystalline control gate 7 is connected to the word line WL that is driven by a row-decoder (not shown).

FIGS. 1e and 1f are respectively a cross sectional view and a top plan view of a 3D switching transistor 105 of the prior art. The bottom source N+ active layer 8 is connected to a diffusion layer 2 to form the local source line SL. A bulk region is a P− silicon cylinder 9 formed on the bottom source N+ active diffusion layer 8. An N+ active diffusion layer 10 is formed on the bulk region P− silicon cylinder 9 to make the drain. The drain N+ active layer 10 is connected to metal layer 12 is the common source line CSL that connected to the row decoder. A polycrystalline cylindrical ring 11 is formed around the bulk P− silicon cylinder 9 to create a gate for the 3D switching transistor 105. The activating of the 3D switching transistor 105 is controlled by activation signal R connected to the polycrystalline cylindrical ring 11.

FIG. 2a is a top plan layout view of a 3D one-transistor/one-bit NMOS NOR flash memory cell array of the prior art. FIGS. 2b and 2c cross sectional views of the 3D one-transistor/one-bit NMOS NOR flash memory cell array of FIG. 2a of the prior art. FIG. 3 is a schematic of a 3D one-transistor/one-bit NMOS NOR flash memory cell array of FIG. 2a of the prior art. Multiple single one-transistor/one-bit 3D NMOS NOR flash transistors 100 are arranged in rows and columns. On each row of the one-transistor/one-bit 3D NMOS NOR flash transistors 100, the polycrystalline control gate 7 is connected to one of the polycrystalline word lines WL0-n, WL1-0, WL1-1, WL1-n, WL1-0, . . . . On each column transistor/one-bit 3D NMOS NOR flash transistors 100, the top drain N+ active diffusion layer 5 of each of the one-transistor/one-bit 3D NMOS NOR flash transistors 100 on each column is connected to one of the metal bit lines BL0, BL1, . . . , BLn. Similarly on each column of the one-transistor/one-bit 3D NMOS NOR flash transistors 100, the bottom source N+ active layer 3 are connected to the source line diffusion layer 2.

The array of the one-transistor/one-bit 3D NMOS NOR flash transistors 100 includes two rows of switching transistors 105. One of the switching transistors 105 on each row of the two rows of switching transistors 105 has its source diffusion 8 connected to the source line diffusion area associated with each column of the one-transistor/one-bit 3D NMOS NOR flash transistors 100. The drain diffusion 10 of the switching transistors 100 is connected to a metal common source diffusion line CSL. The polycrystalline silicon gate 11 of each of the switching transistors 105 is connected to the activation signal R.

FIG. 3 is a table detailing bias voltage conditions for operating an array of the one-transistor/one-bit 3D NMOS NOR flash transistors 100 for Reading, Programming and Erasing. It will be noted that in a read operation, a read voltage level of approximately 3.0V is applied to the selected word line WL and a read biasing voltage level of approximately 0.5V is applied to the selected bit line BL. The selected and unselected source line SL is set to the voltage level of the ground reference voltage level (0.0V) by activating the switching transistors 105 to connect the common source lines CSL to the source line SL. The common source line CSL is set to the ground reference voltage level and the activation signal R is set to an activation voltage level of approximately 3.0V.

In a program of a page of an array, a very large programming voltage of approximately 18.0V is applied to the word line WL of the selected page. The ground reference voltage level is applied to the unselected word lines WL of the unselected pages of the array. The activation signal R is set to the ground reference voltage level (0.0V) to prevent the common source line CSL from being connected to the source lines SL. The common source line CSL is set to a common source line program voltage level of approximately 4.5V. The program inhibit voltage level of 9.0V is applied to the bit lines BL and is coupled to the source lines SL of the unselected 3D NMOS NOR flash transistors 100. The ground reference voltage level is applied to the bit lines BL and coupled to the source lines SL of the selected 3D NMOS NOR flash transistors 100 to initiate a Fowler-Nordheim tunneling phenomenon to program the selected 3D NMOS NOR flash transistors 100.

In a mass or total erase of an array of the 3D NMOS NOR flash transistors 100, all the word lines are connected to the ground reference voltage level (0.0V). The common source line CSL and the activate signal R are set to the very large positive erase voltage level of 18.0V. This couples the very large positive erase voltage level of 18.0V to the source lines SL. The very large positive erase voltage level of 18.0V is transferred to all the bit lines BL. The Fowler-Nordheim tunneling phenomenon is initiated to remove the electrical charges from the 3D NMOS NOR flash transistors 100.

When the 3D NMOS NOR flash transistors 100 on one word line WL are selected to be erased, the selected word line WL has the ground reference voltage level (0.0V) applied to it. An erase inhibit voltage of 9.0V is applied to the unselected word lines WL. The common source line CSL and the activate signal R are set to the very large positive erase voltage level of 18.0V. This couples the very large positive erase voltage level of 18.0V to the source lines SL. The very large positive erase voltage level of 18.0V is transferred to all the bit lines BL. The Fowler-Nordheim tunneling phenomenon is initiated to remove the electrical charges from the 3D NMOS NOR flash transistors 100 of the selected word line WL.

When one column of the 3D NMOS NOR flash transistors 100 is selected to be erased, all the word lines WL have the ground reference voltage level (0.0V) applied to it. An erase inhibit voltage of 9.0V is applied to the unselected bit lines BL. The common source line CSL is set to an intermediate erase voltage level of approximately 13.5V. The activate signal R are set to the erase inhibit voltage. This couples the erase inhibit voltage to the unselected source lines SL. The very large positive erase voltage level of 18.0V is transferred to the selected bit line BL and source lines SL. The Fowler-Nordheim tunneling phenomenon is initiated to remove the electrical charges from the 3D NMOS NOR flash transistors 100 of the selected bit line BL.

When selected single 3D NMOS NOR flash transistors 100 are selected to be erased, the word lines WL of the selected 3D NMOS NOR flash transistors 100 have the ground reference voltage level (0.0V) applied to it. The erase inhibit voltage is applied to the word lines WL of the unselected 3D NMOS NOR flash transistors 100 and to the unselected bit lines BL. The common source line CSL is set to an intermediate erase voltage level of approximately 13.5V. The activate signal R are set to the erase inhibit voltage. This couples the erase inhibit voltage to the unselected source lines SL. The very large positive erase voltage level of 18.0V is transferred to the selected bit line BL and is coupled to the selected source lines SL. The Fowler-Nordheim tunneling phenomenon is initiated to remove the electrical charges from the selected 3D NMOS NOR flash transistors 100 of the selected bit line BL.

### SUMMARY

An object of this application is to provide a very compact three-dimensional one level polycrystalline silicon, charge-trapping, SONGS-type, three-dimensional NAND-based NOR nonvolatile memory cell for constructing very high density nonvolatile memory arrays. Each three-dimensional a three-dimensional NAND-based NOR nonvolatile memory cell consists of two highly scalable three-dimensional SONOS-type charge-retaining transistors connected in series employing three-dimensional low-current NAND-based. NOR cell structure and operation. The three-dimensional two-transistor/two-bit NOR cell is arranged in a series string such that one of the charge-retaining transistors functions as a select gate transistor to prevent leakage current through the charge-retaining transistors when the charge-retaining transistors is not selected for determining a data state of the three-dimensional NAND-based NOR nonvolatile memory cell. The preferable threshold voltage levels Vt1 and Vt0 are chosen to totally eliminate the long-held over-erase concern and achieve a factor of ten faster write speed over the traditional one transistor/one bit NOR flash array.

In various embodiments of the three-dimensional charge-retaining transistors, the first voltage threshold level (Vt1) is approximately +1.0V and second voltage threshold (Vt0) is approximately −2.0V for each three-dimensional two-transistor/two-bit NOR flash cells. These voltage levels achieve the faster and lower power-consumption of the NOR operation with a power supply voltage level (VDD) that is at or below 1.5V. With a power supply voltage level less than or equal to the 1.5V, an on-chip voltage boost generation circuit is not required to generate the selected word line voltages higher than the power supply voltage source.

In some embodiments of this application, a compact one level polycrystalline silicon, charge-trapping, SONOS-type, a three-dimensional NAND-based NOR nonvolatile memory cell array is constructed of a three-dimensional NAND-based NOR nonvolatile memory cell arrange in rows and columns. Each column of the a three-dimensional NAND-based NOR nonvolatile memory cell has with a local bit line and a local source line formed as two parallel N+ active layers diffused below each of the three-dimensional charge-retaining transistors of the NAND-based NOR cell. A source of a first of the two three-dimensional charge-retaining transistors is connected to a second of the two three-dimensional charge-retaining transistors to connect the two three-dimensional charge-retaining transistors in series. The two three-dimensional charge-retaining transistors are offset from one another such that the first three-dimensional charge-retaining transistor is placed above the local bit line and the second three-dimensional charge-retaining transistor is placed above the local source line. The control gates of the two series connected three-dimensional charge-retaining transistors are each coupled to one of two paired word lines that are associated with a row of the NAND-based NOR cells. The control gates polycrystalline silicon formed to be connected with each of the three-dimensional charge-retaining transistors.

In various embodiments, a write flow achieves a fast program and erase operation by setting the values of the first threshold voltage level (Vt0) and the second threshold voltage level (Vt1) to eliminate and over-erase and bit line punch-through the two-transistor/two-bit three-dimensional NAND-based NOR cell array. In some embodiments, the first threshold voltage level (Vt0) is the programmed voltage level and the second threshold voltage level (Vt1) is the erased voltage level. To program the selected row of charge-retaining transistors of two-transistor/two-bit three-dimensional NAND-based NOR cells on a row of the array, the word line attached to the selected row of three-dimensional charge-retaining transistors is set to a very large programming voltage level of approximately 18.0V. The word line connected to the unselected three-dimensional charge-retaining transistors of the selected row of the two-transistor/two-bit three-dimensional NAND-based NOR cells is set to a charge-retaining transistor activation voltage level of approximately 4.5V. The paired word lines of the unselected two-transistor/two-bit three-dimensional NAND-based NOR cells on a row of the array are set to the charge-retaining transistor activation voltage level. The bit lines and source lines of the selected charge-retaining transistors are set to the ground reference voltage level (0.0V). The bit lines and the source lines of the unselected charge-retaining transistors are set to a programming inhibit voltage level of approximately (9.0V).

To erase the two-transistor/two-bit three-dimensional NAND-based NOR cells on a row of the array, the paired word lines of the charge-retaining transistors of the two-transistor/two-bit three-dimensional NAND-based NOR cells are set to the ground reference voltage level (0.0V). The unselected row paired word lines of the two-transistor/two-bit three-dimensional NAND-based NOR cells are set to an erase inhibit voltage level of approximately 9.0V. The bit lines and the source lines of the two-transistor/two-bit three-dimensional NAND-based NOR cells on a row of the array are set to a very large erase voltage level of approximately 18.0V.

In other embodiments, the first threshold voltage-level (Vt0) is the erased voltage level and the second threshold voltage level (Vt1) is the programmed voltage level. To program the selected row of charge-retaining transistors of two-transistor/two-bit three-dimensional NAND-based NOR cells on a row of the array, the word line attached to the selected row of three-dimensional charge-retaining transistors is set to the ground reference voltage level (0.0V). The word line connected to the unselected three-dimensional charge-retaining transistors of the selected row of the two-transistor/two-bit three-dimensional NAND-based NOR cells is set to a charge-retaining transistor activation voltage level of approximately 9.0V. The paired word lines of the unselected two-transistor/two-bit three-dimensional NAND-based NOR cells on a row of the array are set to the charge-retaining transistor activation voltage level. The bit lines and source lines of the selected charge-retaining transistors are set to the a very large programming voltage level of approximately 18.0V. The bit lines and the source lines of the unselected charge-retaining transistors are set to the ground reference voltage level.

To erase the two-transistor/two-bit three-dimensional NAND-based NOR cells of the entire array, the paired word lines of the charge-retaining transistors of the two-transistor/two-bit three-dimensional NAND-based NOR cells are set to a very large erase voltage level of approximately 18.0V. The bit lines and the source lines of the two-transistor/two-bit three-dimensional NAND-based NOR cells on a row of the array are set to the ground reference voltage level (0.0V).

Another object of this application is to provide a very compact three-dimensional single level polycrystalline silicon, charge-retaining, three-transistor/one-bit EEPROM cell for constructing very high density multi-gigabit nonvolatile memory arrays. Each three-dimensional three-transistor/one-bit EEPROM cell consists of one highly scalable three-dimensional charge-retaining transistor with storage capability and two three-dimensional regular high voltage NMOS gating transistors connected in series with the charge-retaining transistor. In various embodiments a first threshold voltage level (Vt0) is the program threshold voltage level and has a voltage value of approximately −2.0V. The second threshold voltage level (Vt1) is the erase threshold voltage level and has a voltage value of approximately value of approximately +3.0V. With the charge-retaining transistor in series between the two gating transistors, the three-transistor/one-bit EEPROM cell has no over-erase concern. This allows a fast erase and program to be achieved within 1 mS to meet the EEPROM write specifications of current EEPROM cells.

In some embodiments of this application, a very compact one level polycrystalline silicon, charge-retaining, three-dimensional EEPROM cell array constructed of three-transistor/one-bit three-dimensional EEPROM cells arranged in rows and columns. Local bit lines and local source lines are formed parallel with their associated columns of the three-dimensional EEPROM cells. The local bit lines and the local source lines are N+ active layers diffused in the surface of the substrate under the charge-retaining transistor and the two three-dimensional high voltage NMOS gating transistors.

The drain of a first of the two gating transistors is connected to a local bit line diffusion that is connected to the drain of the three-dimensional charge-retaining transistor. The source of a second of the two gating transistors is connected to the local source line diffusion that connects to the source of the three-dimensional charge-retaining transistor. The source of the second gating transistors is connected to a metal source line formed in a superior position to the second gating transistor. The gates of the two gating transistors are connected to a selected gating line. The select gating line is a first polycrystalline silicon layer formed parallel with each row of the three-dimensional EEPROM cells. The control gate of the three-dimensional charge-retaining transistors on each row of is connected to a word line. The word line for each row of the three-dimensional charge-retaining transistors is formed of a second polycrystalline silicon layer placed parallel to the associated row of the three-dimensional charge-retaining transistors.

In various embodiments, a write operation achieves a fast program and erase by setting the values of the first threshold voltage level (Vt0) and the second threshold voltage level (Vt1) to eliminate an over-erase and bit line punch-through the three-transistor/one-bit three-dimensional EEPROM array. The first threshold voltage level (Vt0) is the programmed voltage level and the second threshold voltage level (Vt1) is the erased voltage level. To program the selected row of charge-retaining transistors of three-transistor/one-bit three-dimensional EEPROM cells on a row of the array, the ground reference voltage level (0.0V) is applied to the global bit line(s) of the selected and unselected sub-array block(s). The select gating line(s) for the selected sub-array block(s) have a select gating voltage level that is applied to the word line biasing transistor and the gates of the first and second three-dimensional switching transistors. The word line biasing transistor(s) is activated to apply the ground reference voltage level (0.0V) to the word lines, and thus to the gates of the charge-retaining transistors of the selected three-transistor/one-bit three-dimensional EEPROM cells. The select gating biasing voltage level is approximately 18.0V.

The bit lines, and source lines, of the selected sub-array block(s) are all set to the very large programming voltage level to initiate a Fowler-Nordheim Tunneling phenomenon to extract negative charges from the insulating SONOS layer of the charge-retaining transistor shown to decrease the threshold voltage level of the selected three-transistor/one-bit three-dimensional EEPROM cells to the programmed threshold voltage level (Vt0) that is approximately −1.5V. In various embodiments, the bit lines of the selected sub-array block(s) are all set to the very large programming voltage level. The source lines of the selected sub-array block(s) are disconnected and allowed to float or are set to the ground reference voltage level (0.0V) to initiate a hot carrier (hole) injection phenomenon to extract negative charges from the insulating SONOS layer of the charge-retaining transistor. In other embodiments, the source lines of the selected sub-array block(s) are all set to the very large programming voltage level. The bit lines of the selected sub-array block(s) are disconnected and allowed to float or set to the ground reference voltage level (0.0V) to initiate a hot carrier (hole) injection phenomenon to extract negative charges from the insulating SONOS layer of the charge-retaining transistor. The unselected bit lines and source lines of the selected sub-array block(s) are set to the ground reference voltage level (0.0V) to inhibit programming the unselected three-transistor/one-bit three-dimensional EEPROM cells. The very large programming voltage level is approximately 18.0V.

To erase a selected row containing a byte or page of charge-retaining transistors of three-transistor/one-bit three-dimensional EEPROM cells or an entire chip of charge-retaining transistors of three-transistor/one-bit three-dimensional EEPROM cells, a very large erasing voltage level is applied to the global bit line(s) of the array or selected sub-array block(s). The very large erasing voltage level is approximately 18.0V. The select gating line(s) for the selected sub-array block(s) have a select gating voltage level that is applied to the gate of the word line biasing transistor and to the gates of the first and second three-dimensional switching transistors. The word line biasing transistor(s) is activated to apply the very large erasing voltage level to the word lines and thus to the gates of the charge-retaining transistors of the selected three-transistor/one-bit three-dimensional EEPROM cells. The select gating biasing voltage level is approximately 18.0V. The global bit line(s) of the unselected sub-array blocks are set to the ground reference voltage level (0.0V) to deactivate the word line biasing transistor to inhibit erasure.

The bit lines and source lines are all set to the ground reference voltage level (0.0 v) to initiate a Fowler-Nordheim Tunneling phenomenon to attract negative charges to the insulating SONOS layer of the charge-retaining transistor to increase the threshold voltage level of the selected three-transistor/one-bit three-dimensional EEPROM cells to the erased threshold voltage level Vt1 that is approximately 2.0V. If the entire array of three-transistor/one-bit three-dimensional EEPROM cells is to be erased, there are no unselected global bit lines, bit lines or source lines.

Further another object of this application is to provide a very compact three-dimensional, single level polycrystalline silicon, charge-trapping, two transistor/two-bit, NAND-based programmed logic device (PLD) circuit for constructing very high density nonvolatile PLD arrays. Each three-dimensional two transistor/two-bit NAND-based PLD cell consists of two highly scalable three-dimensional SONOS-type charge-retaining transistors connected in series employing a three-dimensional low-current NAND-based PLD cell that is similar in structure and operation to the NAND-based NOR nonvolatile memory cell described above. The three-dimensional two-transistor/two-bit PLD cell is arranged in a series string such that the threshold voltage levels of each of the charge-retaining transistors of the three-dimensional two-transistor/two-bit PLD cell have complementary threshold voltage levels. The threshold voltage levels of each of the charge-retaining transistors of the three-dimensional two-transistor/two-bit PLD cell are selected such that the first threshold voltage level (Vt0) is set to be less than approximately −1.0V and the second threshold voltage level (Vt1) is set to be approximately 0.7V.

In a logic operation the threshold voltage levels of each of the charge-retaining transistors of the three-dimensional two-transistor/two-bit PLD cell are programmed to be complementary such that if one of the charge-retaining transistors is the first threshold voltage value (Vt0), the other charge-retaining transistor is programmed to the second threshold voltage level (Vt1). Each three-dimensional two-transistor/two-bit PLD cell has two inputs that are coupled to two complementary logic input signals I[N] and I[NB].

In various embodiments, an array is formed of rows and columns of the three-dimensional two-transistor/two-bit PLD cells. Each column of the three-dimensional two-transistor/two-bit PLD cells is associated and parallel with a local bit line and a local source line. The local bit lines and a local source lines are formed as two parallel N+ diffusion layer below each column of the three-dimensional two-transistor/two-bit PLD cells. The source of one of the charge-retaining transistors is connected to the drain of a second of the charge-retaining transistors with a local metal layer above the top surface of the charge-retaining transistors of each of the three-dimensional two-transistor/two-bit PLD cells of the array. The two gates of each of the charge-retaining transistors of each of the three-dimensional two-transistor/two-bit PLD cells are coupled to two adjacent paired word lines associated with a row of the three-dimensional two-transistor/two-bit PLD cell. Each of the paired word lines is formed of a single polycrystalline conductor connected to row decoding circuitry for controlling selection of a row of the charge-retaining transistors of the three-dimensional two-transistor/two-bit PLD cells.

In a various embodiments, a write operation achieves a fast program and erase by setting the values of the first threshold voltage level (Vt0) and the second threshold voltage level (Vt1) to eliminate an over-erase and bit line punch-through of the three-dimensional two-transistor/two-bit PLD cell. The first threshold voltage level (Vt0) is the erased voltage level and the second threshold voltage level (Vt1) is the programmed voltage level. The write process begins with a pre-program operation where the entire array of the three-dimensional two-transistor/two-bit PLD cells is programmed to have their threshold voltage levels established at greater than the second threshold or programmed threshold voltage level. To accomplish this, the word lines of the array are placed at the very large positive program voltage and the local source lines and the local bit lines are set to the ground reference voltage level (0.0V). This initiates the Fowler-Nordheim tunneling phenomenon to attract negative charges to the charge-trapping region of the charge-trapping transistors of the three-dimensional two-transistor/two-bit PLD cells.

The write process continues with erasing the first charge-retaining transistors of all of the three-dimensional two-transistor/two-bit PLD cells. The word lines connected to the control gates of the first charge-retaining transistors of all the three-dimensional two-transistor/two-bit PLD cells of the array are set to the ground reference voltage level. The word lines connected to the second charge-retaining transistors of all of the three-dimensional two-transistor/two-bit PLD cells are set to an erase inhibit voltage level of approximately 9.0V. The local bit line and the local source lines are coupled to a very large positive erase voltage of approximately 18V. This initiates the Fowler-Nordheim tunneling phenomena to lower the threshold voltage level of the first charge-retaining transistors of all the three-dimensional two-transistor/two-bit PLD cells of the array to the first threshold voltage level (Vt0) to initiate the Fowler-Nordheim tunneling phenomena.

Selected first charge-retaining transistors of selected pages or rows of the three-dimensional two-transistor/two-bit PLD cells of the array are then programmed. In the page program process, the word lines connected to the selected page(s) are connected to a very large positive programming voltage level of approximately 18.0V. The word lines connected to the unselected pages or rows are connected to an intermediate positive program inhibit voltage level of approximately 9.0V. The unselected pages of the charge-retaining transistors include the unselected word line of the paired word lines of the selected three-dimensional two-transistor/two-bit PLD cells and the paired word lines of the unselected three-dimensional two-transistor/two-bit PLD cells. The local bit lines and the local source lines are set the ground reference voltage level (0.0V) to initiate the Fowler-Nordheim tunneling phenomena.

The write process continues with erasing the second charge-retaining transistors of all of the three-dimensional two-transistor/two-bit PLD cells. The word lines connected to the control gates of the second charge-retaining transistors of all the three-dimensional two-transistor/two-bit PLD cells of the array are set to the ground reference voltage level. The word lines connected to the first charge-retaining transistors of all of the three-dimensional two-transistor/two-bit PLD cells are set to an erase inhibit voltage level of approximately 9.0V. The local bit line and the local source lines are coupled to a very large positive erase voltage of approximately 18V. This initiates the Fowler-Nordheim tunneling phenomena to lower the threshold voltage level of the second charge-retaining transistors of all the three-dimensional two-transistor/two-bit PLD cells of the array to the second threshold voltage level (Vt0) to initiate the Fowler-Nordheim tunneling phenomena.

Selected second charge-retaining transistors of selected pages or rows of the three-dimensional two-transistor/two-bit PLD cells of the array are then programmed. In the page program process, the word lines connected to the selected page(s) are connected to a very large positive programming voltage level of approximately 18.0V. The word lines connected to the unselected pages or rows are connected to an intermediate positive program inhibit voltage level of approximately 9.0V. The unselected pages of the charge-retaining transistors include the unselected word line of the paired word lines of the selected three-dimensional two-transistor/two-bit PLD cells and the paired word lines of the unselected three-dimensional two-transistor/two-bit PLD cells. The local bit lines and the local source lines are set the ground reference voltage level (0.0V) to initiate the Fowler-Nordheim tunneling phenomena.

Another object of the present application is to provide a three-dimensional single level polycrystalline silicon, charge-trapping, SONOS-type, four-transistor/one-bit fast programmable switch cell for a low-resistance switching application for fast connections in an FPGA application. The four-transistor/one-bit cell comprises two three-dimensional charge-retaining transistors connected in a NAND-based series string. The control gate of the first charge-retaining transistor is connected to a primary input line to receive an in-phase logic input signal and the control gate of the second charge-retaining transistor is connected to an inverse primary input line to receive an out-of-phase input signal. The drain of a first of the charge-retaining transistors is connected to a write bit line and the source of a second of the charge-retaining transistors is connected to a write source line. The source of the first charge-retaining transistor and the drain of the second charge-retaining transistor are connected to a gate of a three-dimensional NMOS isolation transistor. The drain of the isolation transistor is connected to read word line that is connected to a gate of a three-dimensional NMOS low-resistance switch transistor. The drain of the low-resistance read transistor is connected to a read bit line and the source of the read transistor is connected to a read source line.

In a logic operation the threshold voltage levels of each of the charge-retaining transistors of the three-dimensional four-transistor/one-bit fast switch cell are programmed to be complementary such that if one of the charge-retaining transistors is the first threshold voltage value (Vt0), the other flash transistor's is programmed to the second threshold voltage level (Vt1). Each three-dimensional four-transistor/one-bit fast switch cell two inputs that are coupled to a primary input line and an inverse primary input line that provide two complementary input signals. The threshold voltage levels are chosen such that a first of the threshold voltage levels (Vt0) is negative with a voltage level of approximately −2.0V and a second threshold voltage level (Vt1) that is positive with a voltage level of approximately +1.0V.

The local write bit line and local source line are an N+ diffusion buried layers running in parallel with and beneath a column of the three-dimensional four-transistor/one-bit fast switch cells. The three-dimensional NMOS isolation transistor is placed as closely as possible to two charge-retaining transistors to form a very compact size of the three-dimensional four-transistor/one-bit fast switch cell.

In a various embodiments, a write operation achieves a fast program and erase by setting the values of the first threshold voltage level (Vt0) and the second threshold voltage level (Vt1) to eliminate an over-erase and bit line punch-through of the four-transistor/one-bit fast programmable switch cell. The first threshold voltage level (Vt0) is the erased voltage level and the second threshold voltage level (Vt1) is the programmed voltage level. The write process begins with a pre-program operation where the entire array of the four-transistor/one-bit fast programmable switch cell is programmed to have their threshold voltage levels established at greater than the second threshold or programmed threshold voltage level. To accomplish this, the primary input and inverse primary input lines of the array are placed at the very large positive program voltage and the local source lines and the local bit lines are set to the ground reference voltage level (0.0V). This initiates the Fowler-Nordheim tunneling phenomenon to attract negative charges to the charge-trapping region of the charge-trapping transistors of the four-transistor/one-bit fast programmable switch cell.

The write process continues with erasing the first charge-retaining transistors of all of the four-transistor/one-bit fast programmable switch cells. The primary input lines connected to the control gates of the first charge-retaining transistors of all the four-transistor/one-bit fast programmable switch cell of the array are set to the ground reference voltage level. The inverse primary input lines connected to the second charge-retaining transistors of all of the four-transistor/one-bit fast programmable switch cells are set to an erase inhibit voltage level of approximately 9.0V. The local bit line and the local source lines are coupled to a very large positive erase voltage of approximately 18V. This initiates the Fowler-Nordheim tunneling phenomena to lower the threshold voltage level of the first charge-retaining transistors of all the four-transistor/one-bit fast programmable switch cells of the array to the first threshold voltage level (Vt0) to initiate the Fowler-Nordheim tunneling phenomena.

Selected first charge-retaining transistors of selected pages or rows of the four-transistor/one-bit fast programmable switch cells of the array are then programmed. In the page program process, the primary input and inverse primary input lines connected to the selected page(s) are connected to a very large positive programming voltage level of approximately 18.0V. The primary input and inverse primary input lines connected to the unselected pages or rows are connected to an intermediate positive program inhibit voltage level of approximately 9.0V. The unselected pages of the charge-retaining transistors include the unselected word line of the paired word lines of the selected four-transistor/one-bit fast programmable switch cells and the paired word lines of the unselected three-dimensional two-transistor/two-bit PLD cells. The local bit lines and the local source lines are set the ground reference voltage level (0.0V) to initiate the Fowler-Nordheim tunneling phenomena.

The write process continues with erasing the second charge-retaining transistors of all of the four-transistor/one-bit fast programmable switch cells. The primary input and inverse primary input lines connected to the control gates of the second charge-retaining transistors of all the four-transistor/one-bit fast programmable switch cells of the array are set to the ground reference voltage level. The primary input and inverse primary input lines connected to the first charge-retaining transistors of all of the four-transistor/one-bit fast programmable switch cells are set to an erase inhibit voltage level of approximately 9.0V. The local bit line and the local source lines are coupled to a very large positive erase voltage of approximately 18V. This initiates the Fowler-Nordheim tunneling phenomena to lower the threshold voltage level of the second charge-retaining transistors of all the four-transistor/one-bit fast programmable switch cells of the array to the second threshold voltage level (Vt0) to initiate the Fowler-Nordheim tunneling phenomena.

Selected second charge-retaining transistors of selected pages or rows of the four-transistor/one-bit fast programmable switch cells of the array are then programmed. In the page program process, the primary input and inverse primary input lines connected to the selected page(s) are connected to a very large positive programming voltage level of approximately 18.0V. The primary input and inverse primary input lines connected to the unselected pages or rows are connected to an intermediate positive program inhibit voltage level of approximately 9.0V. The unselected pages of the charge-retaining transistors include the unselected primary input and inverse primary input lines of the paired primary input and inverse primary input lines of the selected four-transistor/one-bit fast programmable switch cells and the paired word lines of the unselected four-transistor/one-bit fast programmable switch cells. The local bit lines and the local source lines are set the ground reference voltage level (0.0V) to initiate the Fowler-Nordheim tunneling phenomena.

In some embodiments, a three-dimensional combination nonvolatile memory integrated circuit that includes any number of the three-dimensional NAND-based NOR nonvolatile memories including a three-dimensional two-transistor/two-bit NOR array for the block-alterable code storage, a three-dimensional three-transistor/one-bit byte-alterable EEPROM array for byte-alterable data storage, a three-dimensional NAND-based NOR two-transistor/two-bit block-alterable PLD's “AND and OR” logic arrays and a three-dimensional four-transistor/one-bit fast switch block-alterable array for a powerful memory and logic system-on-chip structure.

### BRIEF DESCRIPTION OF THE DRAWINGS

FIG. 1a is a top plan view of a three-dimensional nonvolatile memory cell of the prior art.

FIG. 1b is a schematic diagram of a three-dimensional nonvolatile memory cell of the prior art.

FIGS. 1c-1d are a cross-sectional views of a three-dimensional nonvolatile memory cell of the prior art.

FIG. 1e is a cross-sectional view of a three-dimensional transistor of the prior art.

FIG. 1f is a top plan view of a three-dimensional transistor of the prior art.

FIG. 2a is a top plan view of a three-dimensional nonvolatile memory array of the prior art.

FIG. 2b is a cross-sectional view of a three-dimensional nonvolatile memory array of the prior art.

FIG. 3 is a schematic of a three-dimensional nonvolatile memory array of the prior art.

FIG. 4 is a chart of voltage levels for operating a three-dimensional nonvolatile memory array of the prior art.

FIG. 5a is a top plan view of a three-dimensional NAND-based NOR nonvolatile memory cell embodying the principles of the present application.

FIG. 5b is a schematic diagram of a three-dimensional NAND-based NOR nonvolatile memory cell embodying the principles of the present application.

FIGS. 5c-5d are cross-sectional views of a three-dimensional NAND-based NOR nonvolatile memory cell embodying the principles of the present application.

FIG. 6a is a cross-sectional view of a three-dimensional switching transistor embodying the principles of the present application.

FIG. 6b is a top plan view of a three-dimensional switching transistor embodying the principles of the present application.

FIGS. 7a-7h are plots of the distributions of program and erase threshold voltage levels for the three-dimensional charge-retaining transistors of the three-dimensional NAND-based NOR nonvolatile memory cells of FIGS. 5a-5d embodying the principles of the present application.

FIG. 8a is a schematic of an array of three-dimensional NAND-based NOR nonvolatile memory cells embodying the principles of the present application.

FIG. 8b is a top plan view of an array of three-dimensional NAND-based NOR nonvolatile memory cells embodying the principles of the present application.

FIGS. 8c-8d are cross-sectional views of an array of three-dimensional NAND-based NOR nonvolatile memory cells embodying the principles of the present application.

FIGS. 9a and 9b are flowcharts for two methods of operation of a three-dimensional NAND-based NOR nonvolatile memory array embodying the principles of the present application.

FIGS. 10a and 10b are charts of voltage levels for the operating an array of three-dimensional NAND-based NOR nonvolatile memory cells of FIGS. 9a and 9b embodying the principles of the present application.

FIG. 11a is a top plan view of a three-dimensional NAND-based NOR nonvolatile PLD cell embodying the principles of the present application.

FIG. 11b is a schematic diagram of a three-dimensional NAND-based NOR nonvolatile PLD cell embodying the principles of the present application.

FIG. 11c is a plot of the program and erase threshold voltage distributions of three-dimensional NAND-based NOR nonvolatile PLD cell embodying the principles of the present application.

FIG. 12a is a schematic diagram of an array of three-dimensional NAND-based NOR nonvolatile PLD cells embodying the principles of the present application.

FIG. 12b is a block diagram of multiple arrays of the three-dimensional NAND-based NOR nonvolatile PLD cells embodying the principles of the present application of FIG. 12a.

FIG. 12c is a flowchart for a method of operation of a three-dimensional NAND-based NOR nonvolatile PLD array of FIG. 12a embodying the principles of the present application.

FIG. 12d is a chart of voltage levels for operating with the method of FIG. 12c a three-dimensional NAND-based NOR nonvolatile PLD array embodying the principles of the present application.

FIG. 13a is a schematic diagram of a three-dimensional NAND-based NOR flash nonvolatile reconfigurable switching circuit for a low-resistance switching application for fast connections in an FPGA application embodying the principles of the present application.

FIG. 13b is a top plan view of the three-dimensional NAND-based NOR flash nonvolatile reconfigurable switching circuit of FIG. 13a embodying the principles of the present application.

FIG. 13c is a plot of the program and erase threshold voltage distributions of the three-dimensional NAND-based NOR flash nonvolatile reconfigurable switching circuit of FIG. 13a embodying the principles of the present application.

FIG. 13d is a diagram of an application within an FPGA of the three-dimensional NAND-based NOR flash nonvolatile reconfigurable switching circuit of FIG. 13a embodying the principles of the present application.

FIG. 13e is a chart for the voltage levels for functional operation of the three-dimensional NAND-based NOR flash nonvolatile reconfigurable switching circuit of FIG. 13a embodying the principles of the present application.

FIG. 14a is a flow chart for a method for programming and erasing the three-dimensional NAND-based NOR flash nonvolatile reconfigurable switching circuit of FIG. 13a embodying the principles of the present application.

FIG. 14b is a chart of programming and erasing voltage levels of the operating voltage level of the three-dimensional NAND-based NOR flash nonvolatile reconfigurable switching circuit of FIG. 13a embodying the principles of the present application.

FIG. 15a is a schematic diagram of a three-transistor/one-bit three-dimensional EEPROM cell embodying the principles of the present application.

FIG. 15b is a top plan view of a three-transistor/one-bit three-dimensional EEPROM cell embodying the principles of the present application.

FIGS. 15c-15e are cross-sectional views of the transistors of a three-transistor/one-bit three-dimensional EEPROM cell of FIG. 15b embodying the principles of the present application.

FIG. 15f is a plot of the program and erase threshold voltage distributions of a three-transistor/one-bit three-dimensional EEPROM cell embodying the principles of the present application.

FIG. 16a is a schematic diagram of an array of three-transistor/one-bit three-dimensional EEPROM cells embodying the principles of the present application.

FIG. 16b is a top plan view of an array of three-transistor/one-bit three-dimensional EEPROM cells embodying the principles of the present application

FIG. 16c is a is a cross-sectional view of a interlayer plug of an array of three-transistor/one-bit three-dimensional EEPROM cells embodying the principles of the present application.

FIGS. 16d and 16e are cross sectional views of an array of three-transistor/one-bit three-dimensional EEPROM cells embodying the principles of the present application.

FIG. 17 is a block diagram of an integrated circuit device formed of multiple arrays of three-transistor/one-bit three-dimensional EEPROM cells embodying the principles embodying the principles of the present application.

FIG. 18 is a chart for the voltage levels for functional operation of an array of three-transistor/one-bit three-dimensional EEPROM cells embodying the principles of the present application.

### DETAILED DESCRIPTION

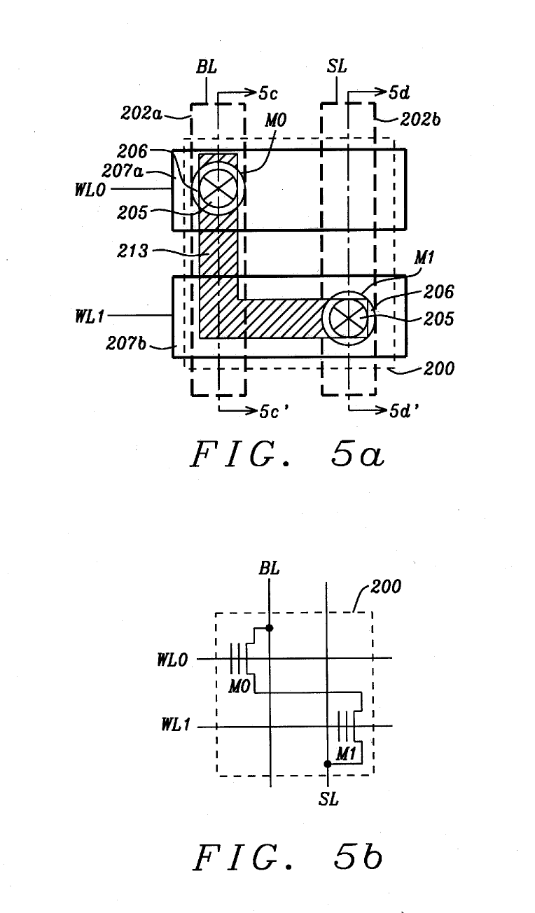

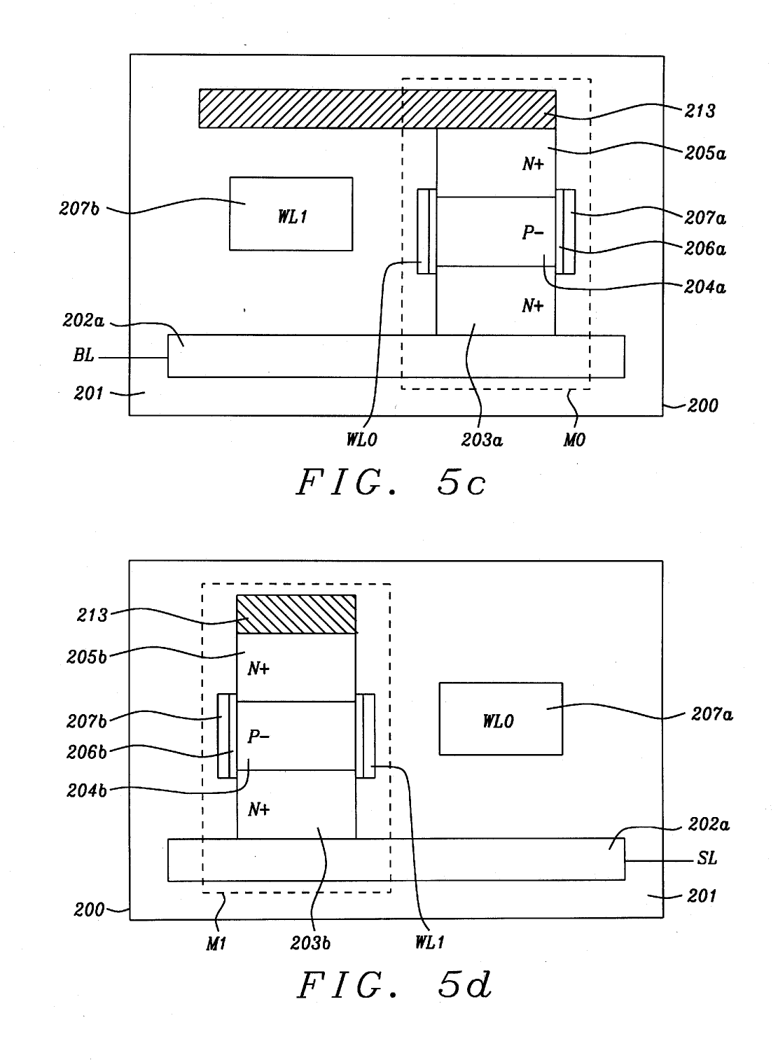

FIG. 5a is a top plan view of a three-dimensional NAND-based NOR nonvolatile memory cell 200. FIG. 5b is a schematic diagram of a three-dimensional NAND-based NOR nonvolatile memory cell 200. FIGS. 5c-5d are cross-sectional views of a three-dimensional NAND-based NOR nonvolatile memory cell 200. The three-dimensional NAND-based NOR nonvolatile memory cell 200 has two three-dimensional charge-retaining transistors M0 and M1 that retain two bits of data. The two three-dimensional charge-retaining transistors M0 and M1 are placed such that they occupy two sub-columns of a column of the three-dimensional charge-retaining transistors M0 and M1 in an array.

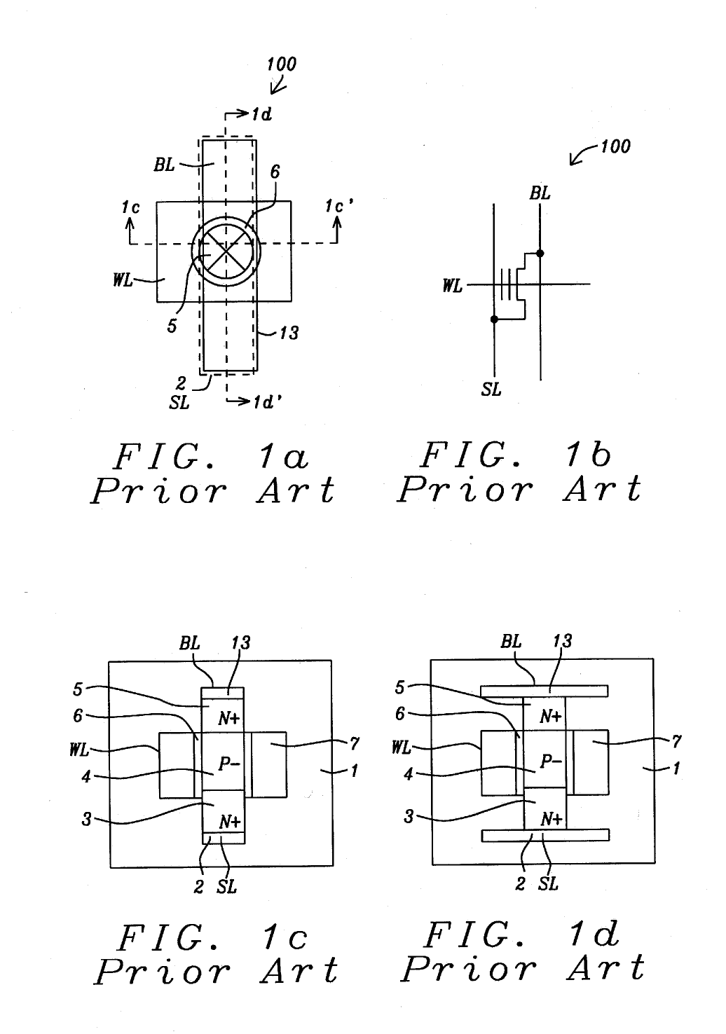

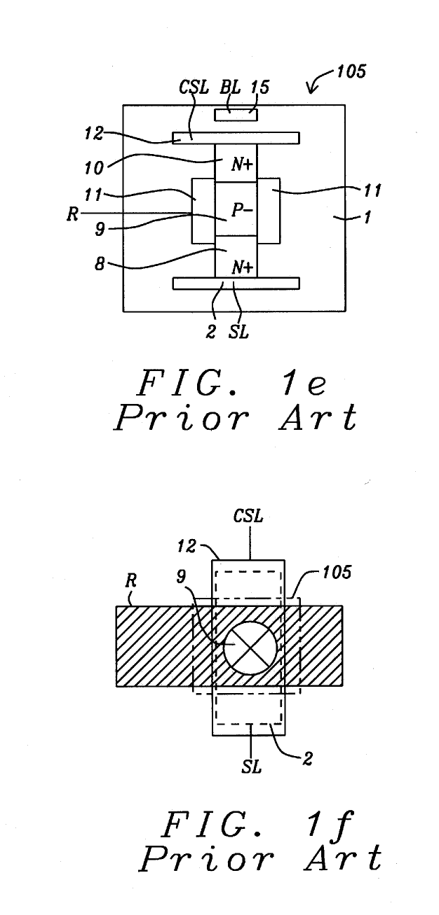

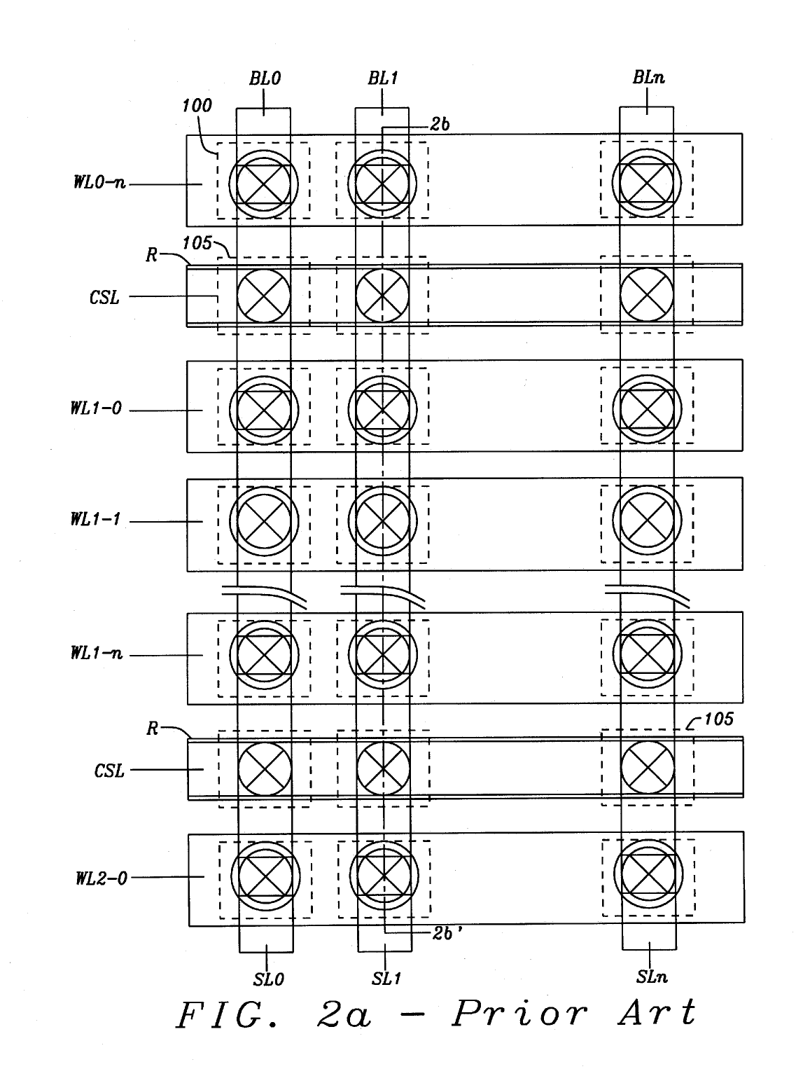

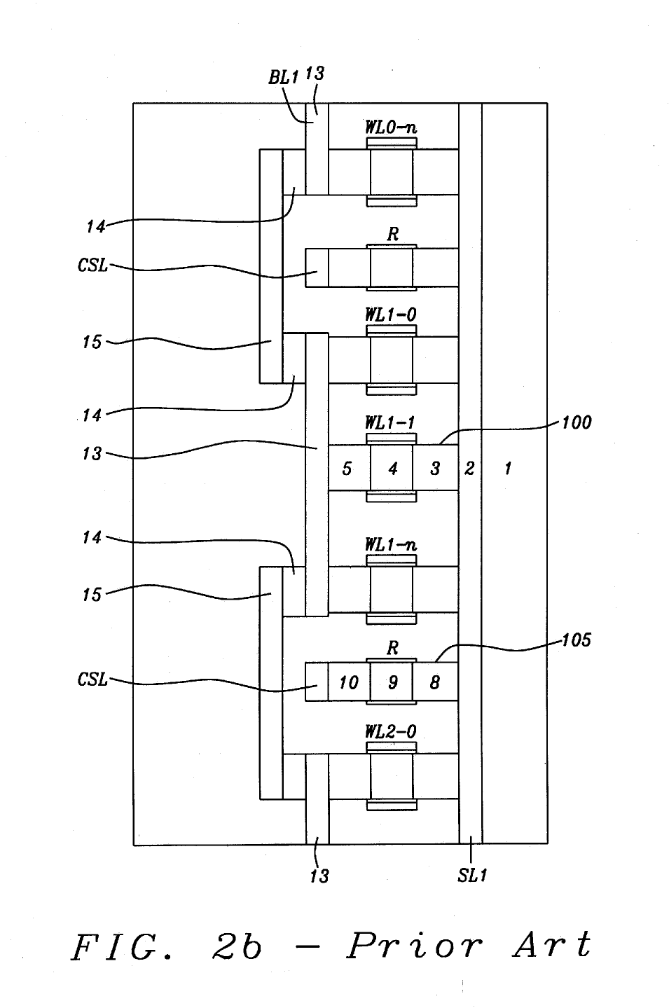

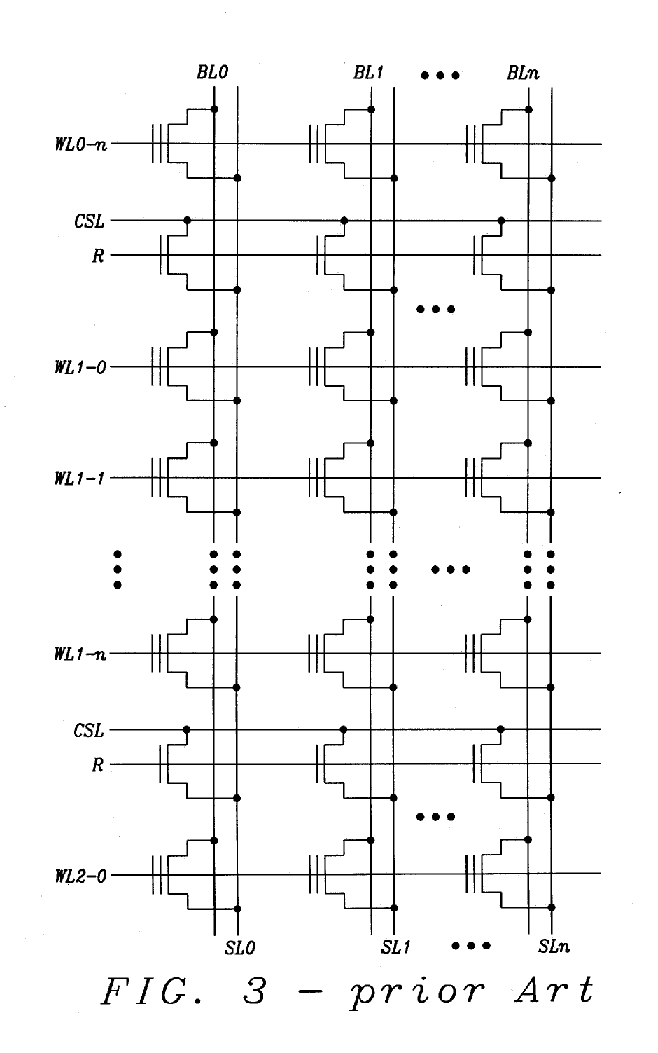

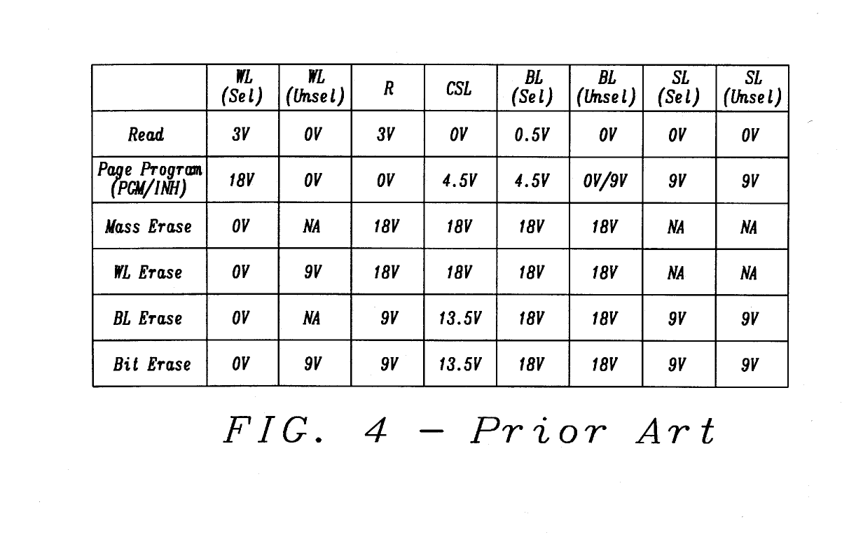

The three-dimensional charge-retaining transistors M0 and M1 are formed similar to the single one-transistor/one-bit three-dimensional NMOS NOR flash transistor 100 of FIG. 1a. The three-dimensional charge-retaining transistors M0 and M1 are formed as a cylindrical doped silicon structures. The drain of the three-dimensional charge-retaining transistor M0 and the source of the three-dimensional charge-retaining transistor M1 are N+ active diffusion layers 203a and 203b formed respectively on a bit line BL that is an N+ active diffusion layer 202a and a source line SL that is an N+ active diffusion layer 202b within the surface of the substrate 201 and connected to column control circuitry (not shown). The bulks of the three-dimensional charge-retaining transistors M0 and M1 are respectively formed of the P− diffusion layers 204a and 204b that is formed immediately above the drain and source N+ active diffusions 203a and 203b. The source of the three-dimensional charge-retaining transistor M0 and the drain three-dimensional charge-retaining transistor M1 are then respectively formed immediately above as the second N+ active diffusion layers 205a and 205b on the bulk P− diffusion layers 204a and 204b. Insulating SONOS layers 206a and 206b are respectively formed to surround the bulk is formed of the P− diffusion layers 204a and 204b. Polycrystalline silicon layers 207a and 207b are formed around the insulating SONOS layers 206a and 206b to respectively create the control gates of the three-dimensional charge-retaining transistors M0 and M1. The control gates 207a and 207b are merged respectively with the word line WL0 and WL1 as a polycrystalline layer extending from row control circuitry (not shown).

A metal layer 213 is a connector strap that joins the source N+ active diffusion layer 205a of the three-dimensional charge-retaining transistor M0 and drain N+ active diffusion layer 205b of the three-dimensional charge-retaining transistor M1. The three-dimensional NAND-based NOR nonvolatile memory cell 200 is structured to store two bits.

Referring to FIG. 5b, the schematic of the three-dimensional NAND-based NOR nonvolatile memory cell 200 illustrates the drain of the three-dimensional charge-retaining transistor M0 connected to the bit line BL. The source of the three-dimensional charge-retaining transistor M0 is connected to the drain of the three-dimensional charge-retaining transistor M1. The source of the three-dimensional charge-retaining transistor M1 is connected to the source line SL. The three-dimensional NAND-based NOR nonvolatile memory cell 200 connected to paired word lines WL0 and WL1 where the control gate of the three-dimensional charge-retaining transistor M0 is connected to the first word line WL0 and the control gate of the three-dimensional charge-retaining transistor M1 is connected to the second word line WL1. While the three-dimensional NAND-based NOR nonvolatile memory cell 200 is shown as a single poly-crystalline silicon three-dimensional charge-retaining transistors M0 and M1, it is in keeping with the intention of this application that the three-dimensional charge-retaining transistors M0 and M1 may be double poly-crystalline silicon floating-gate charge storing transistors. This size of the three-dimensional NAND-based NOR nonvolatile memory cell 200 is about 6λ×6λ, where λ is the minimum layout geometry feature of the technology. The three-dimensional charge-retaining transistors M0 and M1 are serially connected to avoid the over-erase during a block-erase operation of an array of the three-dimensional NAND-based NOR nonvolatile memory cell 200 for operating with a low voltage power supply voltage source (VDD) of approximately 1.2V.

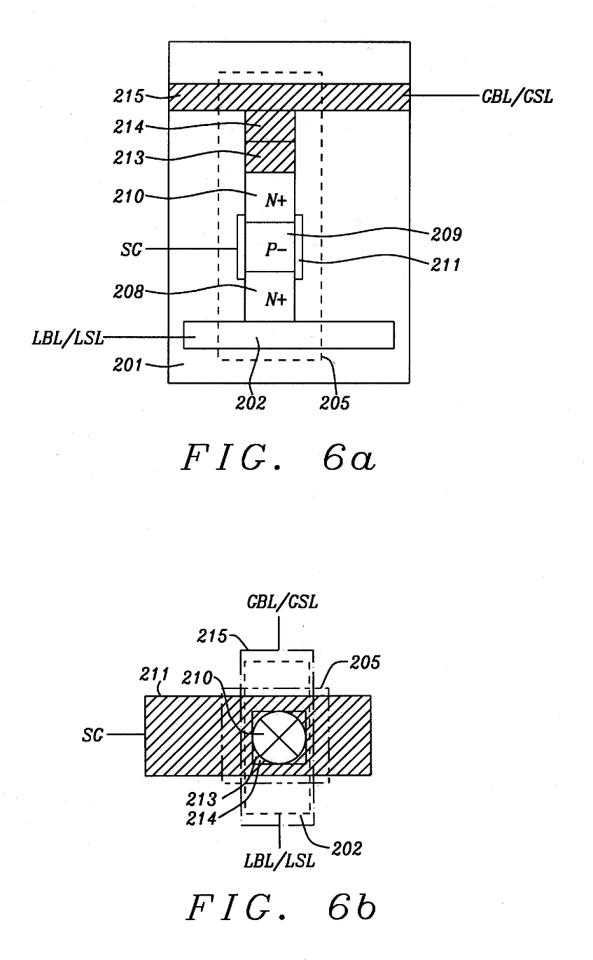

FIG. 6a is a cross-sectional view of a three-dimensional switching transistor. FIG. 6b is a top plan view of a three-dimensional switching transistor. The bottom source N+ active layer 208 is connected to a diffusion layer 202 to form either the local bit line LBL or the local source line LSL. A bulk region is a P− silicon cylinder 209 formed on the bottom source N+ active diffusion layer 208. An N+ active diffusion layer 210 is formed on the bulk region P− silicon cylinder 209 to make the drain. The drain N+ active layer 210 is connected to metal layer 215 that is the global bit line GBL or the global source line GSL that connected to the column control circuitry. The metal layers 213 and 214 form essentially a metal plug to join the drain N+ active diffusion layer 210 to the global bit line GBL or the global source line GSL. A polycrystalline silicon cylindrical ring 211 is formed around the bulk P− silicon cylinder 209 to create a gate for the three-dimensional switching transistor 205. The activating of the three-dimensional switching transistor 205 is controlled by select gating signal SG connected to the gate 211.

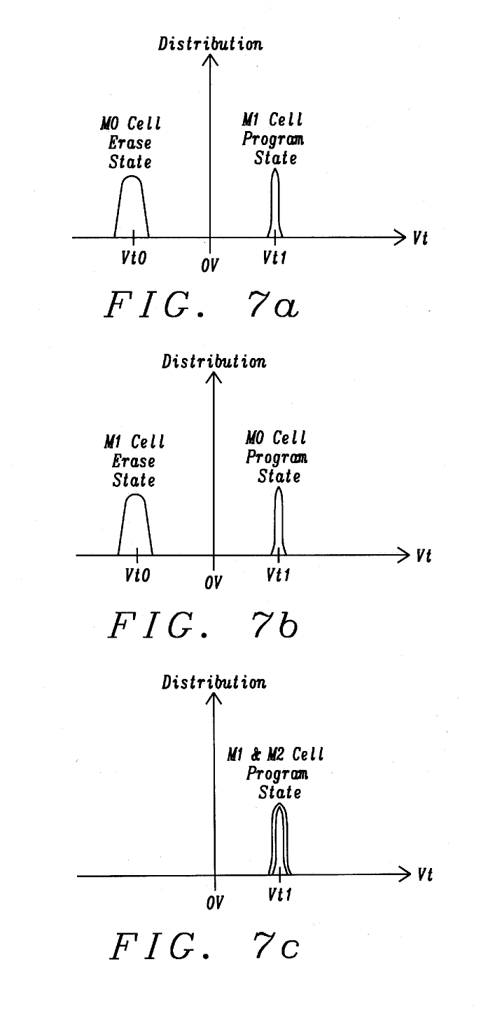

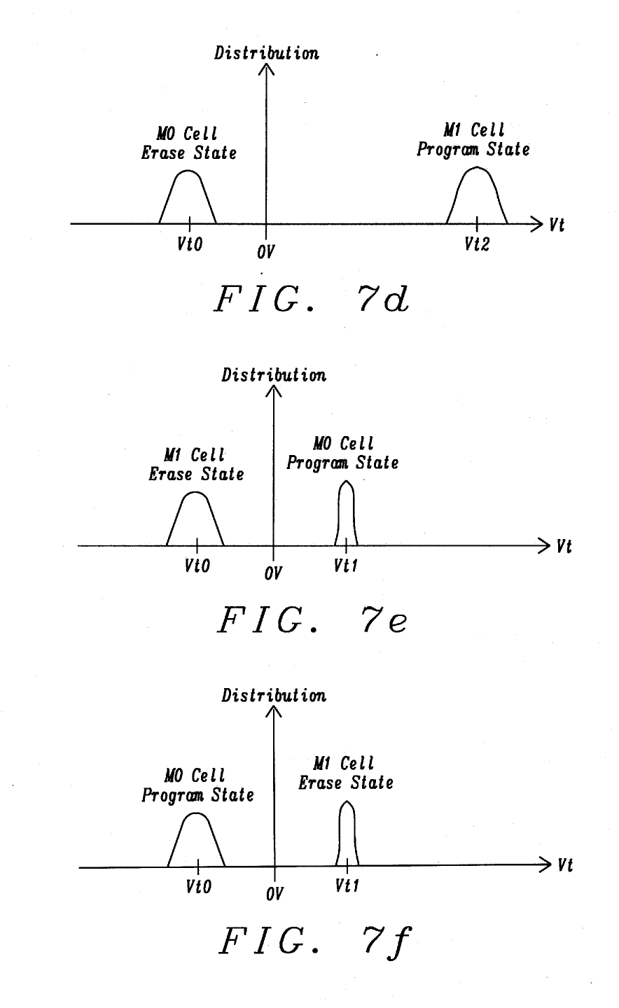

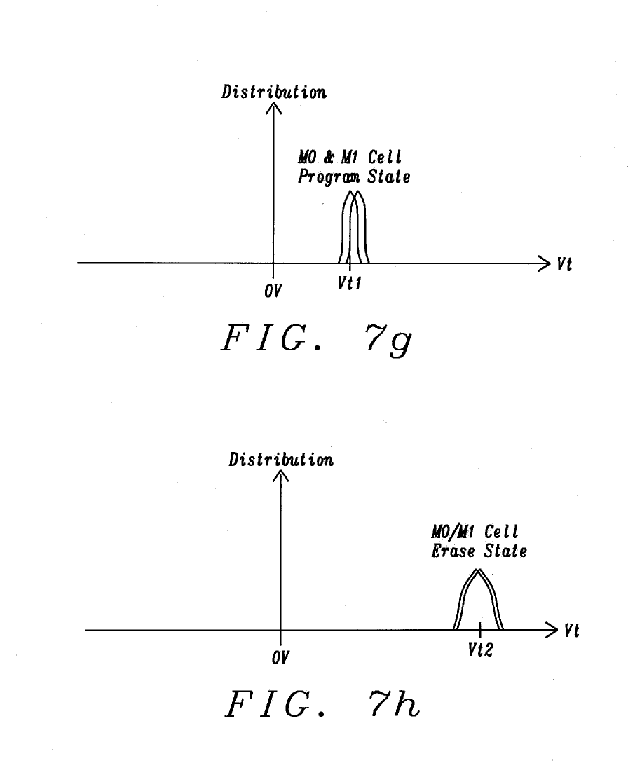

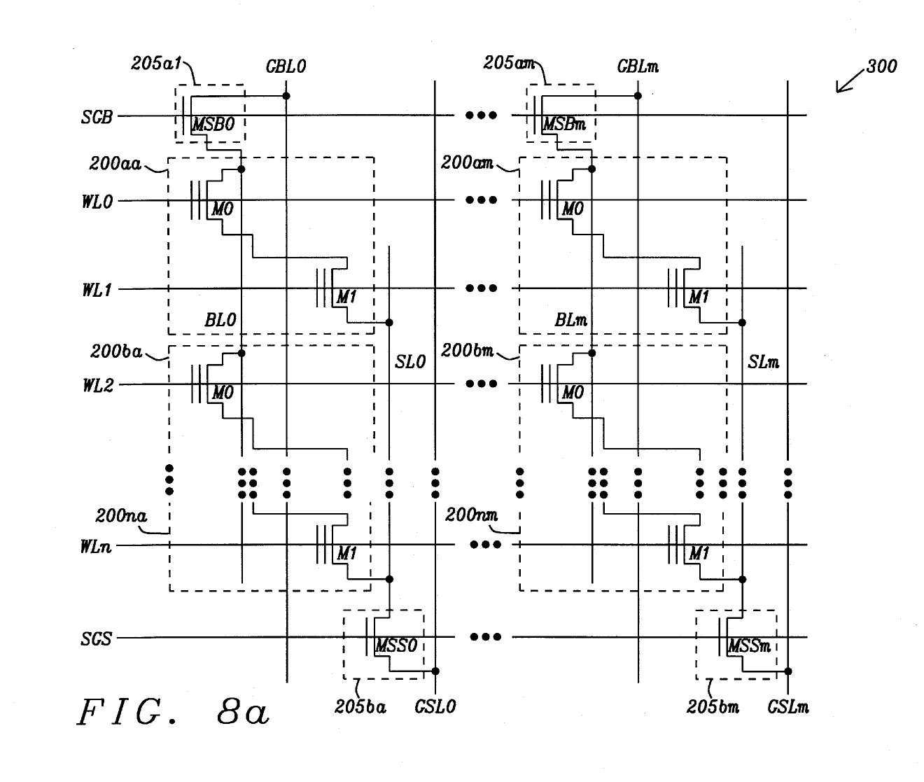

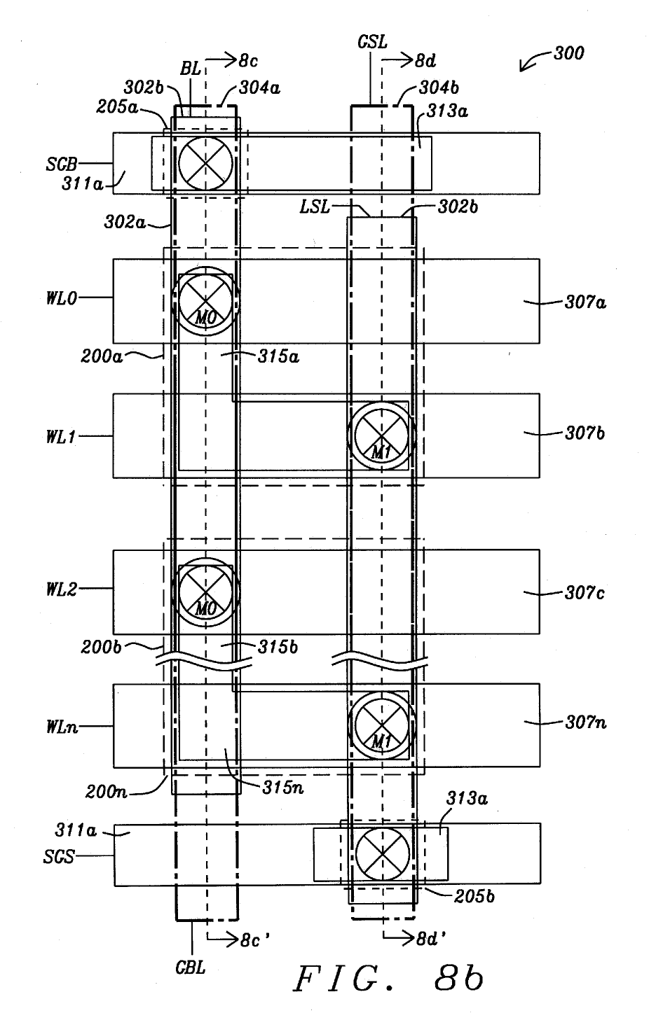

FIGS. 7a-7h are plots of the distributions of program and erase threshold voltage levels for the three-dimensional charge-retaining transistors M0 and M1 of the three-dimensional NAND-based NOR nonvolatile memory cells 200 of FIGS. 5a-5d. The program threshold voltage level (Vt1) is assigned to be a positive threshold voltage level of approximately 0.7V with a variation of +1-0.5V for applications having voltage level of the power supply voltage source (VDD) of approximately 1.2V. If the voltage level of the power supply voltage source (VDD) is approximately 1.5V, the positive threshold voltage level (Vt1) is assigned to be approximately 1.0V with a variation of +/−0.5V. The erase threshold voltage level (Vt0) is assigned a negative threshold voltage level of approximately −2.0V nominally with a maximum negative threshold voltage level of −1.5V. If it any more negative, the negative threshold voltage level is a “don't care” state.

In FIG. 7a, the threshold voltage levels illustrate the first three-dimensional charge-retaining transistor M0 being programmed and the second three-dimensional charge-retaining transistor M1 being erased. In FIG. 7b, the first three-dimensional charge-retaining transistor M0 is erased and the second three-dimensional charge-retaining transistor M1 is programmed. In FIG. 7c, both of the three-dimensional charge-retaining transistors M0 and M1 are programmed. If both of the three-dimensional charge-retaining transistors M0 and M1 are erased, a leakage current will occur from the local bit lines BL to local source lines SL from non-selected three-dimensional NAND-based NOR nonvolatile memory cells 200 in the same selected columns during the read and verification operations. Thus the threshold voltage assignments of FIGS. 7a-7c are not satisfactory unless the coding of the data programmed to three-dimensional charge-retaining transistors M0 and M1 two of the three-dimensional NAND-based NOR nonvolatile memory cell 200 compensates to allow for both of the three-dimensional charge-retaining transistors M0 and M1 to never be simultaneously erased.

In FIG. 7d, the program threshold voltage level (Vt1) is assigned to be a positive threshold voltage level of approximately 2.0V with a variation of +/−0.5V. The erase threshold voltage level (Vt0) is assigned a negative threshold voltage level of approximately −1.2V nominally with a maximum negative threshold voltage level of −0.7V. If it any more negative, the negative threshold voltage level is a “don't care” state. Again, the threshold voltage assignments of FIG. 7d is not satisfactory unless the coding of the data programmed to the three-dimensional charge-retaining transistors M0 and M1 of the three-dimensional NAND-based NOR nonvolatile memory cell 200 compensates to allow for both of the three-dimensional charge-retaining transistors M0 and M1 to never be simultaneously erased.

Referring now to FIGS. 7e, 7f, 7g, and 7h, to eliminate the leakage current as stated above, the assignment of the threshold voltage levels of the three-dimensional charge-retaining transistors M0 and M1 must never be simultaneously be set to have negative threshold voltage levels. To accomplish this, the three-dimensional charge-retaining transistors M0 and M1 will be commonly encoded with the two bits of data, rather than each of the three-dimensional charge-retaining transistors M0 and M1 having its own unique data. Three threshold voltage levels Vt0, Vt1, and Vt2 are employed to establish the encoding. The first threshold voltage level (Vt0) is assigned a negative threshold voltage level of approximately −2.0V nominally with a maximum negative threshold voltage level of −1.5V. If it any more negative, the negative threshold voltage level is a “don't care” state. The second threshold voltage level (Vt1) is assigned to be a positive threshold voltage level of approximately 0.7V with a variation of +/−0.5V for applications having voltage level of the power supply voltage source (VDD) of approximately 1.2V. If the voltage level of the power supply voltage source (VDD) is approximately 1.5V, the positive threshold voltage level (Vt1) is assigned to be approximately 1.0V with a variation of +/−0.5V. The third threshold voltage level is set to be greater than the lower limit of the second programmed threshold voltage level (Vt2L) that is approximately 3.0V.

Refer now to table 1 for one embodiment of the programming of the internal logic states of the three-dimensional charge-retaining transistors M0 and M1 of the three-dimensional NAND-based NOR nonvolatile memory cell 200. The threshold voltage assignments for the three-dimensional charge-retaining transistors M0 and M1 are illustrated in FIGS. 7e-7h. The threshold voltage levels as shown are interpreted as the internal logic states as shown. The internal logic state for the three-dimensional charge-retaining transistors M0 and M1 of the three-dimensional NAND-based NOR nonvolatile memory cell 200 are transferred to a decode circuitry within a column control circuit to translate the internal logic state to the external logic state during a read and verification operation.

TABLE 1

| | Threshold of | Internal Logic | External Logic |
|---|---|---|---|
| | M0 & M1 | State | State |
| FIG. 7e | Vt1, Vt0 | 1, 0 | 1, 1 |
| FIG. 7f | Vt0, Vt1 | 0, 1 | 0, 1 |
| FIG. 7g | Vt1, Vt1 | 1, 1 | 1, 0 |
| FIG. 7h | Vt2, Vt2 | 0, 0 | 0, 0 |

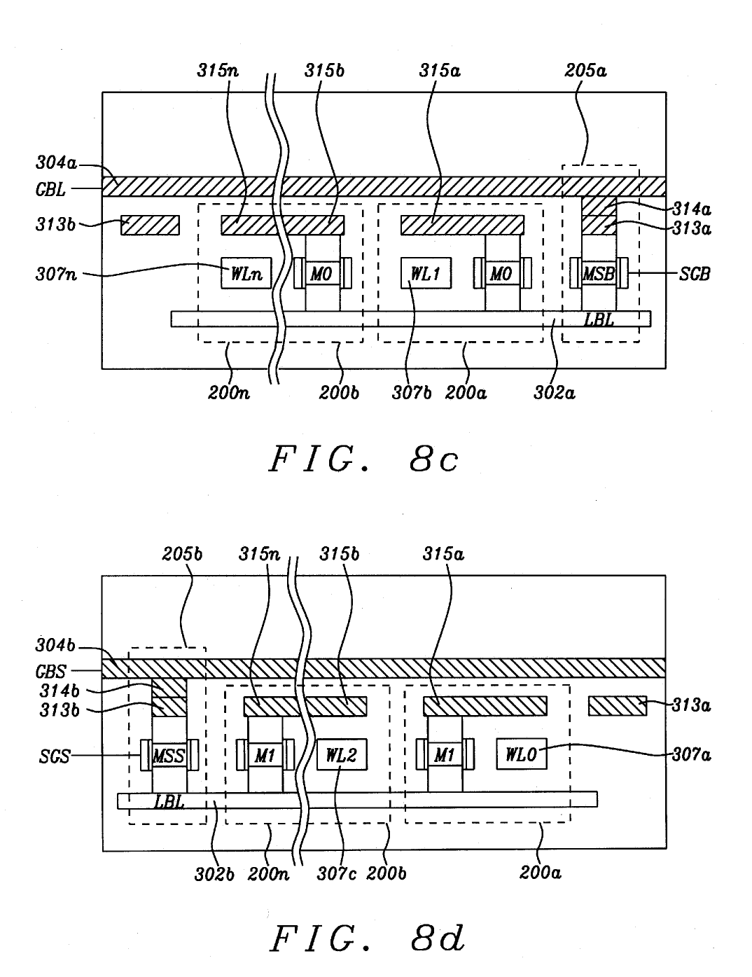

FIG. 8a is a schematic of the array 300 of three-dimensional NAND-based NOR nonvolatile memory cells 200a, . . . , 200n. FIG. 8b is a top plan view of an array 300 of three-dimensional NAND-based NOR nonvolatile memory cells 200a, . . . , 200n. FIGS. 8c-8d are cross-sectional views of the array 300 of three-dimensional NAND-based NOR nonvolatile memory cells 200a, . . . , 200n. In FIG. 8a, a number of three-dimensional NAND-based NOR nonvolatile memory cells 200aa, . . . , 200am, . . . , 200na, . . . , 200nm are arranged in rows and columns. Each of the three-dimensional NAND-based NOR nonvolatile memory cells 200aa, . . . , 200am, . . . , 200na, . . . , 200nm are structured as described in FIGS. 5a-5d. The drain of each the charge-retaining transistors M0 are connected to a local bit line BL0, BLm. The source of each of the charge-retaining transistors M1 are connected to a local source line SL0, SLm. The local bit lines BL0, . . . , BLm and the local source lines SL0, . . . , SLm are N+ active diffusion layers placed beneath each of the three-dimensional NAND-based NOR nonvolatile memory cells 200aa, . . . , 200am, . . . , 200na, . . . , 200nm. Each of the local bit lines BL0, . . . , BLm and the local source lines SL0, . . . , SLm are associated with one column of the three-dimensional NAND-based NOR nonvolatile memory cells 200aa, . . . , 200am, . . . , 200na, . . . , 200nm.

Each row of the three-dimensional NAND-based NOR nonvolatile memory cells 200aa, . . . , 200am, . . . , 200na, . . . , 200nm is associated with a pair of word lines WL0, WL1, . . . , WLn. One of the paired word lines WL0, WL1, . . . , WLn is connected to the control gate of the first of the three-dimensional charge-retaining transistors M0 and the second of the paired word lines WL0, WL1, . . . , WLn is connected to the control gate of the three-dimensional charge-retaining transistors M1. The paired word lines WL0, WL1, WLn are connected to row control circuitry (not shown) that provides the necessary voltages for reading, programming, erasing, and verifying the programming or erasing of selected three-dimensional NAND-based NOR nonvolatile memory cells 200aa, . . . , 200am, . . . , 200na, . . . , 200nm.

Each of the local bit lines BL0, . . . , BLm are connected to the source of one of the select gating transistors 205a0, . . . , 205am. Each drain of select gating transistors 205a0, . . . , 205am are connected to a global bit line GBL0, . . . , GBLm associated with each column of the three-dimensional NAND-based NOR nonvolatile memory cells 200aa, . . . , 200am, . . . , 200na, . . . , 200nm. Each of the local source lines SL0, . . . , SLm are connected to the source of one of the select gating transistors 205b0, . . . , 205bm. Each drain of select gating transistors 205b0, 205bm are connected to a global source line GSL0, . . . , GSL associated with each column of the three-dimensional NAND-based NOR nonvolatile memory cells 200aa, . . . , 200am, . . . , 200na, . . . , 200nm. The global bit lines GBL0, . . . , GBL and the global source lines GSL0, . . . , GSL are connected to a column control circuit that provides the circuitry for generating the necessary voltage levels necessary for reading, programming, erasing and verifying the programming and erasing of selected three-dimensional NAND-based NOR nonvolatile memory cells 200aa, . . . , 200am, . . . , 200na, . . . , 200nm. The gate of the select gating transistor 205a is connected to a select bit line gating signal generated by the row control circuitry (not shown) to activate the select gating transistor 205a. The gate of the select gating transistor 205b is connected to a select bit line gating signal generated by the row control circuitry (not shown) to activate the select gating transistor 205b.

Refer now to FIGS. 8b, 8c, and 8d. FIG. 8b illustrates a single column of the array 300 of the three-dimensional NAND-based NOR nonvolatile memory cells 200aa, . . . , 200am, . . . , 200na, . . . , 200nm of FIG. 8a. FIG. 8c is a cross-sectional view of a first sub-column of the first charge-retaining transistors M0 of the column of the three-dimensional NAND-based NOR nonvolatile memory cells 200aa, . . . , 200am, . . . , 200na, . . . , 200nm. Similarly, FIG. 8d is a cross-sectional view of a first sub-column of the second charge-retaining transistors M1 of the column of the three-dimensional NAND-based NOR nonvolatile memory cells 200aa, . . . , 200am, . . . , 200na, . . . , 200nm. The N+ active diffusion layers 302a and 302b respectively form the bit line BL and the source line SL. The structures of the charge-retaining transistors M0 and M1 are equivalent those described in FIGS. 5a-5d. The control gates of each of the charge-retaining transistors M0 and M1 are merged with the polycrystalline silicon layers 307a, 307b, . . . , and 307n that form the word lines WL0, WL1, . . . , WLn.

One end of the local bit line N+ active diffusion layer 302a is connected to the source of the select gating transistor 205a. Similarly, one end of the local source line N+ active diffusion layer 302b is connected to the source of the select gating transistor 205b. The select gating transistors 205a and 205b are structured as described in FIGS. 6a-6b. The drain of the select gating transistor 205a is connected to the metal layer 304a that forms the global bit line GBL. The drain of the select gating transistor 205b is connected to the metal layer 304b that forms the global source line GSL.

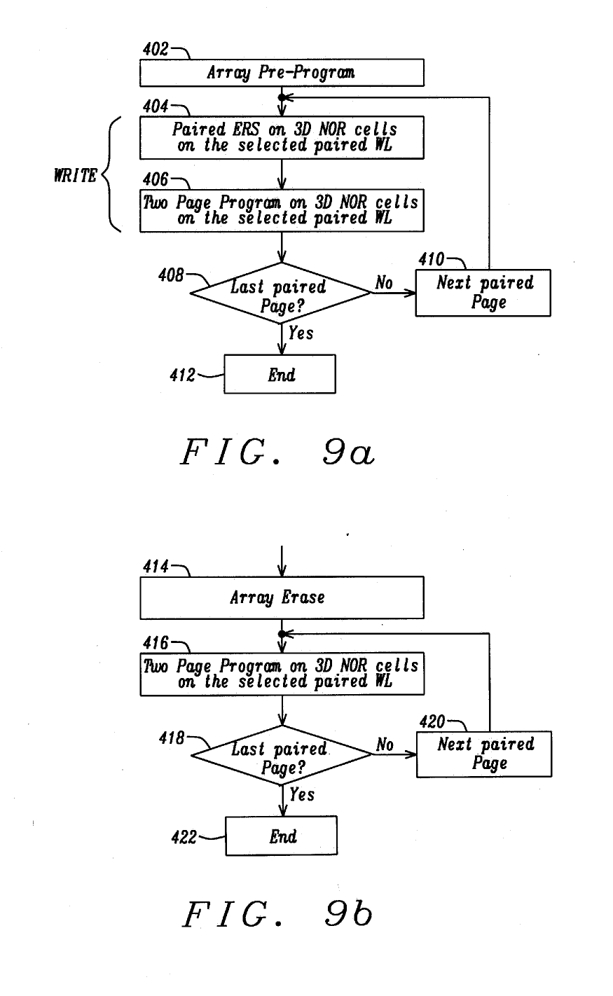

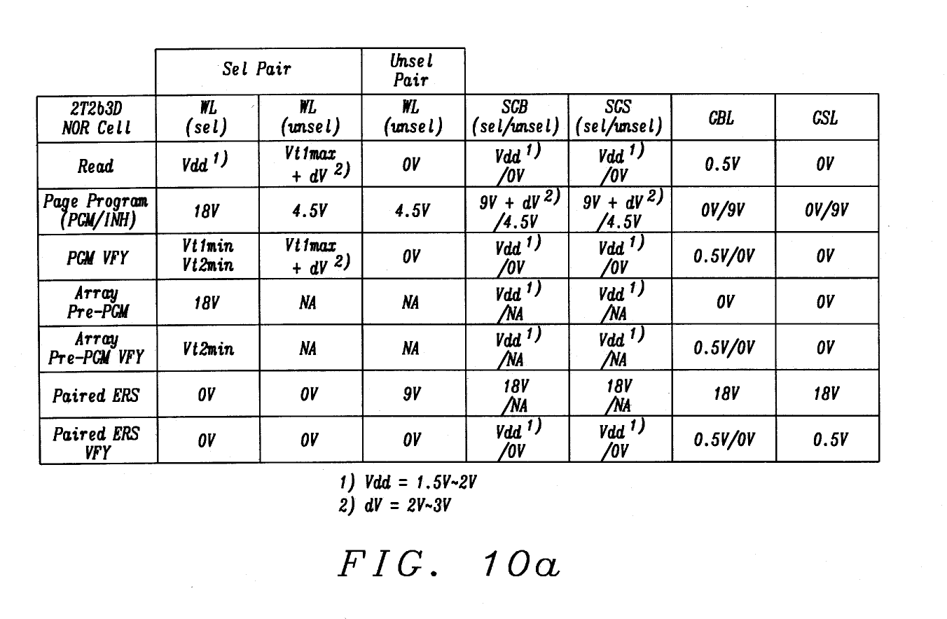

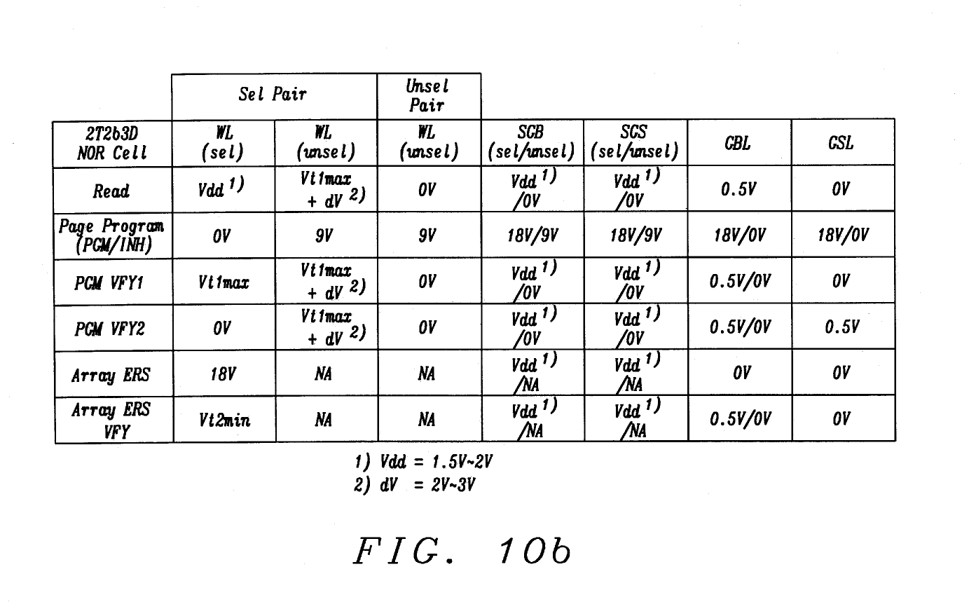

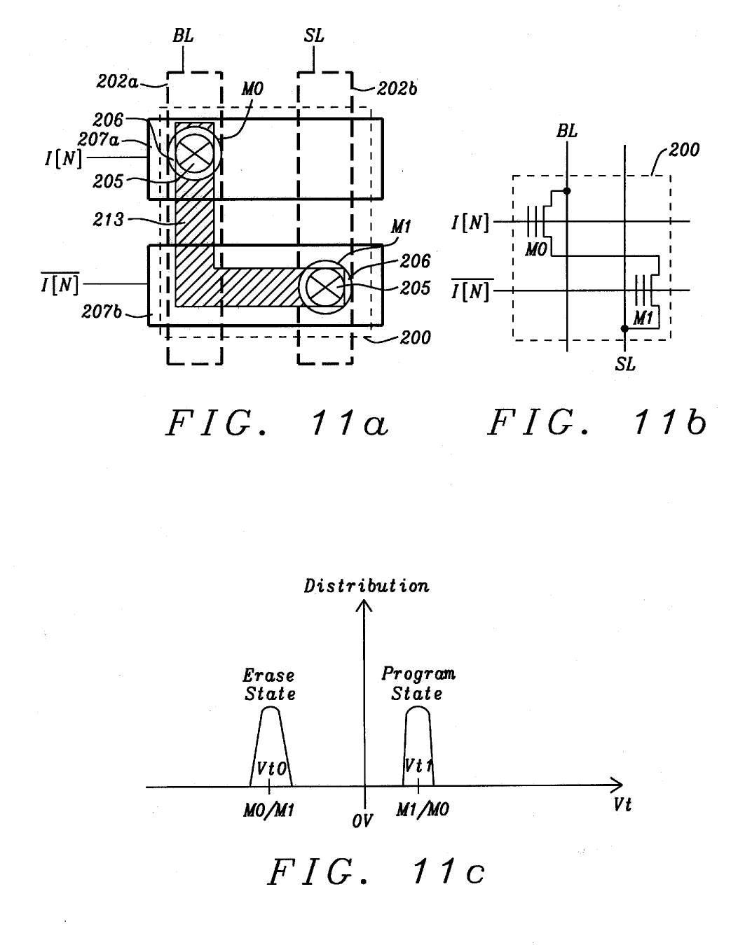

FIGS. 9a and 9b are flowcharts for two methods of operation of a three-dimensional NAND-based NOR nonvolatile memory array embodying the principles of the present application. FIGS. 10a and 10b are charts of voltage levels for the operating methods an array of three-dimensional NAND-based NOR nonvolatile memory cells of FIGS. 9a and 9b embodying the principles of the present application. Referring to FIGS. 9a and 10a, the method of operating the array of three-dimensional NAND-based NOR nonvolatile memory cells begins with pre-programming (Box 402) the array of three-dimensional NAND-based NOR nonvolatile memory cells. The pre-programming operation establishes the voltage thresholds of all the charge-retaining transistors M0 and M1 of the three-dimensional NAND-based NOR nonvolatile memory cells 200aa, . . . , 200am, . . . , 200na, . . . , 200nm of the array to be set at the positive programmed threshold voltage level. To establish this, the voltage levels for the word lines WL, the global bit lines GBL, the global source lines GSL, the bit line select gating lines SGB, and the source line select gating lines SGS are shown in the row for the array pre-program of FIG. 10a.

The charge-retaining transistors M0 and M1 of the three-dimensional NAND-based NOR nonvolatile memory cells 200aa, . . . , 200am, . . . , 200na, . . . , 200nm are pre-program verified as part of the pre-programming (Box 402). Each word line is set to the minimum voltage level of the third threshold voltage level (Vt2min) for determining that each of the charge-retaining transistors M0 and M1 of the three-dimensional NAND-based NOR nonvolatile memory cells 200aa, . . . , 200am, . . . , 200na, . . . , 200nm are pre-programmed with the global bit lines GBL, the global source lines GSL, the bit line select gating lines SGB, and the source line select gating lines SGS being set as shown in the row for the array pre-program verify of FIG. 10a.

The write process begins with erasing (Box 404) a selected paired row of the charge-retaining transistors M0 and M1 of the three-dimensional NAND-based NOR nonvolatile memory cells 200aa, . . . , 200am, . . . , 200na, . . . , 200nm on a selected row to the first threshold voltage level (Vt0). This is accomplished by setting the voltage levels for the word lines WL, the global bit lines GBL, the global source lines GSL, the bit line select gating lines SGB, and the source line select gating lines SGS are shown in the row for the paired erase of FIG. 10a.

The paired row of charge-retaining transistors M0 and M1 of the three-dimensional NAND-based NOR nonvolatile memory cells 200aa, . . . , 200am, . . . , 200na, . . . , 200nm are erase verified as part of the erasing (Box 404). Each paired word line is set to the ground reference voltage level (0.0V) for determining that each of the charge-retaining transistors M0 and M1 of the three-dimensional NAND-based NOR nonvolatile memory cells 200aa, . . . , 200am, . . . , 200na, . . . , 200nm are erased with the unselected word lines WL, global bit lines GBL, the global source lines GSL, the bit line select gating lines SGB, and the source line select gating lines SGS being set as shown in the row for the paired erase verify of FIG. 10a.

The write process continues with programming (Box 406) a selected paired row of the charge-retaining transistors M0 and M1 of the three-dimensional NAND-based NOR nonvolatile memory cells 200aa, . . . , 200am, . . . , 200na, . . . , 200nm on a selected row to the second threshold voltage level (Vt1). This is accomplished by setting the voltage levels for the selected and unselected word lines WL, the global bit lines GBL, the global source lines GSL, the bit line select gating lines SGB, and the source line select gating lines SGS are shown in the row for the paired erase of FIG. 10a.

The paired row of charge-retaining transistors M0 and M1 of the three-dimensional NAND-based NOR nonvolatile memory cells 200aa, . . . , 200am, . . . , 200na, . . . , 200nm are program verified as part of the programming (Box 406). Each paired word line is iteratively set to the minimum value of the second threshold voltage level (Vt1 min) followed by minimum value of the third threshold voltage level (Vt2 min) for determining that each of the charge-retaining transistors M0 and M1 of the three-dimensional NAND-based NOR nonvolatile memory cells 200aa, . . . , 200am, . . . , 200na, . . . , 200nm are programmed with the unselected word lines WL, global bit lines GBL, the global source lines GSL, the bit line select gating lines SGB, and the source line select gating lines SGS being set as shown in the row for the paired erase verify of FIG. 10a.

The process examines (Box 408) if the last paired row of the charge-retaining transistors M0 and M1 of the three-dimensional NAND-based NOR nonvolatile memory cells 200aa, . . . , 200am, . . . , 200na, . . . , 200nm have been written. If they have not been written, the next paired row of the charge-retaining transistors M0 and M1 are selected (Box 410) and written as described above. When all the selected charge-retaining transistors M0 and M1 of the three-dimensional NAND-based NOR nonvolatile memory cells 200aa, . . . , 200am, . . . , 200na, . . . , 200nm are written the process ends (Box 412).

The chart of FIG. 10a further includes the necessary voltages levels that are applied to the charge-retaining transistors M0 and M1 of the three-dimensional NAND-based NOR nonvolatile memory cells 200aa, . . . , 200am, . . . , 200na, . . . , 200nm for reading the data contained in a selected row or page of the three-dimensional NAND-based NOR nonvolatile memory cells 200aa, . . . , 200am, . . . , 200na, . . . , 200nm. The read is accomplished by setting the voltage levels for the selected and unselected word lines WL, the global bit lines GBL, the global source lines GSL, the bit line select gating lines SGB, and the source line select gating lines SGS are shown in the row for the read of FIG. 10a.

Referring to FIGS. 9b and 10b, the method of operating the array of three-dimensional NAND-based NOR nonvolatile memory cells has the erased threshold voltage level set to the third threshold voltage level (Vt2) as shown in FIG. 7h. The method of FIGS. 9b and 10b begins with erasing (Box 414) charge-retaining transistors M0 and M1 of the array of three-dimensional NAND-based NOR nonvolatile memory cells 200aa, . . . , 200am, . . . , 200na, . . . , 200nm to establish the voltage thresholds of all the charge-retaining transistors M0 and M1 of the three-dimensional NAND-based NOR nonvolatile memory cells 200aa, . . . , 200am, . . . , 200na, . . . , 200nm of the array to be the positive erased threshold voltage level (Vt2). To establish this, the voltage levels for the word lines WL, the global bit lines GBL, the global source lines GSL, the bit line select gating lines SGB, and the source line select gating lines SGS are shown in the row for the array pre-program of FIG. 10b.

The charge-retaining transistors M0 and M1 of the three-dimensional NAND-based NOR nonvolatile memory cells 200aa, . . . , 200am, . . . , 200na, . . . , 200nm are erase verified as part of the erasing (Box 402). Each word line is set to the minimum voltage level of the third threshold voltage level (Vt2 min) for determining that each of the charge-retaining transistors M0 and M1 of the three-dimensional NAND-based NOR nonvolatile memory cells 200aa, . . . , 200am, . . . , 200na, . . . , 200nm are erased with the global bit lines GBL, the global source lines GSL, the bit line select gating lines SGB, and the source line select gating lines SGS being set as shown in the row for the array pre-program verify of FIG. 10b.

A two page program (Box 416) of a selected paired row of the charge-retaining transistors M0 and M1 of the three-dimensional NAND-based NOR nonvolatile memory cells 200aa, . . . , 200am, . . . , 200na, . . . , 200nm on a selected row to the first threshold voltage level (Vt0) and the second threshold voltage level (Vt1). This is accomplished by setting the voltage levels for the word lines WL, the global bit lines GBL, the global source lines GSL, the bit line select gating lines SGB, and the source line select gating lines SGS are shown in the row for the paired erase of FIG. 10a. This is a two step process where each of the selected charge-retaining transistors M0 and M1 are programmed to the second threshold voltage level (Vt1) and then have a first verify operation where the selected word line WL is set to the maximum voltage level of the second threshold voltage level (Vt1). The unselected word lines WL, global bit lines GBL, the global source lines GSL, the bit line select gating lines SGB, and the source line select gating lines SGS being set as shown in the raw for the paired erase verify of FIG. 10a.

The page programming (Box 416) continues with programming the selected paired row of the charge-retaining transistors M0 and M1 of the three-dimensional NAND-based NOR nonvolatile memory cells 200aa, . . . , 200am, . . . , 200na, . . . , 200nm on a selected row to the first threshold voltage level (Vt0). This is accomplished by setting the voltage levels for the selected and unselected word lines WL, the global bit lines GBL, the global source lines GSL, the bit line select gating lines SGB, and the source line select gating lines SGS are shown in the row for the paired program of FIG. 10a.

The paired row of charge-retaining transistors M0 and M1 of the three-dimensional NAND-based NOR nonvolatile memory cells 200aa, . . . , 200am, . . . , 200na, . . . , 200nm are program verified as part of the programming (Box 416). Each paired word line is ground reference voltage level (0.0V) for determining that each of the charge-retaining transistors M0 and M1 of the three-dimensional NAND-based NOR nonvolatile memory cells 200aa, . . . , 200am, . . . , 200na, . . . , 200nm are programmed to the first threshold voltage level (0.0V). The unselected word lines WL, global bit lines GBL, the global source lines GSL, the bit line select gating lines SGB, and the source line select gating lines SGS being set as shown in the row for the page program verify of FIG. 10b.

The process examines (Box 418) if the last paired row of the charge-retaining transistors M0 and M1 of the three-dimensional NAND-based NOR nonvolatile memory cells 200aa, . . . , 200am, . . . , 200na, . . . , 200nm have been written. If they have not been written, the next paired row of the charge-retaining transistors M0 and M1 are selected (Box 420) and written as described above. When all the selected charge-retaining transistors M0 and M1 of the three-dimensional NAND-based NOR nonvolatile memory cells 200aa, . . . , 200am, . . . , 200na, . . . , 200nm are written the process ends (Box 422).

The chart of FIG. 10b further includes the necessary voltages levels that are applied to the charge-retaining transistors M0 and M1 of the three-dimensional NAND-based NOR nonvolatile memory cells 200aa, . . . , 200am, . . . , 200na, . . . , 200nm for reading the data contained in a selected row or page of the three-dimensional NAND-based NOR nonvolatile memory cells 200aa, . . . , 200am, . . . , 200na, . . . , 200nm. The read is accomplished by setting the voltage levels for the selected and unselected word lines WL, the global bit lines GBL, the global source lines GSL, the bit line select gating lines SGB, and the source line select gating lines SGS are shown in the row for the read of FIG. 10a.

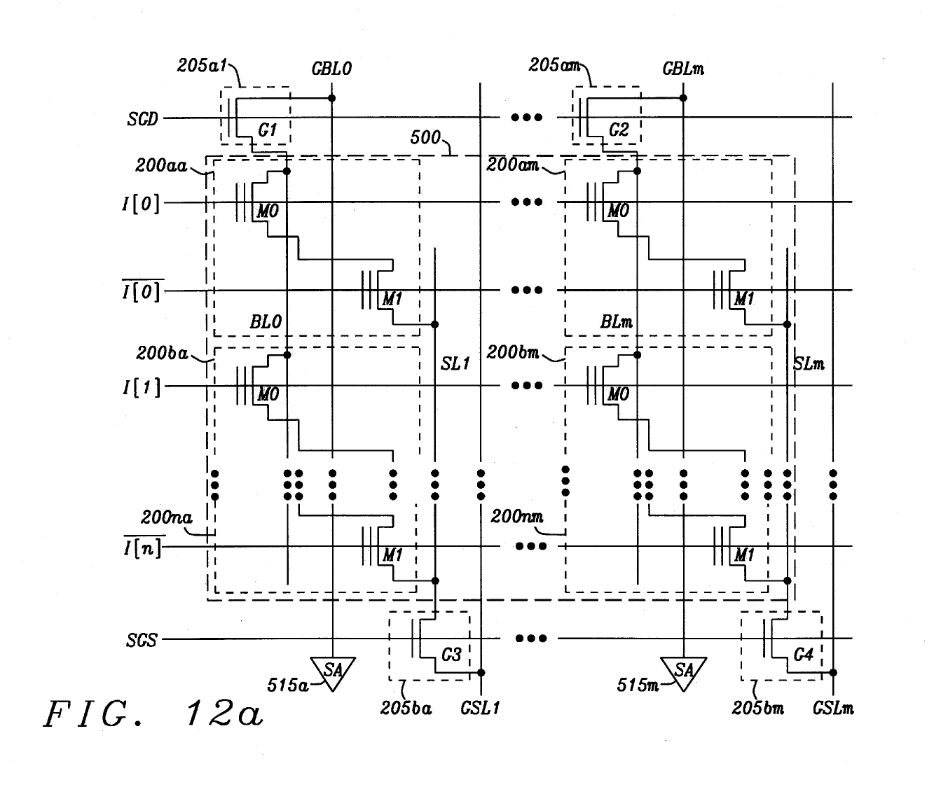

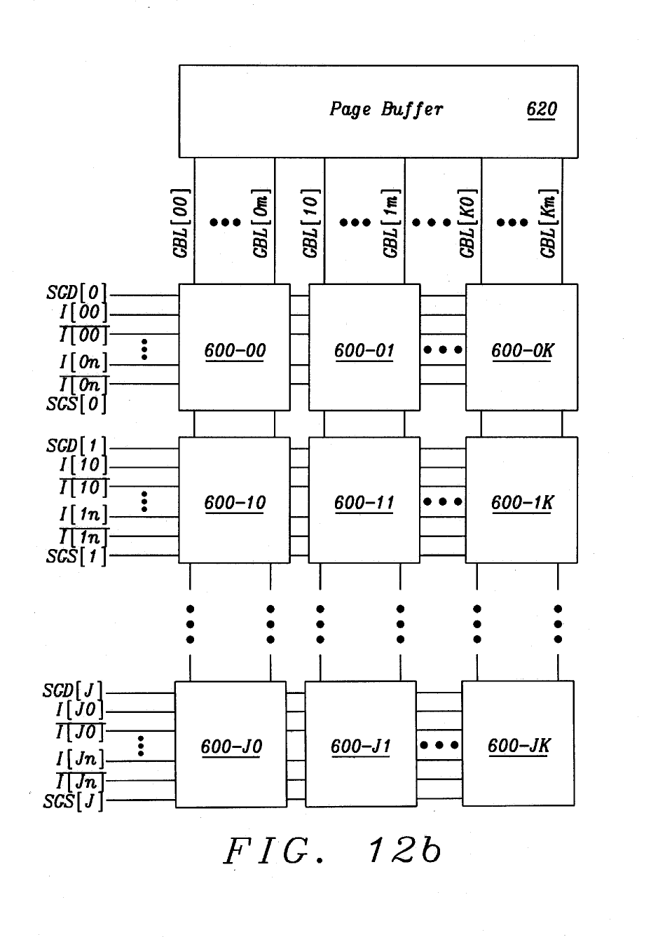

FIG. 11a is a top plan view of a three-dimensional NAND-based NOR nonvolatile PLD cell employing the three-dimensional NAND-based NOR nonvolatile PLD cell as described above for FIGS. 5a-5d. FIG. 11b is a schematic diagram of a three-dimensional NAND-based NOR nonvolatile PLD cell as described above for FIGS. 5a-5d. The three-dimensional NAND-based NOR nonvolatile PLD cell 200 is structurally and dimensionally identical to the three-dimensional NAND-based NOR nonvolatile memory cell of FIGS. 5a-5d. The polycrystalline silicon layers 207a and 207b form the control gates of the three-dimensional charge-retaining transistors M0 and M1 of the three-dimensional NAND-based NOR nonvolatile PLD cell 200 are connected to the primary input I[N] and inverse primary input I̅[̅N̅]̅. The primary input I[N] and inverse primary input I̅[̅N̅]̅ are the in-phase and out-of-phase of the logic variable signal applied to the control gates of the three-dimensional charge-retaining transistors M0 and M1 of the three-dimensional NAND-based NOR nonvolatile PLD cell 200.

FIG. 11c is a plot of the program and erase threshold voltage levels for the three-dimensional charge-retaining transistors M0 and M1 of the three-dimensional NAND-based NOR nonvolatile memory cells 200 of FIGS. 11a-11b. The program threshold voltage level (Vt1) is assigned to be a positive threshold voltage level of approximately 0.7V with a variation of +/−0.5V for applications having voltage level. The erase threshold voltage level (Vt0) is assigned a negative threshold voltage level of approximately −2.0V nominally with a maximum negative threshold voltage level of −1.5V. If it any more negative, the negative threshold voltage level is a “don't care” state. The primary input I[N] and inverse primary input I̅[̅N̅]̅ being at opposing states causes the threshold voltage levels of three-dimensional charge-retaining transistors M0 and M1 to be at opposite states. That is, when the three-dimensional charge-retaining transistor M0 has a threshold voltage level of the erased threshold voltage level (Vt0), the three-dimensional charge-retaining transistor M1 has a threshold voltage level of the programmed threshold voltage level (Vt1). Similarly, when the three-dimensional charge-retaining transistor M0 has a threshold voltage level of the programmed threshold voltage level (Vt1), the three-dimensional charge-retaining transistor M1 has a threshold voltage level of the erased threshold voltage level (Vt1).

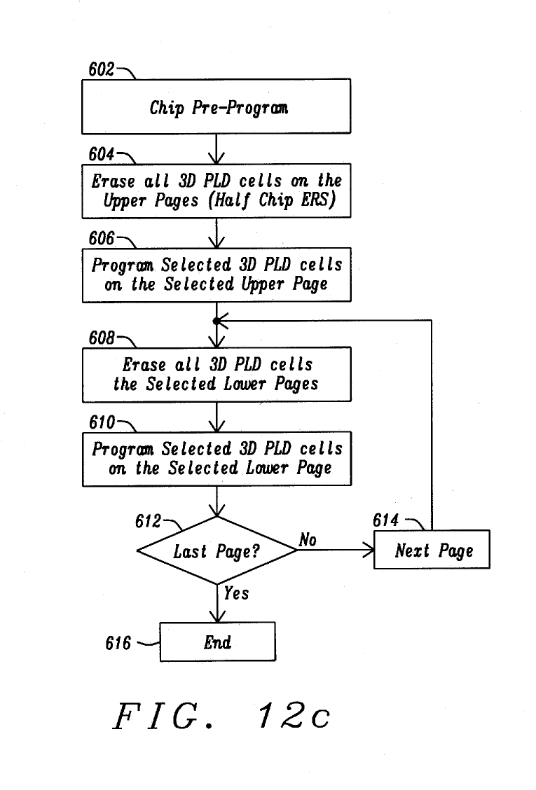

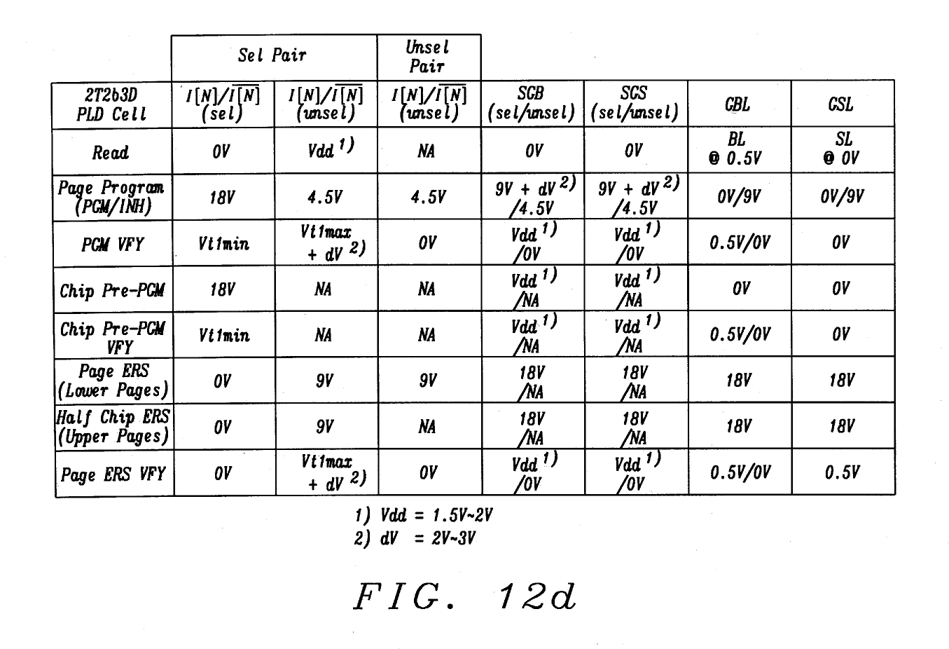

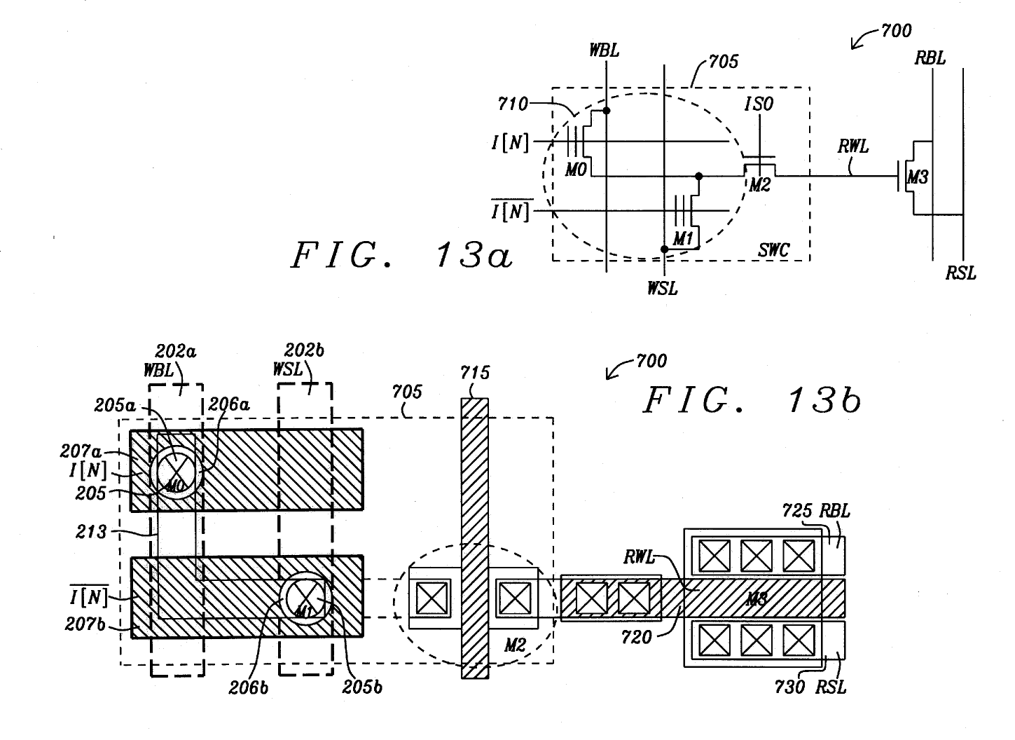

FIG. 12a is a schematic diagram of an array 300 of three-dimensional NAND-based NOR nonvolatile PLD cells 200aa, . . . , 200am, . . . , 200na, . . . , 200nm as described above for FIGS. 11a and 11b. The array structure is equivalent to that of FIG. 8a. The difference being that the word lines WL0, . . . , WLn of FIG. 8a is replaced with the primary inputs I[0], . . . , I[n] and inverse primary inputs I̅[̅0̅]̅, . . . , I̅[̅n̅]̅. The primary inputs I[0], . . . , I[n] and inverse primary inputs I̅[̅0̅]̅, . . . I̅[̅n̅]̅ are paired in-phase and out-of-phase of the logic variable signals applied to the array 300.

As in FIG. 8a, the drain of each the charge-retaining transistors M0 are connected to a local bit line BL0, . . . , BLm. The source of each of the charge-retaining transistors M1 are connected to a local source line SL0, . . . , SLm. The local bit lines BL0, . . . , BLm and the local source lines SL0, . . . , SLm are N+ active diffusion layers placed beneath each of the three-dimensional NAND-based NOR nonvolatile PLD cells 200aa, . . . , 200am, . . . , 200na, . . . , 200nm. Each of the local bit lines BL0, . . . , BLm and the local source lines SL0, . . . , SLm are associated with one column of the three-dimensional NAND-based NOR nonvolatile PLD cells 200aa, . . . , 200am, . . . , 200na, 200nm.

Each of the local bit lines BL0, . . . , BLm are connected to the source of one of the select gating transistors 205a0, . . . , 205am. Each drain of select gating transistors 205a0, . . . , 205am are connected to a global bit line GBL0, . . . , GBLm associated with each column of the three-dimensional NAND-based NOR nonvolatile PLD cells 200aa, . . . , 200am, . . . , 200na, . . . , 200nm. Each of the local source lines SL0, . . . , SLm are connected to the source of one of the select gating transistors 205b0, . . . , 205bm. Each drain of select gating transistors 205b0, . . . , 205bm are connected to a global source line GSL0, . . . , GSLm associated with each column of the three-dimensional NAND-based NOR nonvolatile PLD cells 200aa, . . . , 200am, . . . , 200na, . . . , 200nm. The global bit lines GBL0, . . . , GBLm and the write source lines GSL0, . . . , GSLm are connected to a column control circuit that provides the circuitry for generating the necessary voltage levels necessary for reading, programming, erasing and verifying the programming and erasing of selected three-dimensional NAND-based NOR nonvolatile PLD cells 200aa, . . . , 200am, . . . , 200na, . . . , 200nm. Each of the global bit lines GBL0, . . . , GBLm are connected to a sense amplifier 515a, . . . , 515m. In a read operation where a logic operation being performed with the primary inputs I[0], . . . , I[n] and inverse primary inputs I̅[̅0̅]̅, . . . , I̅[̅n̅]̅, the sense amplifiers 515a, . . . , 515m determine the logic state of each of the columns of the three-dimensional NAND-based NOR nonvolatile PLD cells 200aa, . . . , 200am, . . . , 200na, . . . , 200nm. In various embodiments, the sense amplifiers 515a, . . . , 515m include a resistor that is connected between the drain of the charge-retaining transistors M0 through the local bit lines BL0, . . . , BLm and the global bit lines GBL0, . . . , GBLm. The opposite end of the resistor is connected to the power supply voltage source VDD such that each column of the three-dimensional NAND-based NOR nonvolatile PLD cells 200aa, . . . , 200am, . . . , 200na, . . . , 200nm functions as an AND gate with a common drain configuration. The end of each resistors connected to each global bit line GBL0, . . . , GBLm is connected to an inverter (not shown) for connection to other circuitry.

The gates of the select gating transistors 205a1, . . . , 205am are connected to a select bit line gating signal SGD generated by the row control circuitry (not shown) to activate the select gating transistors 205a1, . . . , 205am. The select gating transistors 205a1, . . . , 205am control connecting the drains of the charge-retaining transistors M0 of the columns of the three-dimensional NAND-based NOR nonvolatile PLD cells 200aa, . . . , 200am, . . . , 200na, . . . , 200nm to the column control circuitry including the sense amplifiers 515a, . . . , 515m. The gates of the select gating transistors 205b1, . . . , 205bm is connected to a select source line gating signal SGS generated by the row control circuitry (not shown) to activate the select gating transistors 205a1, . . . , 205am. The select gating transistors 205b1, . . . , 205bm control connecting the sources of the charge-retaining transistors M1 of the columns of the three-dimensional NAND-based NOR nonvolatile PLD cells 200aa, . . . , 200am, . . . , 200na, . . . , 200nm to the column control circuitry.

FIG. 12b is a block diagram of multiple arrays 600-00, . . . , 600-0K, . . . , 600-J0, . . . , 600-JK of the three-dimensional NAND-based NOR nonvolatile PLD cells 200aa, . . . , 200am, . . . , 200na, . . . , 200nm of FIG. 12a. Each of the arrays 600-00, . . . , 600-0K, . . . , 600-J0, . . . , 600-JK of the three-dimensional NAND-based NOR nonvolatile PLD cells represents a block of the cells. The arrays or blocks 600-00, . . . , 600-0K, . . . , 600-J0, . . . , 600-JK of the three-dimensional NAND-based NOR nonvolatile PLD cells 200aa, . . . , 200am, . . . , 200na, . . . , 200nm are arranged in rows and columns.

Each row of the blocks 600-00, . . . , 600-0K, . . . , 600-J0, . . . , 600-JK of the three-dimensional NAND-based NOR nonvolatile PLD cells 200aa, . . . , 200am, . . . , 200na, . . . , 200nm is connected to receive the select bit line gating signals SGD[0], . . . , SGD[J] and the select source line gating signals SGS[0], . . . , SCS[J]. The rows of blocks 600-00, . . . , 600-0K, . . . , 600-J0, . . . , 600-JK each have primary inputs I[00], . . . , I[0n], . . . , I[J0], . . . , I[Jn] and inverse primary inputs I̅[̅0̅0̅]̅, . . . , I̅[̅0̅n̅]̅, . . . , I̅[̅J̅0̅]̅, . . . , I̅[̅J̅n̅]̅. Each of the primary inputs I[00], . . . , I[0n], . . . , I[J0], . . . , I[Jn] and inverse primary inputs I̅[̅0̅0̅]̅, . . . , I̅[̅0̅n̅]̅, . . . , I̅[̅J̅0̅]̅, . . . , I̅[̅n̅]̅ may be separate inputs or common inputs across each of the rows of blocks 600-00, . . . , 600-0K, . . . , 600-J0, . . . , 600-JK.

The global bit lines GBL[00], . . . , GBL[0m], . . . , GBL[K0], . . . , GBL[Km] originating with each column of the blocks the blocks 600-00, . . . , 600-0K, . . . , 600-J0, . . . , 600-JK of the three-dimensional NAND-based NOR nonvolatile PLD cells 200aa, 200am, . . . , 200na, . . . , 200nm is connected to a page buffer 620 to retain the logic states determined by the columns of the three-dimensional NAND-based NOR nonvolatile PLD cells 200aa, . . . , 200am, . . . , 200na, . . . , 200nm of each of the blocks 600-00, . . . , 600-0K, . . . , 600-J0, . . . , 600-JK.

FIG. 12c is a flowchart for a method of operation of a three-dimensional NAND-based NOR nonvolatile PLD array 300 of FIG. 12a. FIG. 12d is a chart of voltage levels for operating with the method of FIG. 12c a three-dimensional NAND-based NOR nonvolatile PLD array 300 of FIG. 12a. Referring to FIGS. 12a, 12c, and 12d, the method of operating the array of three-dimensional NAND-based NOR nonvolatile PLD cells begins with pre-programming (Box 602) the array of three-dimensional NAND-based NOR nonvolatile PLD cells 200aa, . . . , 200am, . . . , 200na, . . . , 200nm. The pre-programming operation (Box 602) establishes the voltage thresholds of all the charge-retaining transistors M0 and M1 of the three-dimensional NAND-based NOR nonvolatile PLD cells 200aa, . . . , 200am, . . . , 200na, . . . , 200nm of the array to be set at the positive programmed threshold voltage level. To establish this, the voltage levels for the primary input I[N], inverse primary input I̅[̅N̅]̅, the global bit lines GBL, the global source lines GSL, the bit line select gating lines SGB, and the source line select gating lines SGS are shown in the row for the array pre-program of FIG. 12d.

The charge-retaining transistors M0 and M1 of the three-dimensional NAND-based NOR nonvolatile PLD cells 200aa, . . . , 200am, . . . , 200na, . . . , 200nm are pre-program verified as part of the pre-programming operation (Box 602). Each word line is set to the minimum voltage level of the third threshold voltage level (Vt2min) for determining that each of the charge-retaining transistors M0 and M1 of the three-dimensional NAND-based NOR nonvolatile PLD cells 200aa, . . . , 200am, . . . , 200na, 200nm are pre-programmed with the global bit lines GBL, the global source lines GSL, the bit line select gating lines SGB, and the source line select gating lines SGS being set as shown in the row for the array pre-program verify of FIG. 12d.

The write process begins with erasing (Box 604) a selected upper row of the charge-retaining transistors M0 of the three-dimensional NAND-based NOR nonvolatile PLD cells 200aa, . . . , 200am, . . . , 200na, . . . , 200nm on a selected row to the first threshold voltage level (Vt0). This is accomplished by setting the voltage levels for the primary input I[N], inverse primary input I̅[̅N̅]̅, the global bit lines GBL, the global bit lines GBL, the global source lines GSL, the bit line select gating lines SGB, and the source line select gating lines SGS are shown in the row for the paired erase of FIG. 12d.

The upper row of charge-retaining transistors M0 and M1 of the three-dimensional NAND-based NOR nonvolatile PLD cells 200aa, . . . , 200am, . . . , 200na, . . . , 200nm are erase verified as part of the erasing (Box 604). Each paired word line is set to the ground reference voltage level (0.0V) for determining that each of the charge-retaining transistors M0 and M1 of the three-dimensional NAND-based NOR nonvolatile PLD cells 200aa, . . . , 200am, . . . , 200na, . . . , 200nm are erased with the unselected primary input I[N], inverse primary input I̅[̅N̅]̅, the global bit lines GBL, the global source lines GSL, the bit line select gating lines SGB, and the source line select gating lines SGS being set as shown in the row for the paired erase verify of FIG. 12d.

The write process continues with programming (Box 606) selected charge-retaining transistors M0 of a selected upper row of the three-dimensional NAND-based NOR nonvolatile PLD cells 200aa, . . . , 200am, . . . , 200na, . . . , 200nm to the second threshold voltage level (Vt1). This is accomplished by setting the voltage levels for the selected and unselected primary input I[N], inverse primary input I̅[̅N̅]̅, the global bit lines GBL, the global bit lines GBL, the global source lines GSL, the bit line select gating lines SGB, and the source line select gating lines SGS are shown in the row for the paired erase of FIG. 12d.

The upper row of charge-retaining transistors of the three-dimensional NAND-based NOR nonvolatile PLD cells 200aa, . . . , 200am, . . . , 200na, . . . , 200nm are program verified as part of the programming (Box 606). Each paired word line is iteratively set to the minimum value of the second threshold voltage level (Vt1min) followed by minimum value of the third threshold voltage level (Vt2min) for determining that each of the charge-retaining transistors M0 of the three-dimensional NAND-based NOR nonvolatile PLD cells 200aa, . . . , 200am, . . . , 200na, . . . , 200nm are programmed with the unselected primary input I[N], inverse primary input I̅[̅N̅]̅, the global bit lines GBL, the global source lines GSL, the bit line select gating lines SGB, and the source line select gating lines SGS being set as shown in the row for the paired erase verify of FIG. 12d.

The write process continues with erasing (Box 608) a selected lower row of the charge-retaining transistors M1 of the three-dimensional NAND-based NOR nonvolatile PLD cells 200aa, . . . , 200am, . . . , 200na, . . . , 200nm on a selected row to the first threshold voltage level (Vt0). This is accomplished by setting the voltage levels for the primary input I[N], inverse primary input I[N], the global bit lines GBL, the global bit lines GBL, the global source lines GSL, the bit line select gating lines SGB, and the source line select gating lines SGS are shown in the row for the paired erase of FIG. 12d.

The lower row of charge-retaining transistors M0 and M1 of the three-dimensional NAND-based NOR nonvolatile PLD cells 200aa, . . . , 200am, . . . , 200na, . . . , 200nm are erase verified as part of the erasing (Box 608). Each paired word line is set to the ground reference voltage level (0.0V) for determining that each of the charge-retaining transistors M0 and M1 of the three-dimensional NAND-based NOR nonvolatile PLD cells 200aa, . . . , 200am, . . . , 200na, . . . , 200nm are erased with the unselected primary input I[N], inverse primary input I̅[̅N̅]̅, the global bit lines GBL, the global source lines GSL, the bit line select gating lines SGB, and the source line select gating lines SGS being set as shown in the row for the paired erase verify of FIG. 12d.

The write process continues with programming (Box 610) selected charge-retaining transistors M1 of a selected lower row of the three-dimensional NAND-based NOR nonvolatile PLD cells 200aa, . . . , 200am, . . . , 200na, . . . , 200nm to the second threshold voltage level (Vt1). This is accomplished by setting the voltage levels for the selected and unselected primary input I[N], inverse primary input I̅[̅N̅]̅, the global bit lines GBL, the global bit lines GBL, the global source lines GSL, the bit line select gating lines SGB, and the source line select gating lines SGS are shown in the row for the paired erase of FIG. 12d.

The lower row of charge-retaining transistors of the three-dimensional NAND-based NOR nonvolatile PLD cells 200aa, . . . , 200am, . . . , 200na, . . . , 200nm are program verified as part of the programming (Box 610). Each paired word line is iteratively set to the minimum value of the second threshold voltage level (Vt1min) followed by minimum value of the third threshold voltage level (Vt2min) for determining that each of the charge-retaining transistors M0 of the three-dimensional NAND-based NOR nonvolatile PLD cells 200aa, . . . , 200am, . . . , 200na, . . . , 200nm are programmed with the unselected primary input I[N], inverse primary input I̅[̅N̅]̅, the global bit lines GBL, the global source lines GSL, the bit line select gating lines SGB, and the source line select gating lines SGS being set as shown in the row for the paired program verify of FIG. 12d.

The process examines (Box 612) if the last paired row of the charge-retaining transistors M0 and M1 of the three-dimensional NAND-based NOR nonvolatile PLD cells 200aa, . . . , 200am, . . . , 200na, . . . , 200nm have been written. If they have not been written, the next paired row of the charge-retaining transistors M0 and M1 are selected (Box 614) and written as described above. When all the selected charge-retaining transistors M0 and M1 of the three-dimensional NAND-based NOR nonvolatile PLD cells 200aa, . . . , 200am, . . . , 200na, . . . , 200nm are written the process ends (Box 616).

The chart of FIG. 12d further includes the necessary voltages levels that are applied to the charge-retaining transistors M0 and M1 of the three-dimensional NAND-based NOR nonvolatile PLD cells 200aa, . . . , 200am, . . . , 200na, . . . , 200nm for reading the data contained in a selected row or page of the three-dimensional NAND-based NOR nonvolatile PLD cells 200aa, . . . , 200am, . . . , 200na, . . . , 200nm. The read is accomplished by setting the voltage levels for the selected and unselected word lines WL, the global bit lines GBL, the global source lines GSL, the bit line select gating lines SGB, and the source line select gating lines SGS are shown in the row for the read of FIG. 112d.

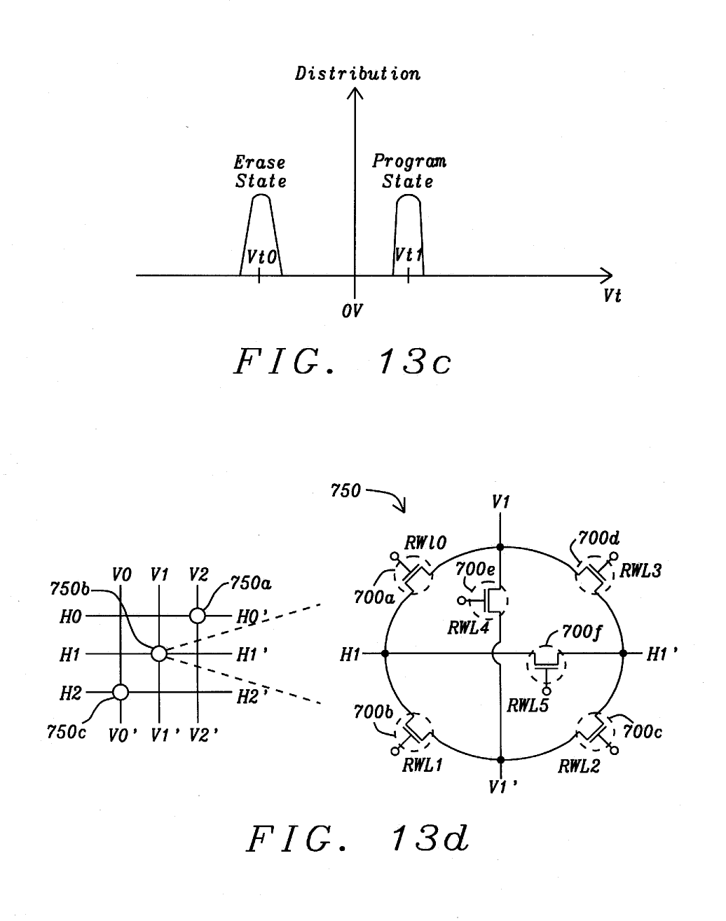

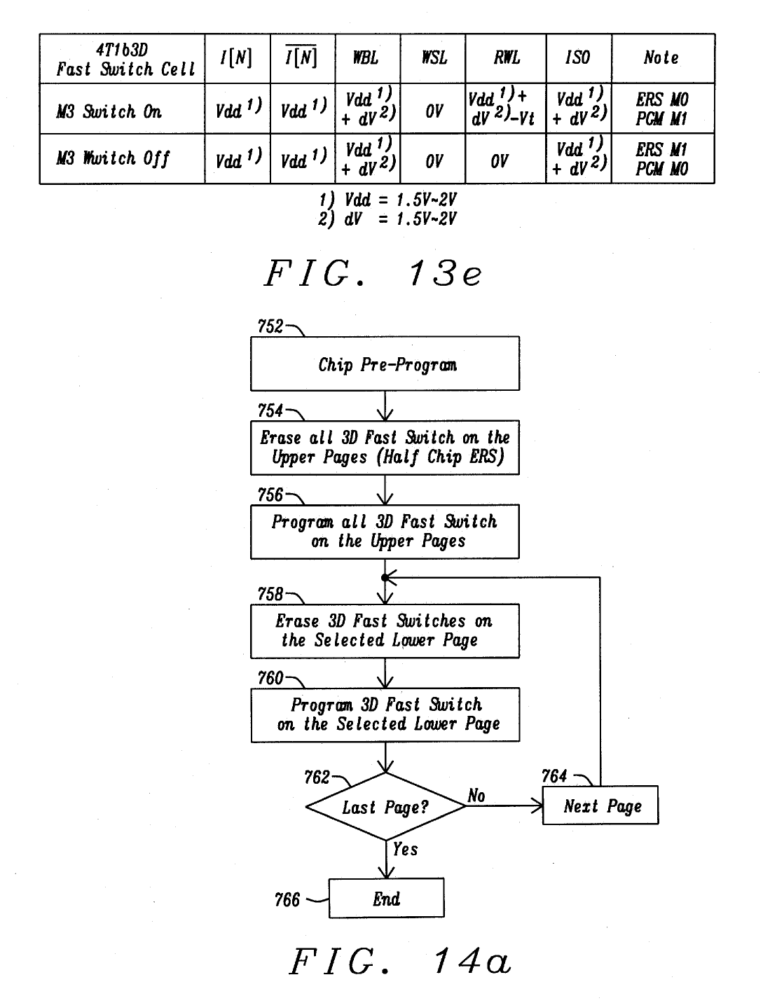

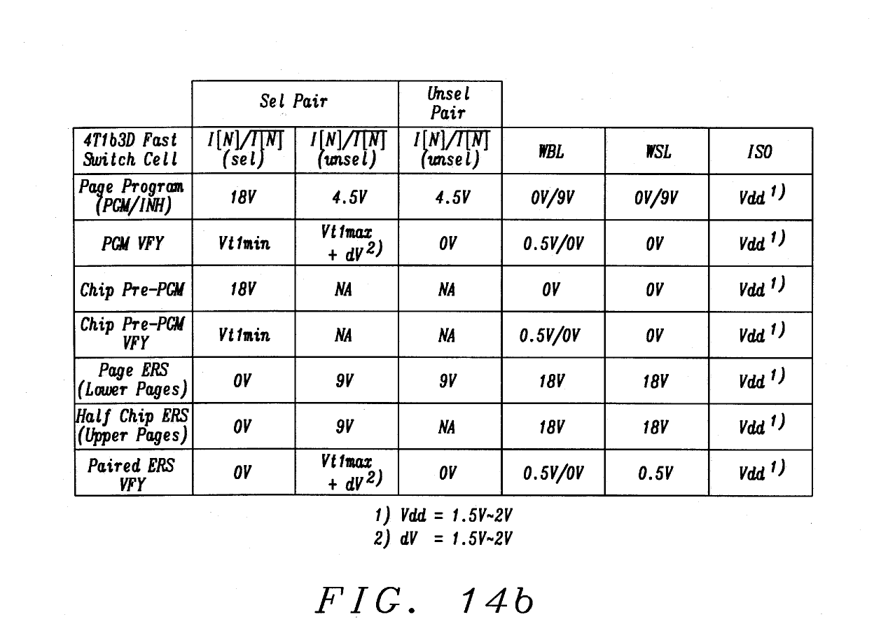

FIG. 13a is a schematic diagram of a three-dimensional NAND-based NOR flash nonvolatile reconfigurable switching circuit 700 for a low-resistance switching application for fast connections in an FPGA application. The three-dimensional NAND-based NOR flash nonvolatile reconfigurable switching circuit has a switching transistor M3 having a drain connected to a read bit line RBL and a source connected to a read source line RSL to selectively connect the read bit line RBL to the read source line RSL for transferring a logic value signal between the read bit line RBL to the read source line RSL. A switch control circuit 705 connected through a read word line RWL to a gate of the switching transistor M3 turns on or turns off the switching transistor M3 to selectively connect the read bit line RBL to the read source line RSL based on a program state of the switch control circuit. If the switching transistor M3 is activated, a logic value signal from the read source line RSL is connected to the logic function circuit connected to the read bit line RBL. Alternately, if the switching transistor M3 is deactivated, the logic value signal from the read source line RSL is not connected to the logic function circuit connected to the read bit line RBL. It should be noted that the logic value signal may in fact be transferred from the read bit line RBL to the read source line RSL and still be in keeping with the principles of this invention.

The switch control circuit 705 is formed of a NAND-based NOR flash memory cell 710 having a pair of serially connected charge-retaining transistors M0 and M1 connected such that a drain a first charge-retaining transistor M0 is connected to a write bit line WBL. A source of a second charge-retaining transistor M1 is connected to a write source line WSL. The source of the first charge-retaining transistor M0 and the drain of the second charge-retaining transistors M1 are merged together. A select gating transistor M2 has a drain connected to the merged source of the first charge-retaining transistor M0 and the drain of the second charge-retaining transistors M1. A source of the select gating transistor M2 is connected to read word line RWL and thus to a gate of the switching transistor M3. A gate of the select gating transistor M2 is connected to an Isolation gating terminal ISO. The select gating transistor M2 is used to prevent damage from high voltage applied to the switching transistor M3 during program/erase operations. The high speed requirement in the read mode forces the switching transistor M3 to be made of a low voltage device with thinner oxide thickness. A gate of the first charge-retaining transistor M0 is connected to a primary input I[N] and the gate of the second charge-retaining transistor M1 is connected to an inverse primary input I̅[̅N̅]̅.

FIG. 13b is a top plan view of the three-dimensional NAND-based NOR flash nonvolatile reconfigurable switching circuit of FIG. 13a. The fundamental structure of the NAND-based NOR flash memory cell 710 is essentially as described above for FIGS. 5a, 5c, and 5d. The three-dimensional charge-retaining transistors M0 and M1 are formed as a cylindrical doped silicon structures. The drain of the three-dimensional charge-retaining transistor M0 and the source of the three-dimensional charge-retaining transistor M1 are N+ active diffusion layers formed respectively on a write bit line WBL that is an N+ active diffusion layer and a write source line WSL that is an N+ active diffusion layer within the surface of the substrate and connected to column control circuitry (not shown). The bulks of the three-dimensional charge-retaining transistors M0 and M1 are respectively formed of the P− diffusion layers that are formed immediately above the drain and source N+ active diffusions. The source of the three-dimensional charge-retaining transistor M0 and the drain three-dimensional charge-retaining transistor M1 are then respectively formed immediately above as the second N+ active diffusion layers 205a and 205b on the bulk P− diffusion layers. Insulating SONOS layers 206a and 206b are respectively formed to surround the bulk is formed of the P− diffusion layers 204a and 204b. Polycrystalline silicon layers 207a and 207b are formed around the insulating SONOS layers 206a and 206b to respectively create the control gates of the three-dimensional charge-retaining transistors M0 and M1. The control gates 207a and 207b are merged respectively with the primary input I[N], inverse primary input I̅[̅N̅]̅ as a polycrystalline silicon layer extending from row control circuitry (not shown).

A metal layer 213 is connector strap that joins the source N+ active diffusion layer 205a of the three-dimensional charge-retaining transistor M0 and drain N+ active diffusion layer 205b of the three-dimensional charge-retaining transistor M1. The metal layer 213 has a metal extension 713 that connects to the drain of the select gating transistor M2. The gate of the select gating transistor M2 is formed of the polycrystalline silicon layer 715 that is connected to external circuitry (not shown) to receive the isolation signal ISO. The source of the select gating transistor M2 is connected to the read word line 720. The read word line is a polycrystalline silicon layer 720 that extends to form the gate of the switching transistor M3. The drain of the switching transistor M3 is connected to the metal layer 725 that forms the read bit line RBL. The source of the switching transistor M3 is connected to the metal layer 730 that forms the read source line RSL.

FIG. 13c is a plot of the program and erase threshold voltage distributions of the three-dimensional NAND-based NOR flash nonvolatile reconfigurable switching circuit of FIG. 13a. The program threshold voltage level (Vt1) is assigned to be a positive threshold voltage level of approximately 0.7V with a variation of +/−0.5V for applications having voltage level of the power supply voltage source (VDD) of approximately 1.2V. If the voltage level of the power supply voltage source (VDD) is approximately 1.5V, the positive threshold voltage level (Vt1) is assigned to be approximately 1.0V with a variation of +/−0.5V. The erase threshold voltage level (Vt0) is assigned a negative threshold voltage level of approximately −2.0V nominally with a maximum negative threshold voltage level of −1.5V. If it any more negative, the negative threshold voltage level is a “don't care” state.

FIG. 13d is a diagram of an application within an FPGA of the three-dimensional NAND-based NOR flash nonvolatile reconfigurable switching circuit of FIG. 13a. A switching array is formed such that input conductors V0, V1, V2, V0′, V1′, V2′ are provided vertically top and bottom and output conductors H0, H1, H2, H0′, H1′, H2′ are provided horizontally side-to-side. This configuration is exemplary and the input conductors V0, V1, V2, V0′, VV, V2′ versus the output conductors H0, H1, H2, H0′, H1′, H2′ may be any suitable configuration and be in keeping with the principles of this invention. A cluster switch 750a, 750b, 750c of the three-dimensional NAND-based NOR flash nonvolatile reconfigurable switching circuits 700 of FIGS. 13a and 13b are placed at each intersection of the input conductors V0, V1, V2, V0′, V1′, V2′ and the output conductors H0, H1, H2, H0′, H1′, H2′. Each of the input conductors V0, V1, V2, V0′, VV, V2′ and the output conductors H0, H1, H2, H0′, H1′, H2′ may be connected to any of the six input conductors V0, V1, V2, V0′, VV, V2′ and the six output conductors H0, H1, H2, H0′, H1′, H2′ present at the intersection. For instance the input conductors V1, V1′ and the output conductors H1, H1′ are connected to the cluster switch 750b. In various embodiments of the cluster switch 750 is formed of six the three-dimensional NAND-based NOR flash nonvolatile reconfigurable switching circuits 700a, 700b, 700f. In the diagram each of the three-dimensional NAND-based NOR flash nonvolatile reconfigurable switching circuits 700a, 700b, . . . , 700f are shown as the switching transistor M3 with the read word line RWL connected to the gate of the switching transistor M3. The read word lines RWL0, RWL1, . . . , RWL5 are connected to the switch control circuit 700 (not shown) for the switching transistor M3 of the three-dimensional NAND-based NOR flash nonvolatile reconfigurable switching circuits 700a, 700b, . . . , 700f.

Each of the input conductors V0, V1, V2, V0′, VV, V2′ and the output conductors H0, H1, H2, H0′, H1′, H2′ at one intersection are connected to a cluster switch 750. One of the three-dimensional NAND-based NOR flash nonvolatile reconfigurable switching circuits 700a, 700b, . . . , 700f is connected from one of the input conductors V0, V1, V2, V0′, VV, V2′ to its complementary input conductor V0, V1, V2, V0′, VV, V2′ and the associated output conductors H0, H1, H2, H0′, H1′, H2′. For example, with the input conductors V1, V1′ and the output conductors H1, H1′ that are connected to the cluster switch 750b, the input conductor V1 is connected through the three-dimensional NAND-based NOR flash nonvolatile reconfigurable switching circuits 700a to the output conductor H1. The input conductor V1 is connected through the three-dimensional NAND-based NOR flash nonvolatile reconfigurable switching circuits 700d to the output conductor H1′. The input conductor V1 is connected through the three-dimensional NAND-based NOR flash nonvolatile reconfigurable switching circuits 700e to the input conductor VV. The input conductor V1′ is connected through the three-dimensional NAND-based NOR flash nonvolatile reconfigurable switching circuits 700b to the output conductor H1. The input conductor V1 is connected through the three-dimensional NAND-based NOR flash nonvolatile reconfigurable switching circuits 700c to the output conductor H1′. The output conductor H1 is connected through the three-dimensional NAND-based NOR flash nonvolatile reconfigurable switching circuits 700f to the output conductor H1′. This structure enable any of the input conductors V0, V1, V2, V0′, VV, V2′ and the output conductors H0, H1, H2, H0′, H1′, H2′ to be interconnected with their associated input conductors V0, V1, V2, V0′, VV, V2′ and the output conductors H0, H1, H2, H0′, H1′, H2′.

In order to insure a connection that is sufficiently low in resistance, the switching transistor M3 must be turned on to pass the full swing of the voltage levels of the power supply voltage source VDD or the ground reference voltage VSS. To accomplish this, the voltage at the read word lines RWL0, RWL1, . . . , RWL5 connected to the input conductors V0, V1, V2, V′0, V′1, V′2 and the output conductors H0, H1, H2, H′0, H′1, H′2 must be greater than the power supply voltage source VDD by a differential voltage dv of from approximately 1.5V to approximately 2.0V. For those of the input conductors V0, V1, V2, V′0, V′1, V′2 and the output conductors H0, H1, H2, H′0, H′1, H′2 that are not to be connected, the switching transistor M3 completely turned off. Therefore, the read word lines RWL0, RWL1, . . . , RWL5 are connected to the ground reference voltage level VSS. This insures that the deactivated switching transistor M3 are non-conducting with a very large mega-ohm impedance.

FIG. 13e is a chart for the voltage levels for functional operation of the three-dimensional NAND-based NOR flash nonvolatile reconfigurable switching circuit 700 of FIG. 13a. In order to connect any of the associated input conductors V0, V1, V2, V′0, V′1, V′2 or the associated output conductors H0, H1, H2, H′0, H′1, H′2 to an associated input conductor V0, V1, V2, V′0, VI, V′2 or the output conductor H0, H1, H2, H′0, H′1, H′2, the switching transistor must be turned on. The operational voltages are as shown in the first row of table of FIG. 13e. In order to disconnect any of the associated input conductors V0, V1, V2, V′0, V′1, V′2 or the associated output conductors H0, H1, H2, H′0, H′1, H′2 to an associated input conductor V0, V1, V2, V′0, V′1, V′2 or the output conductor H0, H1, H2, H′0, H′1, H′2, the switching transistor must be turned off. The operational voltages are as shown in the second row of table of FIG. 13e.

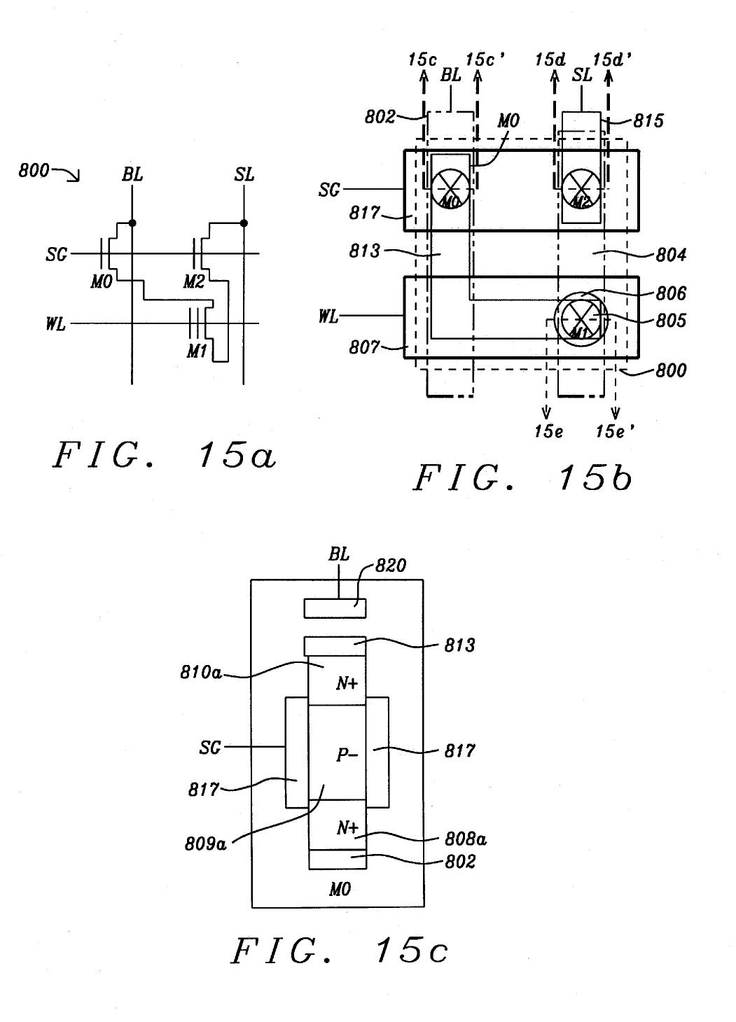

FIG. 14a is a flow chart for a method for programming and erasing the three-dimensional NAND-based NOR flash nonvolatile reconfigurable switching circuit of FIG. 13a. FIG. 14b is a chart of programming and erasing voltage levels of the three-dimensional NAND-based NOR flash nonvolatile reconfigurable switching circuit of FIG. 13a.

Referring to FIGS. 13a, 13d, 14a, and 14b, the method of programming and erasing an array of cluster switches 700 begins with pre-programming (Box 752) the array of three-dimensional NAND-based NOR flash nonvolatile reconfigurable switching circuits 700aa, . . . , 700am, . . . , 700na, . . . , 700nm. The pre-programming operation (Box 752) establishes the voltage thresholds of all the charge-retaining transistors M0 and M1 of the three-dimensional NAND-based NOR flash nonvolatile reconfigurable switching circuit 700aa, . . . , 700am, . . . , 700na, . . . , 700nm of the array to be set at the positive programmed threshold voltage level Vt1. To establish this, the voltage levels for the primary input I[N], inverse primary input I̅[̅N̅]̅, the write bit lines WBL, the write source lines WSL, and the isolation signal ISO are shown in the row for the array pre-program of FIG. 14b.

The charge-retaining transistors M0 and M1 of the three-dimensional NAND-based NOR flash nonvolatile reconfigurable switching circuit 700aa, . . . , 700am, . . . , 700na, . . . , 700nm are pre-program verified as part of the pre-programming operation (Box 752). Each word line is set to the minimum voltage level of the programmed threshold voltage level (Vt1min) for determining that each of the charge-retaining transistors M0 and M1 of the three-dimensional NAND-based NOR flash nonvolatile reconfigurable switching circuit 700aa, . . . , 700am, . . . , 700na, . . . , 700nm are pre-programmed with the write bit lines WBL, the write source lines WSL, bit line and the isolation signal ISO being set as shown in the row for the array pre-program verify of FIG. 14b.

The write process begins with erasing (Box 754) a selected upper row of the charge-retaining transistors M0 of the three-dimensional NAND-based NOR flash nonvolatile reconfigurable switching circuit 700aa, . . . , 700am, . . . , 700na, . . . , 700nm on a selected row to the first threshold voltage level (Vt0). This is accomplished by setting the voltage levels for the primary input I[N], inverse primary input I̅[̅N̅]̅, the write bit lines WBL, the write source lines WSL, and the isolation signal ISO are shown in the row for the paired erase of FIG. 14b.

The upper row of charge-retaining transistors M0 and M1 of the three-dimensional NAND-based NOR flash nonvolatile reconfigurable switching circuit 700aa, . . . , 700am, . . . , 700na, . . . , 700nm are page erase verified as part of the erasing (Box 754). Each paired word line is set to the ground reference voltage level (0.0V) for determining that each of the charge-retaining transistors M0 and M1 of the three-dimensional NAND-based NOR flash nonvolatile reconfigurable switching circuit 700aa, . . . , 700am, . . . , 700na, . . . , 700nm are erased with the unselected primary input I[N], inverse primary input I̅[̅N̅]̅, the write bit lines WBL, the write source lines WSL, and the isolation signal ISO being set as shown in the row for the page erase verify of FIG. 14b.

The write process continues with programming (Box 756) selected charge-retaining transistors M0 of a selected upper row of the three-dimensional NAND-based NOR nonvolatile PLD cells 700aa, . . . , 700am, . . . , 700na, . . . , 700nm to the second threshold voltage level (Vt1). This is accomplished by setting the voltage levels for the selected and unselected primary input I[N], inverse primary input I̅[̅N̅]̅, the write bit lines WBL, the write source lines WSL, and the isolation signal ISO are shown in the row for the paired erase of FIG. 14b.

The upper row of charge-retaining transistors of the three-dimensional NAND-based NOR flash nonvolatile reconfigurable switching circuit 700aa, . . . , 700am, . . . , 700na, . . . , 700nm are program verified as part of the programming (Box 756). Each paired word line is iteratively set to the minimum value of the second threshold voltage level (Vt1min) for determining that each of the charge-retaining transistors M0 of the three-dimensional NAND-based NOR flash nonvolatile reconfigurable switching circuit 700aa, . . . , 700am, . . . , 700na, . . . , 700nm are programmed with the unselected primary input I[N], inverse primary input I̅[̅N̅]̅, the write bit lines WBL, the write source lines WSL bit line select gating lines SGB, and the isolation signal ISO being set as shown in the row for the page erase verify of FIG. 14b.

The write process continues with erasing (Box 758) a selected lower row of the charge-retaining transistors M1 of the three-dimensional NAND-based NOR flash nonvolatile reconfigurable switching circuit 700aa, . . . , 700am, . . . , 700na, . . . , 700nm on a selected row to the first threshold voltage level (Vt0). This is accomplished by setting the voltage levels for the primary input I[N], inverse primary input I̅[̅N̅]̅, the write bit lines WBL, the write source lines WSL, and the isolation signal ISO are shown in the row for the paired erase of FIG. 14b.

The lower row of charge-retaining transistors M0 and M1 of the three-dimensional NAND-based NOR flash nonvolatile reconfigurable switching circuit 700aa, . . . , 700am, . . . , 700na, . . . , 700nm are page erase verified as part of the erasing (Box 758). Each paired word line is set to the ground reference voltage level (0.0V) for determining that each of the charge-retaining transistors M0 and M1 of the three-dimensional NAND-based NOR flash nonvolatile reconfigurable switching circuit 700aa, . . . , 700am, . . . , 700na, . . . , 700nm are erased with the selected and unselected primary input I[N], inverse primary input I̅[̅N̅]̅, the write bit lines WBL, the write source lines WSL, bit line and the isolation signal ISO being set as shown in the row for the page erase verify of FIG. 14b.

The write process continues with programming (Box 760) selected charge-retaining transistors M1 of a selected lower row of the three-dimensional NAND-based NOR nonvolatile PLD cells 700aa, . . . , 700am, . . . , 700na, . . . , 700nm to the second threshold voltage level (Vt1). This is accomplished by setting the voltage levels for the selected and unselected primary input I[N], inverse primary input I̅[̅N̅]̅, the write bit lines WBL, the write source lines WSL, and the isolation signal ISO are shown in the row for the paired program of FIG. 14b.

The lower row of charge-retaining transistors of the three-dimensional NAND-based NOR flash nonvolatile reconfigurable switching circuit 700aa, . . . , 700am, . . . , 700na, . . . , 700nm are program verified as part of the programming (Box 760). Each paired word line is iteratively set to the minimum value of the second threshold voltage level (Vt1min) followed by minimum value of the third threshold voltage level (Vt2min) for determining that each of the charge-retaining transistors M0 of the three-dimensional NAND-based NOR flash nonvolatile reconfigurable switching circuit 700aa, . . . , 700am, . . . , 700na, . . . , 700nm are programmed with the selected and unselected primary input I[N], inverse primary input I̅[̅N̅]̅, the write bit lines WBL, the write source lines WSL, and the isolation signal ISO being set as shown in the row for the page program verify of FIG. 14b.

The process examines (Box 762) if the last paired row of the charge-retaining transistors M0 and M1 of the three-dimensional NAND-based NOR flash nonvolatile reconfigurable switching circuit 700aa, . . . , 700am, . . . , 700na, . . . , 700nm have been written. If they have not been written, the next paired row of the charge-retaining transistors M0 and M1 are selected (Box 764) and written as described above. When all the selected charge-retaining transistors M0 and M1 of the three-dimensional NAND-based NOR flash nonvolatile reconfigurable switching circuit 700aa, . . . , 700am, . . . , 700na, . . . , 700nm are written the process ends (Box 766).

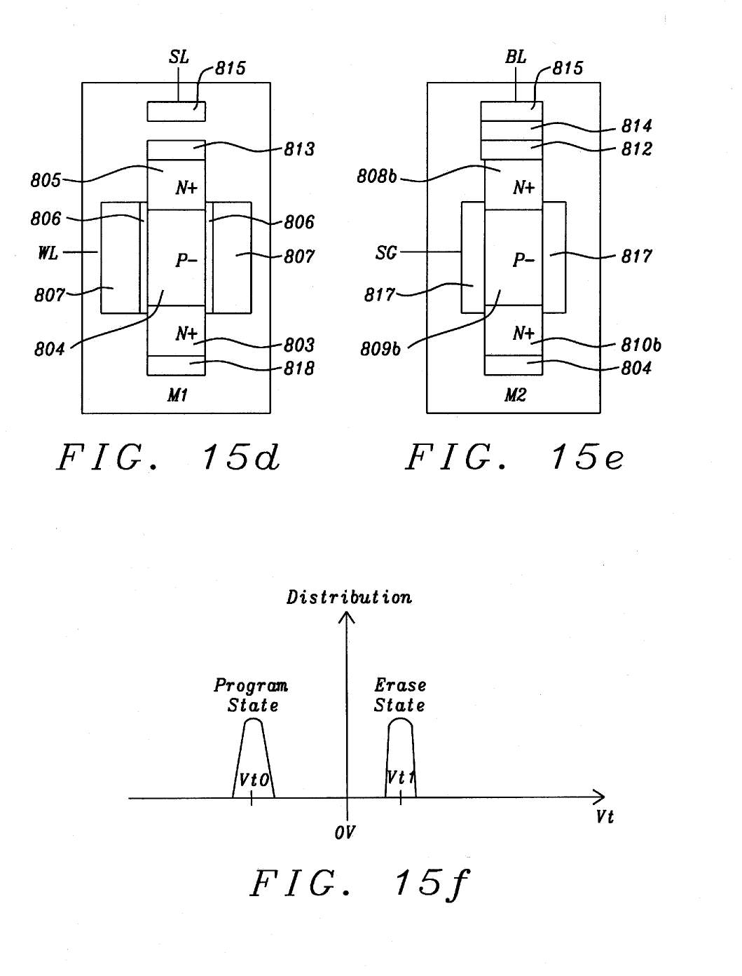

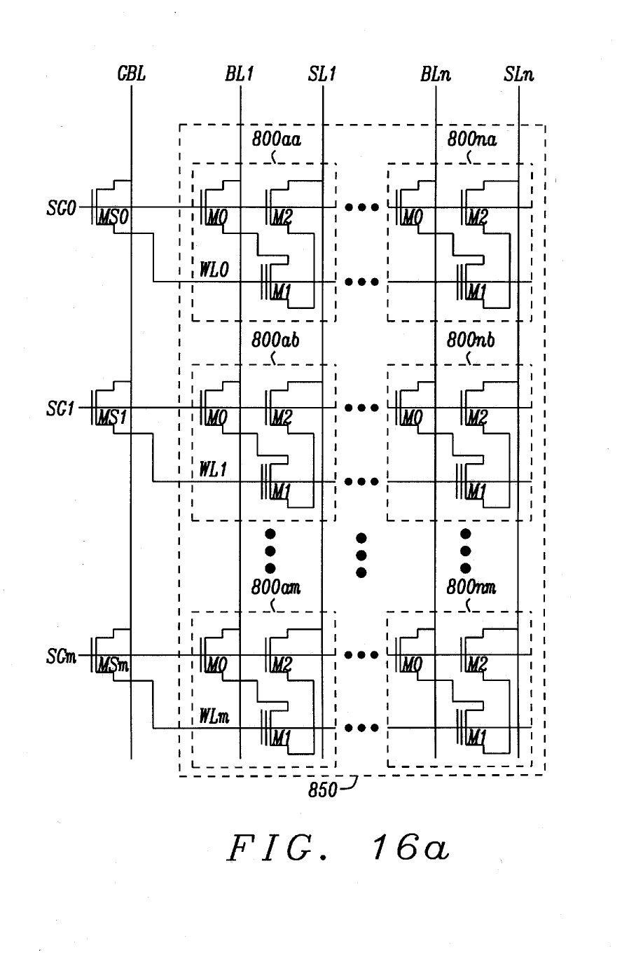

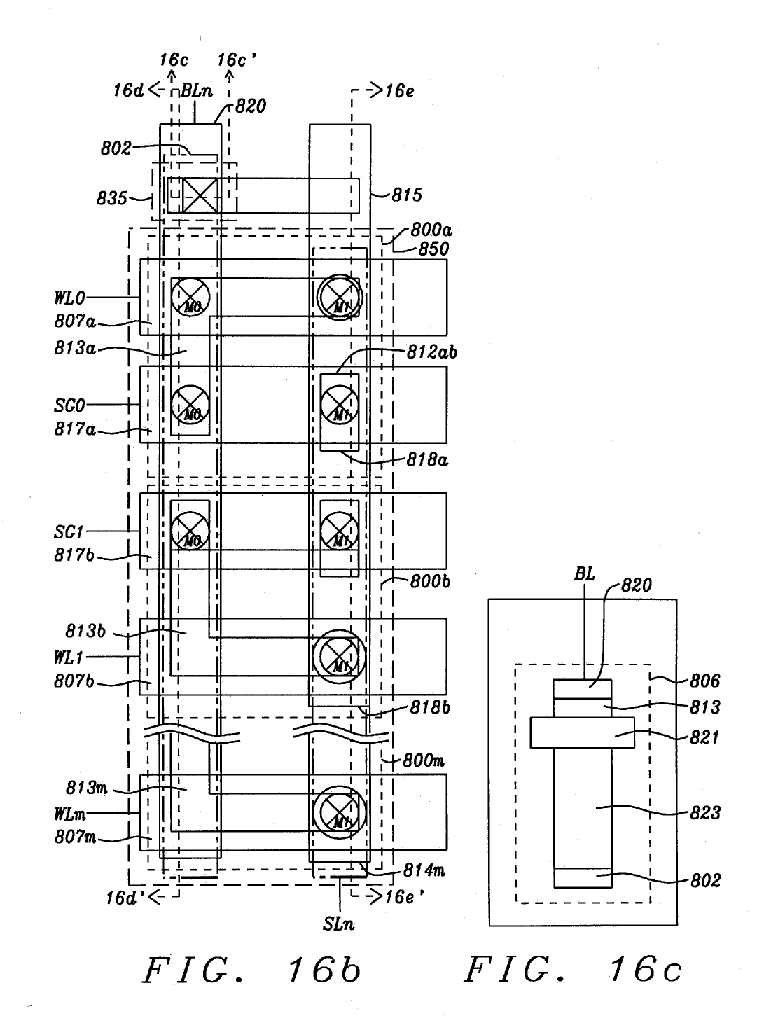

FIG. 15a is a schematic diagram of a three-transistor/one-bit three-dimensional EEPROM cell 800. FIG. 15b is a top plan view of a three-transistor/one-bit three-dimensional EEPROM cell 800. FIGS. 15c-15e are cross-section views of the transistors M0, M1, and M2 of a three-transistor/one-bit three-dimensional EEPROM cell 800 of FIG. 15a. The three-dimensional EEPROM cell 800 has a three-dimensional NMOS NOR flash transistor M1 that is formed similar to the single one-transistor/one-bit three-dimensional NMOS NOR flash transistor 100 of FIG. 1a. The three-dimensional NMOS NOR flash transistor M1 in FIG. 15d is formed as a cylindrical doped silicon structure. The source is an N+ active diffusion layer 803 formed on a N+ active diffusion local source line 818 within the surface of the substrate. The bulk 804 is formed of the P− diffusion layer that is formed immediately above the source N+ active diffusion 803. The drain is then formed immediately above as a second N+ active diffusion layer 805 on the bulk P− diffusion layer 804. An insulating SONOS layer 806 is formed to surround the bulk with a polycrystalline silicon layer 807 forming the control gate as a polycrystalline layer extending from row control circuitry (not shown) to be connected with the word line WL.

The drain N+ active diffusion layer 805 of the three-dimensional NMOS NOR flash transistor M1 is connected to a metal layer 813 that is connected to a source a first three-dimensional switching transistor M0. The first three-dimensional switching transistor M0 in FIG. 15d is formed similar to the three-dimensional switching transistor 205 of FIGS. 6a and 6b. The source of the first three-dimensional switching transistor MO is an N+ active layer 810a. A bulk region 809a is a P− silicon cylinder formed beneath the source N+ active diffusion layer 810a. An N+ active diffusion layer 810a is formed beneath the bulk region P− silicon cylinder 809a to make the drain of the first three-dimensional switching transistor M0. The drain N+ active diffusion layer 810a is connected to a diffusion layer 802a that forms the local bit line BL.

The source N+ active diffusion layer 803 of the three-dimensional NMOS NOR flash transistor M1 is connected to a drain of a second three-dimensional switching transistor M2 through the local source line N+ active diffusion local source line 818. The drain of the second three-dimensional switching transistor M2 is a N+ active diffusion 810b layer formed on the local source line N+ active diffusion local source line 818. A bulk region is a P− diffusion cylinder 809b formed on top of the source N+ active diffusion layer 810b. The drain of the three-dimensional NMOS NOR flash transistor M1 is formed of a N+ active diffusion layer 808b formed on the bulk P− diffusion region 809b. The drain N+ active diffusion layer 808b is connected to the metal plug layers 812 and 814 to a metal layer 815 that forms the source line SL.

A polycrystalline silicon layer 817 forms the gate of the first and second three-dimensional switching transistors M0 and M2. The polycrystalline silicon layer 817 is extended to the row control circuitry (not shown) to form the select gating line SG. The gates 817 of the first and second three-dimensional switching transistors M0 and M2 are commonly connected because the signals applied to the gates are identical for read, program and erase operations.

FIG. 15f is a plot of the program and erase threshold voltage distributions of a three-transistor/one-bit three-dimensional EEPROM cell 800. The erase threshold voltage level (Vt1) is assigned to be a positive threshold voltage level of approximately 0.7V with a variation of +/−0.5V for applications having voltage level of the power supply voltage source (VDD) of approximately 1.2V. If the voltage level of the power supply voltage source (VDD) is approximately 1.5V, the positive threshold voltage level (Vt1) is assigned to be approximately 1.0V with a variation of +/−0.5V. The program threshold voltage level (Vt0) is assigned a negative threshold voltage level of approximately −2.0V nominally with a maximum negative threshold voltage level of −1.5V. If it is any more negative, the negative threshold voltage level is a “don't care” state. The three-dimensional NMOS NOR flash transistor M1 is programmed and erased using the Fowler-Nordheim tunneling phenomenon. The first and second three-dimensional switching transistors M0 and M2 insure that there will be no current leakage during programming with the program state is the negative threshold voltage level Vt0. Therefore, there is no need for a program verification operation with the protection of the first and second three-dimensional switching transistors M0 and M2.

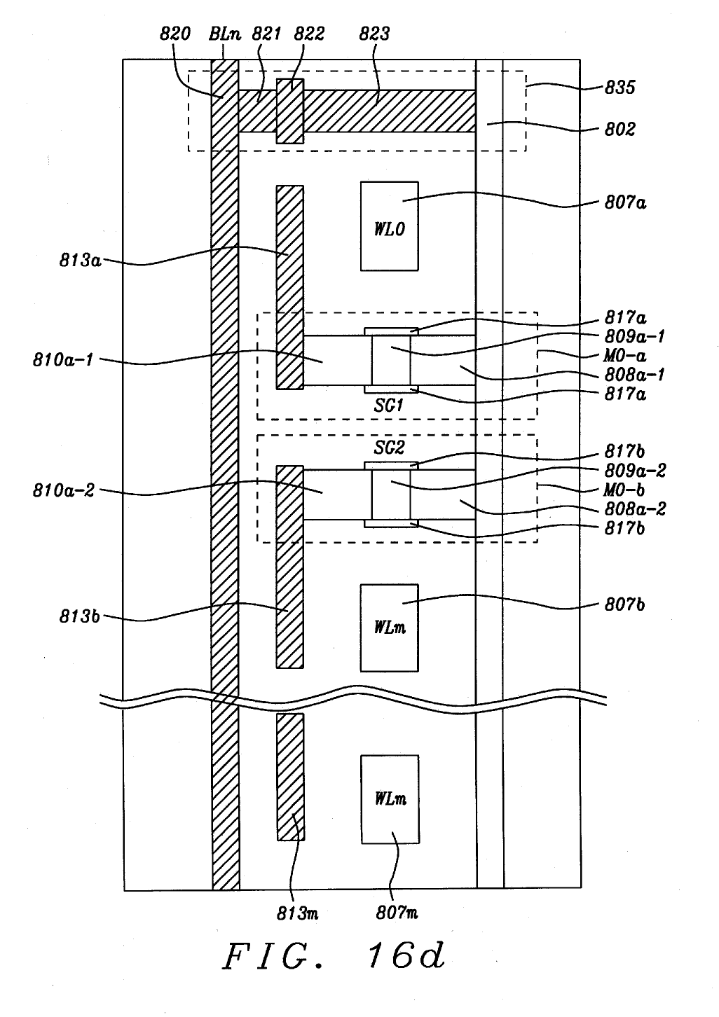

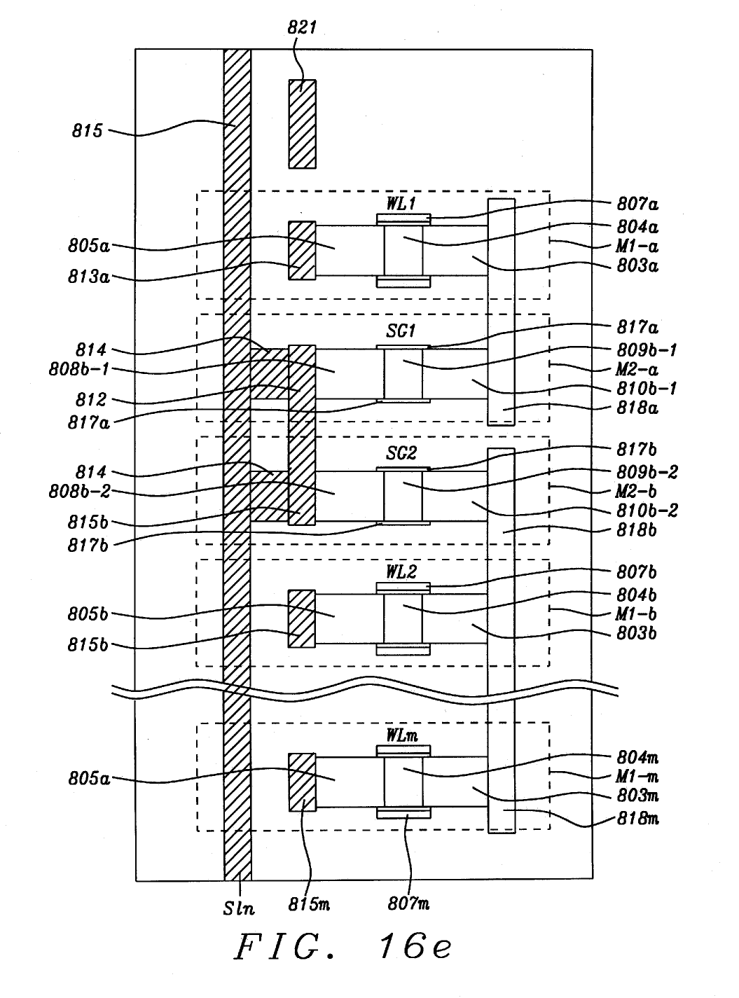

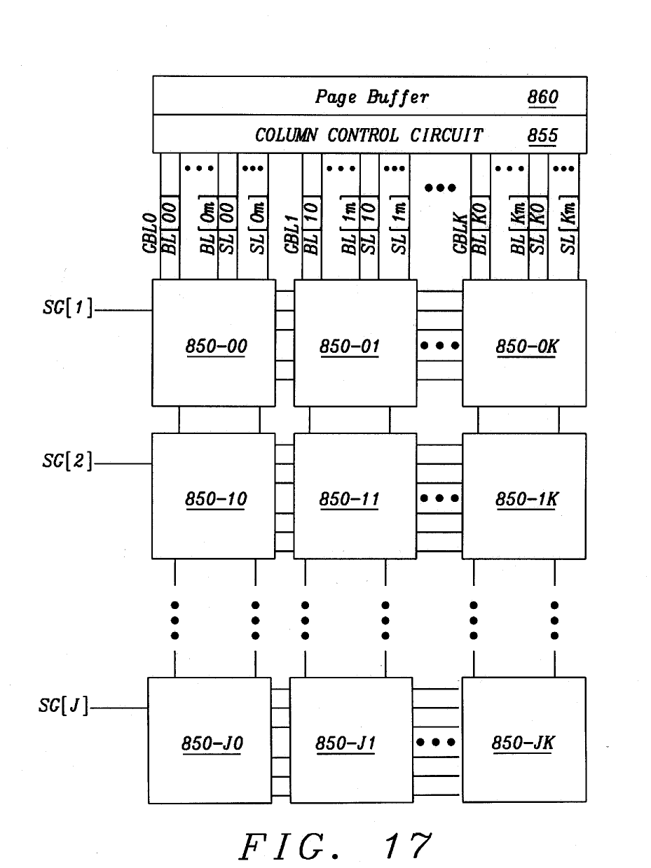

FIG. 16a is a schematic diagram of an array 850 of three-transistor/one-bit three-dimensional EEPROM cells 800aa, . . . , 800am, . . . , 800na, . . . , 800n. Multiple three-transistor/one-bit three-dimensional EEPROM cells 800aa, . . . , 800am, . . . , 800na, . . . , 800n are arranged in rows and columns. A select gating line SG0, SG1, . . . , SGm is connected to the first and second three-dimensional switching transistors M0 and M2 of each row of the three-dimensional EEPROM cells 800aa, . . . , 800am, . . . , 800na, . . . , 800n. A word line WL0, WL1, WLm is connected to each of the three-dimensional NMOS NOR flash transistor M1 of each row of the three-dimensional EEPROM cells 800aa, . . . , 800am, . . . , 800na, . . . , 800n. A bit line Bt0, BL1, . . . , BLn is connected to the drain of the first three-dimensional switching transistors M0 of each column of the three-dimensional EEPROM cells 800aa, . . . , 800am, . . . , 800na, . . . , 800n. Similarly, a source line SL0, SL1, . . . , SLm is connected to the source of the second three-dimensional switching transistors M2 of each column of the three-dimensional EEPROM cells 800aa, . . . , 800am, . . . , 800na, . . . , 800n. The bit lines BL0, BL1, . . . , BLn and the source lines SL0, SL1, . . . , SLm are connected to a column control circuit (not shown) to provide the necessary voltages to the bit lines BL0, BL1, . . . , BLn and the source lines SL0, SL1, . . . , SLm for programming, erasing, and reading selected three-dimensional EEPROM cells 800aa, . . . , 800am, . . . , 800na, . . . , 800n.

A word line biasing transistor MS0, MS1, . . . , MSm is associated with each of the rows of the three-dimensional EEPROM cells 800aa, . . . , 800am, . . . , 800na, 800n. The drain of each word line biasing transistor MS0, MS1, MSm is connected to a global bit line GBL that is connected to a column control circuit (not shown). The global bit line GBL transfers the word line biasing voltages for programming, erasing, and reading selected three-dimensional EEPROM cells 800aa, . . . , 800am, . . . , 800na, . . . , 800n. The source of each word line biasing transistor MS0, MS1, MSm is connected to the associated word line WL0, WL1, . . . , WLm of the row of the three-dimensional EEPROM cells 800aa, . . . , 800am, . . . , 800na, . . . , 800n. The gate of each word line biasing transistor MS0, MS1, . . . , MSm is connected to the associated select gating line SG0, SG1, . . . , SGm of each row of the three-dimensional EEPROM cells 800aa, . . . , 800am, . . . , 800na, . . . , 800n.

FIG. 16b is a top plan view of an array 850 of three-transistor/one-bit three-dimensional EEPROM cells 800a, 800b, . . . , 800m. FIG. 16c is a cross-sectional view of a interlayer plug 835 of a three-transistor/one-bit three-dimensional EEPROM cell 800a, 800b, . . . , 800m. FIGS. 16d-16e are cross-sectional views of a column of an array 850 of a three-transistor/one-bit three-dimensional EEPROM cells 800a, 800b, . . . , 800m. The column of three-transistor/one-bit three-dimensional EEPROM cells 800a, 800b, . . . , 800m has two sub-columns of the three-transistor/one-bit three-dimensional EEPROM cells 800a, 800b, . . . , 800m. The first three-dimensional switching transistors M0 for each of the three-transistor/one-bit three-dimensional EEPROM cells 800a, 800b, . . . , 800m are placed on a first sub-column. The three-dimensional NMOS NOR flash transistor M1 and the second three-dimensional switching transistor M2 of each of the three-transistor/one-bit three-dimensional EEPROM cells 800a, 800b, . . . , 800m are positioned to form the second sub-column of the column of the three-transistor/one-bit three-dimensional EEPROM cells 800a, 800b, . . . , 800m. Similarly, each row of the three-transistor/one-bit three-dimensional EEPROM cells 800a, 800b, . . . , 800m is formed of two sub-rows. The second three-dimensional switching transistors M1 for each of the three-transistor/one-bit three-dimensional EEPROM cells 800a, 800b, . . . , 800m are placed on the first sub-row. The three-dimensional NMOS NOR flash transistor M1 and the first three-dimensional switching transistor M0 of each of the three-transistor/one-bit three-dimensional EEPROM cells 800a, 800b, . . . , 800m are positioned to form the second sub-row of each row of the three-transistor/one-bit three-dimensional EEPROM cells 800a, 800b, . . . , 800m. The polycrystalline silicon layers 807a, 807b, . . . , 807m form the control gates for the three-dimensional NMOS NOR flash transistor M1 and are extended to a row control circuit (not shown) to form the word lines for the array 850. The word lines WL0, WL1, . . . , WLm transmit the word line control biasing voltages for programming, erasing, and reading selected three-transistor/one-bit three-dimensional EEPROM cells 800a, 800b, . . . , 800m. The polycrystalline silicon layers 817a, 817b, . . . , 817m form the gates for the first and second three-dimensional switching transistors M0 and M2 of each of the three-transistor/one-bit three-dimensional EEPROM cells 800a, 800b, . . . , 800m. The polycrystalline silicon layers 817a, 817b, . . . , 817m are extended to form the select gating lines SG0, SG1, . . . that are connected to the row control circuit (not shown). The select gating lines SG0, SG1, . . . transmit the select gating signals for selectively turning on and turning off the first and second three-dimensional switching transistors M0 and M2 of each of the three-transistor/one-bit three-dimensional EEPROM cells 800a, 800b, . . . , 800m for programming, erasing, and reading.

The structure of three-transistor/one-bit three-dimensional EEPROM cells 800a, 800b, . . . , 800m is as described for FIGS. 15b, 15c, 15d, and 15e. The source N+ active diffusion layers 803a, 803b, . . . , 803m are placed on the local source line diffusion layers 818a, 818b, . . . , 818m Each of the bulk P− regions 804a, 804b, . . . , 804m are placed on the source N+ active diffusion layers 803a, 803b, . . . , 803m. The drain N+ active diffusion layers 805a, 805b, . . . , 805m are placed on the bulk P− regions 804a, 804b, . . . , 804m. The drain N+ active diffusion layers 805a, 805b, . . . , 805m are connected to the metal layer 813a, 813b, . . . , 813m that is connected to a source N+ active diffusion layer 810a-1, 810a-2, . . . , of the first three-dimensional switching transistor M0-a, M0-b, . . . , of each of the three-transistor/one-bit three-dimensional EEPROM cells 800a, 800b, . . . , 800m. The source N+ active diffusion layer 810a-1, 810a-2, . . . , are formed on the bulk P− regions 809a-1, 809a-2, . . . , which in turn are formed on the drain N+ active diffusion layer 808a-1, 808a-2, . . . . The drain N+ active diffusion layer 808a-1, 808a-2, . . . , are formed on the bit line diffusion layer 802. The bit line diffusion layer is connected to the interlayer plug 835 shown in FIG. 16c. The interlayer diffusion plug is formed of metal layers 821, 822, and 823 that is connected to the metal layer 820 to form the bit line BLn that is associated with one column of the array 850 of the three-transistor/one-bit three-dimensional EEPROM cells 800a, 800b, . . . , 800m. The bit line BLn metal layer 820 is connected to column control circuitry (not shown) that provides the necessary bit line biasing voltages to the bit line BLn metal layer 820 for operating the selected three-transistor/one-bit three-dimensional EEPROM cells 800a, 800b, . . . , 800m for programming, erasing, and reading.

The source N+ active diffusion layers 803a, 803b, . . . , 803m are connected through the local source line diffusion layers 818a, 818b, . . . , 818m to the drain N+ active diffusion layers 810b-1, 810b-2, . . . , of the second three-dimensional switching transistor M2-a, M2-b, . . . . The bulk P− regions 809a-1, 809a-2, . . . , are formed on the drain N+ active diffusion layers 810b-1, 810b-2, . . . , and the source N+ active diffusion layers 808b-1, 808b-2, . . . , are formed one the bulk P− regions 809a-1, 809a-2, . . . . The metal layers 812 and 814 connect the source N+ active diffusion layers 808b-1, 808b-2, . . . , to the metal layer 815 that forms the source line SLn. The source line SLn is connected to the column control circuit (not shown) that provides the biasing voltages for programming, erasing, and reading to the selected the three-transistor/one-bit three-dimensional EEPROM cells 800a, 800b, . . . , 800m. The source line SLn and the bit line BLn is associated and parallel with one of the columns of the array 850 of the three-transistor/one-bit three-dimensional EEPROM cells 800a, 800b, . . . , 800m.

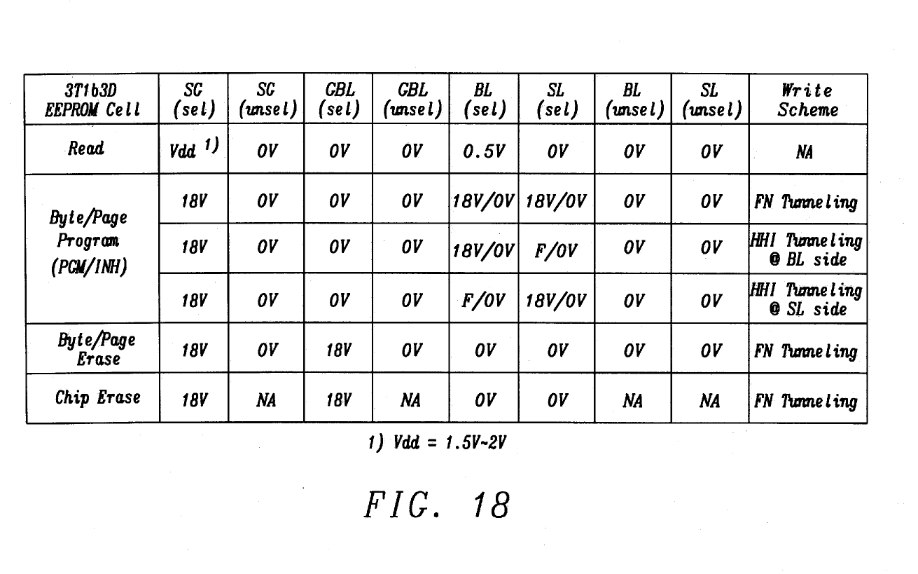

FIG. 17 is a block diagram of an integrated circuit device formed of multiple arrays 850-00, . . . , 850-0K, . . . , 850-J0, . . . , 850-JK of three-transistor/one-bit three-dimensional EEPROM cells 800a, 800b, . . . , 800m of FIGS. 15a and 15b. Each of the arrays 850-00, . . . , 850-0K, . . . , 850-J0, . . . , 850-JK of the three-transistor/one-bit three-dimensional EEPROM cells 800a, 800b, . . . , 800m represents a unit of the cells. The arrays or blocks 850-00, . . . , 850-0K, . . . , 850-J0, . . . , 850-JK of the three-transistor/one-bit three-dimensional EEPROM cells 800a, 800b, . . . , 800m are arranged in rows and columns.

Each row of the blocks 850-00, . . . , 850-0K, . . . , 850-J0, . . . , 850-JK of the three-transistor/one-bit three-dimensional EEPROM cells 800a, 800b, . . . , 800m is connected to receive the select gating lines SG[0], . . . , SG[J]. The select gating lines SG[0], . . . , SG[J] provide the activating signal for control the application of operating voltage levels to the word lines WL0, WL1, . . . , WLm for programming, erasing, and reading as above described.

The global bit lines GBL0, . . . , GBLK, the bit lines BL[00], . . . , BL[0m], . . . , BL[K0], . . . , BL[Km] and the source lines SL[00], . . . , SL[0m], . . . , SL[K0], . . . , SL[Km] originating with each column of the blocks the blocks 850-00, . . . , 850-0K, . . . , 850-J0, . . . , 850-JK of the three-transistor/one-bit three-dimensional EEPROM cells 800a, 800b, . . . , 800m is connected to a column control circuit 855 and from the column control circuit 855 to the page buffer 860. The column control circuit 855 generates the necessary operating voltage levels that are to be applied to the global bit lines GBL0, . . . , GBLK, the bit lines BL[00], . . . , BL[0m], . . . , BL[K0], . . . , BL[Km] and the source lines SL[00], . . . , SL[0m], . . . , SL[K0], . . . , SL[Km] for the programming, erasing, and reading of three-transistor/one-bit three-dimensional EEPROM cells 800a, 800b, . . . , 800m. The page buffer 860 retains the logic states determined during a read operation of selected three-transistor/one-bit three-dimensional EEPROM cells 800a, 800b, . . . , 800m of each of the blocks 850-00, . . . , 850-0K, . . . , 850-J0, . . . , 850-JK. The page buffer 860 further provides the logic states during a write operation of selected three-transistor/one-bit three-dimensional EEPROM cells 800a, 800b, . . . , 800m of each of the blocks 850-00, . . . , 850-0K, . . . , 850-J0, . . . , 850-JK.

In various embodiments, each row of the three-transistor/one-bit three-dimensional EEPROM cells 800a, 800b, . . . , 800m defined as a page and each page is further divided into byte units (eight three-transistor/one-bit three-dimensional EEPROM cells 800a, 800b, . . . , 800m). As illustrated each of the array blocks 850-00, . . . , 850-0K, . . . , 850-J0, . . . , 850-JK represent one byte of the page of each row of the array. Each of the byte blocks 850-00, . . . , 850-0K, . . . , 850-J0, . . . , 850-JK includes its own global bit lines GBL0, . . . , GBLK, bit lines BL[00], . . . , BL[0m], . . . , BL[K0], . . . , BL[Km] and source lines SL[00], . . . , SL[0m], . . . , SL[K0], . . . , SL[Km]. This permits the programming, erasing, and reading of the array of three-transistor/one-bit three-dimensional EEPROM cells 800a, 800b, . . . , 800m in groups of byte blocks 850-00, . . . , 850-0K, . . . , 850-J0, . . . , 850-JK. These may be a single byte block 850-00, . . . , 850-0K, . . . , 850-J0, . . . , 850-JK, a full page of the byte blocks 850-00, . . . , 850-0K, . . . , 850-J0, . . . , 850-JK, or the entire array of the three-transistor/one-bit three-dimensional EEPROM cells 800a, 800b, . . . , 800m.

FIG. 18 is a chart for the voltage levels for functional operation of an array of three-transistor/one-bit three-dimensional EEPROM cells 800a, 800b, . . . , 800m of FIGS. 15a and 15b. Referring to FIGS. 16a, 17, and 18, in an erase operation, a very large erasing voltage level is applied to the global bit line(s) GBL0, . . . , GBLK of the selected sub-array block(s) 850-00, . . . , 850-0K, . . . , 850-J0, . . . , 850-JK. The very large erasing voltage level is approximately 18.0V. The select gating line(s) SG[0], . . . , SG[J] for the selected sub-array block(s) 850-00, . . . , 850-0K, . . . , 850-J0, . . . , 850-JK have a select gating voltage level that is applied to the gate of the word line biasing transistor MS0, MS1, . . . , MSm and to the gates of the first and second three-dimensional switching transistors M0 and M2. The word line biasing transistor(s) MS0, MS1, . . . MSm is activated to apply the very large erasing voltage level to the word lines WL0, WL1, . . . , WLm and thus to the gates of the charge-retaining transistors M1 of the selected three-transistor/one-bit three-dimensional EEPROM cells 800a, 800b, . . . , 800m. The select gating biasing voltage level is approximately 18.0V. The global bit line(s) GBL0, . . . , GBLK of the unselected sub-array block(s) 850-00, . . . , 850-0K, . . . , 850-J0, . . . , 850-JK are set to the ground reference voltage level (0.0V) to deactivate the word line biasing transistor MS0, MS1, . . . , MSm to inhibit erasure.

The bit lines BL[00], . . . , BL[0m], . . . , BL[K0], . . . , BL[Km] and source lines SL[00], . . . , SL[0m], . . . , SL[K0], . . . , SL[Km] are all set to the ground reference voltage level (0.0 v) to initiate a Fowler-Nordheim Tunneling phenomenon to attract negative charges to the insulating SONOS layer 806 of the charge-retaining transistor M1 shown in FIG. 15b to increase the threshold voltage level of the selected three-transistor/one-bit three-dimensional EEPROM cells 800a, 800b, . . . , 800m to the erased threshold voltage level Vt1 that is approximately 2.0V. If the entire array of three-transistor/one-bit three-dimensional EEPROM cells 800a, 800b, . . . , 800m is to be erase, there are no unselected global bit lines GBL0, . . . , GBLK, bit lines BL[00], . . . , BL[0m], . . . , BL[K0], . . . , BL[Km] or source lines SL[00], . . . , SL[0m], . . . , SL[K0], . . . , SL[Km].

In a programming operation, the ground reference voltage level (0.0V) is applied to the global bit line(s) GBL0, . . . , GBLK of the selected and unselected sub-array block(s) 850-00, . . . , 850-0K, . . . , 850-J0, . . . , 850-JK. The select gating line(s) SG[0], . . . , SG[J] for the selected sub-array block(s) 850-00, . . . , 850-0K, . . . , 850-J0, . . . , 850-JK have a select gating voltage level that is applied to the word line biasing transistor MS0, MS1, . . . , MSm and the gates of the first and second three-dimensional switching transistors M0 and M2. The word line biasing transistor(s) MS0, MS1, . . . MSm is activated to apply the ground reference voltage level (0.0V) to the word lines WL0, WL1, . . . , WLm and thus to the gates of the charge-retaining transistors M1 of the selected three-transistor/one-bit three-dimensional EEPROM cells 800a, 800b, . . . , 800m. The select gating biasing voltage level is approximately 18.0V.

The bit lines BL[00], . . . , BL[0m], . . . , BL[K0], . . . , BL[Km] and source lines SL[00], . . . , SL[0m], . . . , SL[K0], . . . , SL[Km] of the selected sub-array block(s) 850-00, . . . , 850-0K, . . . , 850-J0, . . . , 850-JK are alt set to the very large programming voltage level to initiate a Fowler-Nordheim Tunneling phenomenon to extract negative charges from the insulating SONOS layer 806 of the charge-retaining transistor M1 shown in FIG. 15b to decrease the threshold voltage level of the selected three-transistor/one-bit three-dimensional EEPROM cells 800a, 800b, . . . , 800m to the programmed threshold voltage level Vt0 that is approximately −1.5V. In various embodiments, the bit lines BL[00], . . . , BL[0m], . . . , BL[K0], . . . , BL[Km] of the selected sub-array block(s) 850-00, . . . , 850-0K, . . . , 850-J0, . . . , 850-JK are all set to the very large programming voltage level. The source lines SL[00], . . . , SL[0m], . . . , SL[K0], . . . , SL[Km] of the selected sub-array block(s) 850-00, . . . , 850-0K, . . . , 850-J0, . . . , 850-JK are disconnected and allowed to float or are set to the ground reference voltage level (0.0V) to initiate a hot carrier (hole) injection phenomenon to extract negative charges from the insulating SONOS layer 806 of the charge-retaining transistor M1. In other embodiments, the source lines SL[00], . . . , SL[0m], . . . , SL[K0], . . . , SL[Km] of the selected sub-array block(s) 850-00, . . . , 850-0K, . . . , 850-J0, . . . , 850-JK are all set to the very large programming voltage level. The bit lines BL[00], . . . , BL[0m], . . . , BL[K0], . . . , BL[Km] of the selected sub-array block(s) 850-00, . . . , 850-0K, . . . , 850-J0, . . . , 850-JK are disconnected and allowed to float or set to the ground reference voltage level (0.0V) to initiate a hot carrier (hole) injection phenomenon to extract negative charges from the insulating SONOS layer 806 of the charge-retaining transistor M1. The unselected bit lines BL[00], . . . , BL[0m], . . . , BL[K0], . . . , BL[Km] and source lines SL[00], . . . , SL[0m], . . . , SL[K0], . . . , SL[Km] of the selected sub-array block(s) 850-00, . . . , 850-0K, . . . , 850-J0, . . . , 850-JK are set to the ground reference voltage level (0.0V) to inhibit programming the unselected three-transistor/one-bit three-dimensional EEPROM cells 800a, 800b, . . . , 800m. The very large programming voltage level is approximately 18.0V.

The structure of the each column of the three-transistor/one-bit three-dimensional EEPROM cells 800a, 800b, . . . , 800m being associated with is own bit lines BL[00], . . . , BL[0m], . . . , BL[K0], . . . , BL[Km] and source lines SL[00], . . . , SL[0m], . . . , SL[K0], . . . , SL[Km] placed in parallel provides a secure programming operation with no concern for punch through with the charge-retaining transistors M1 of the three-transistor/one-bit three-dimensional EEPROM cells 800a, 800b, . . . , 800m. Further the separate select gating line(s) SG[0], . . . , SG[J] for the selected sub-array block(s) 850-00, . . . , 850-0K, . . . , 850-J0, . . . , 850-JK isolates the selected page of the three-transistor/one-bit three-dimensional EEPROM cells 800a, 800b, . . . , 800m from the remaining pages of the three-transistor/one-bit three-dimensional EEPROM cells 800a, 800b, . . . , 800m to avoid program disturbances and insure that the array of three-transistor/one-bit three-dimensional EEPROM cells 800a, 800b, . . . , 800m can meet a specification for 1M endurance cycles. The time for writing (programming and erasing) a byte or page of the three-transistor/one-bit three-dimensional EEPROM cells 800a, 800b, . . . , 800m is from approximately 1.0 ms to approximately 2.0 ms with a wide power supply voltage range of from 1.8V to 5.5V. An advantage of the three-transistor/one-bit three-dimensional EEPROM cells 800a, 800b, . . . , 800m is the relatively large channel width of the charge-retaining transistor M1 to insure a read speed that is faster than the comparable two-dimensional EEPROM cells.

In some embodiments, a three-dimensional combination nonvolatile memory integrated circuit that includes any number of the three-dimensional flash-based memories including a three-dimensional two-transistor/two-bit NOR array as described in FIG. 8a for the block-alterable code storage, a three-dimensional three-transistor/one-bit byte-alterable EEPROM array as described in FIG. 16a for byte-alterable data storage, a three-dimensional flash-based two-transistor/two-bit block-alterable PLD's “AND and OR” logic arrays as described in FIG. 12a and a three-dimensional four-transistor/one-bit fast switch block-alterable array as described in FIG. 13d for a powerful memory and logic system-on-chip structure.

In various embodiments of the three-dimensional NAND-based NOR nonvolatile memory cell, the three-dimensional charge-retaining transistors are formed as a single cylindrical doped silicon structure. The first drain/source of one of the three-dimensional charge-retaining transistors is formed on an N+ active diffusion layer that may be the source line or bit line of the circuit. The bulk of the one three-dimensional charge-retaining transistor is formed of a first P− diffusion layer that is formed immediately above the first drain/source N+ active diffusion of the one three-dimensional charge-retaining transistor. The merged drain/source of the two three-dimensional charge-retaining transistors as a second N+ active diffusion layer on the first bulk P− diffusion layer. A second bulk P− diffusion layer is formed on the merged drain/source N+ active diffusion layer. A drain/source for the second charge-retaining transistor is formed on the second bulk P− diffusion layer. The drain source of the second charge-retaining transistor is connected to a metal layer that may be the bit line or source line of the circuit depending on the function of the lower N+ active diffusion layer.

Two insulating SONOS layers are formed such that one surrounds the first bulk P− diffusion layer and the other surrounds the second bulk P− diffusion layer to form the charge-retaining layers for the three-dimensional NAND-based NOR nonvolatile memory cell. Two polycrystalline silicon layers are formed such that one of the polycrystalline silicon layer is in line with the first bulk P− diffusion layer and the second polycrystalline silicon layer is in line with the second bulk P− diffusion layer. The two polycrystalline silicon layers are extended to form the word lines for the circuit.

This integration of the three-dimensional NAND-based NOR nonvolatile memory cell as a single cylindrical doped silicon structure allows the three-dimensional charge-retaining transistors to be serially connected to avoid the over-erase during a block-erase operation of an array of the three-dimensional NAND-based NOR nonvolatile memory cells.

While this disclosure has been particularly shown and described with reference to the preferred embodiments thereof, it will be understood by those skilled in the art that various changes in form and details may be made without departing from the spirit and scope of the disclosure.

What is claimed is:

1. A three-dimensional NAND-based NOR nonvolatile memory cell comprising:
a first and second three-dimensional charge-retaining transistors arranged in a series string such that one of the charge-retaining transistors functions as a select gate transistor to prevent leakage current through the charge-retaining transistors when the charge-retaining transistors is not selected for determining a logic state;
wherein the a three-dimensional NAND-based NOR nonvolatile memory cell is associated with a local bit line that is formed as a first active layer heavily doped with the impurity of a first conductivity type diffused below the first three-dimensional charge-retaining transistor and a local source line formed as a second active layer heavily doped with the impurity of the first conductivity type diffused below the second three-dimensional charge-retaining transistor and in parallel with the local bit line.

2. The three-dimensional NAND-based NOR nonvolatile memory cell of claim 1 wherein,
the first three-dimensional charge-retaining transistors comprises:
a first drain diffusion heavily doped with the impurity of the first conductivity type cylindrically formed on the local bit line,
a first bulk diffusion lightly doped with an impurity of a second conductivity type cylindrically formed on the first drain diffusion,
a first source diffusion heavily doped with the impurity of the first conductivity type cylindrically formed on the first bulk diffusion,
a first charge retaining insulating layer formed of an insulating material to surround the first bulk diffusion, and
a first polycrystalline silicon layer formed to surround the first charge retaining layer to form a first control gate and is extended to form a first word line that conducts operating voltages to the control gate; the second three-dimensional charge-retaining transistors comprises:
a second source diffusion heavily doped with the impurity of the first conductivity type cylindrically formed on the local source line,
a second bulk diffusion lightly doped with the impurity of the second conductivity type cylindrically formed on the second source diffusion,
a second drain diffusion heavily doped with the impurity of the first conductivity type cylindrically formed on the first bulk diffusion,
a second charge retaining insulating layer formed of the insulating material to surround the first bulk diffusion, and
a second polycrystalline silicon layer formed to surround the second charge retaining layer to form a second control gate and is extended to form a second word line that conducts operating voltages to the control gate; and
wherein the first drain diffusion and the second source diffusion are connected solely with a conductive layer to merge the first drain diffusion and the second source diffusion.

3. The three-dimensional NAND-based NOR nonvolatile memory cell of claim 1 wherein the first and second three-dimensional charge-retaining transistors have a first threshold voltage level to represent a first data state and a second threshold voltage level to represent a second data state.

4. The three-dimensional NAND-based NOR nonvolatile memory cell of claim 3 wherein the first voltage threshold level is approximately +1.0V and second voltage threshold is approximately −2.0V.

5. The three-dimensional NAND-based NOR nonvolatile memory cell of claim 3 wherein the first voltage threshold level is the programmed threshold voltage level and second voltage threshold is erased threshold voltage level.

6. The three-dimensional NAND-based NOR nonvolatile memory cell of claim 5 wherein programming a selected charge-retaining transistor to the first threshold voltage level comprises the steps of:
applying a very large programming voltage level to the control gate of the selected charge retaining transistor,
applying a charge-retaining transistor activation voltage level to the control gate of an unselected three-dimensional charge-retaining transistor, and
applying a ground reference voltage level (0.0V) local bit line and local source lines of the selected charge-retaining transistors.

7. The three-dimensional NAND-based NOR nonvolatile memory cell of claim 6 wherein inhibiting programming an unselected charge-retaining transistor comprises the steps of:
applying a charge-retaining transistor activation voltage level to the control gates of first and second three-dimensional charge-retaining transistors;
applying a programming inhibit voltage level to the bit lines and the source lines of the first and second charge-retaining transistors.

8. The three-dimensional NAND-based NOR nonvolatile memory cell of claim 7 wherein the very large programming voltage level is approximately 18.0V and the programming inhibit voltage level is approximately (9.0V).

9. The three-dimensional NAND-based NOR nonvolatile memory cell of claim 7 wherein the first and second charge retaining transistors are one level polycrystalline silicon, charge-trapping, SONOS transistors.

10. The three-dimensional NAND-based NOR nonvolatile memory cell of claim 5 wherein erasing the first and second charge-retaining transistors to the second threshold voltage level comprises the steps of:
applying the ground reference voltage level (0.0V) to the control gates of the first and second three-dimensional charge-retaining transistors, and
applying very large erase voltage level to the bit lines and source lines connected to the first and second three-dimensional charge-retaining transistors.

11. The three-dimensional NAND-based NOR nonvolatile memory cell of claim 10 wherein inhibiting erasing of the first and second charge-retaining transistors comprises the steps of:
applying an erase inhibit voltage level to the control gates of the first and second three-dimensional charge-retaining transistors.

12. The three-dimensional NAND-based NOR nonvolatile memory cell of claim 11 wherein the erase inhibit voltage level is approximately 9.0V and the very large erase voltage level is approximately 18.0V.

13. The three-dimensional NAND-based NOR nonvolatile memory cell of claim 1 wherein the first and second three-dimensional charge-retaining transistors are programmed to a first programmed threshold voltage level representing a first programmed internal logic state, the first three-dimensional charge-retaining transistor is programmed to the first programmed threshold voltage level and the second three-dimensional charge-retaining transistor is programmed to an erased threshold voltage level representing a second programmed internal logic state, the first three-dimensional charge-retaining transistor is programmed to the erased threshold voltage level and the second three-dimensional charge-retaining transistor is programmed to the first programmed threshold voltage level representing a third programmed internal logic state, and the first and second three-dimensional charge-retaining transistors are programmed to a second programmed threshold voltage level representing a fourth programmed internal logic state.

14. The three-dimensional NAND-based NOR nonvolatile memory cell of claim 13 wherein the second programmed threshold voltage level prevents the first and second three-dimensional charge-retaining transistors from turning on to prevent leakage current.

15. The three-dimensional NAND-based NOR nonvolatile memory cell of claim 13 wherein the first program threshold level is approximately +1.0V, the second program threshold voltage level is approximately 3.0V, and the erased threshold voltage level is approximately −2.0V.

16. A three-dimensional three-transistor/one-bit EEPROM nonvolatile memory cell comprising:
a three-dimensional charge-retaining transistor;
a first three-dimensional high voltage NMOS gating transistor including a source connected to a drain of the charge-retaining transistor, a drain connected to a bit line for receiving operating voltage levels for programming, erasing, and reading the charge-retaining transistor, and a gate connected to receive a select gating signal for activating the three-dimensional three-transistor/one-bit EEPROM nonvolatile memory cell; and
a second three-dimensional high voltage NMOS gating transistor including a drain connected to a source of the charge-retaining transistor, a source connected to a source line for receiving operating voltage levels for programming, erasing, and reading the charge-retaining transistor, and a gate connected to receive the select gating signal for activating the three-dimensional three-transistor/one-bit EEPROM nonvolatile memory cell.

17. The three-dimensional three-transistor/one-bit EEPROM nonvolatile memory cell of claim 16 wherein,
the three-dimensional charge-retaining transistor comprises:
a first source diffusion heavily doped with the impurity of the first conductivity type cylindrically formed on a local source line diffusion,
a first bulk diffusion lightly doped with an impurity of a second conductivity type cylindrically formed on the first source diffusion,
a first drain diffusion heavily doped with the impurity of the first conductivity type cylindrically formed on the first bulk diffusion,
a first charge retaining insulating layer formed of an insulating material to surround the first bulk diffusion, and
a first polycrystalline silicon layer formed to surround the first charge retaining layer to form a first control gate and is extended to form a word line that conducts operating voltages to the control gate;
the first three-dimensional high voltage NMOS gating transistor comprises:
a second drain diffusion heavily doped with the impurity of the first conductivity type cylindrically formed on a local bit line,
a second bulk diffusion lightly doped with the impurity of the second conductivity type cylindrically formed on the second drain diffusion,
a second source diffusion heavily doped with the impurity of the first conductivity type cylindrically formed on the second bulk diffusion, and
a second polycrystalline silicon layer formed to surround the second bulk diffusion to form a first gate and is extended to form a select gating line that conducts operating voltages to the first gate; and
the second three-dimensional high voltage NMOS gating transistor comprises:
a third source diffusion heavily doped with the impurity of the first conductivity type cylindrically formed on a local source line,
a third bulk diffusion lightly doped with the impurity of the second conductivity type cylindrically formed on the third source diffusion,
a second drain diffusion heavily doped with the impurity of the first conductivity type cylindrically formed on the third bulk diffusion, and
a third polycrystalline silicon layer formed to surround the third bulk diffusion to form a second gate and is extended to join the second polycrystalline silicon layer as the select gating line that conducts operating voltages to the second gate.

18. The three-dimensional three-transistor/one-bit EEPROM nonvolatile memory cell of claim 16 wherein the three-dimensional charge-retaining transistor is programmed with a first threshold voltage level that turns on the three-dimensional charge-retaining transistor when a read reference voltage is applied to a control gate of the three-dimensional charge-retaining transistor and is erased with a second threshold voltage level that turns off the three-dimensional charge-retaining transistor when the read reference voltage is applied to the control gate of the three-dimensional charge-retaining transistor.

19. The three-dimensional three-transistor/one-bit EEPROM nonvolatile memory cell of claim 18 wherein the first threshold voltage level is approximately −2.0V and the second threshold voltage level is approximately +3.0V.

20. The three-dimensional three-transistor/one-bit EEPROM nonvolatile memory cell of claim 16 wherein erasing the three-dimensional three-transistor/one-bit EEPROM nonvolatile memory cell comprises the steps of:
applying a very large select gating signal to the gates of the first and second three-dimensional high voltage NMOS gating transistors to activate the first and second three-dimensional high voltage NMOS gating transistors,
applying very large erase voltage level to the word line and thus to the control gate of the three-dimensional charge-retaining transistor, and
applying the ground reference voltage level (0.0V) to the source and drain of the three-dimensional charge-retaining transistor through the first and second three-dimensional high voltage NMOS gating transistors.

21. The three-dimensional three-transistor/one-bit EEPROM nonvolatile memory cell of claim 16 wherein Fowler Nordheim tunnel programming the three-dimensional three-transistor/one-bit EEPROM nonvolatile memory cell comprises the steps of:
applying a very large select gating signal to the gates of the first and second three-dimensional high voltage NMOS gating transistors to activate the first and second three-dimensional high voltage NMOS gating transistors,
applying a very large programming voltage level to the local source line and local bit line and thus to the source and drain of the three-dimensional charge-retaining transistor,
and
applying a ground reference voltage level (0.0V) to the control gate of the three-dimensional charge-retaining transistor.

22. The three-dimensional three-transistor/one-bit EEPROM nonvolatile memory cell of claim 16 wherein source side hot carrier injection programming the three-dimensional three-transistor/one-bit EEPROM nonvolatile memory cell comprises the steps of:
applying a very large select gating signal to the gates of the first and second three-dimensional high voltage NMOS gating transistors to activate the first and second three-dimensional high voltage NMOS gating transistors,
applying a very large programming voltage level to the local source line and thus to the source of the three-dimensional charge-retaining transistor,
and
applying a ground reference voltage level (0.0V) to the control gate and the drain of the three-dimensional charge-retaining transistor.

23. The three-dimensional three-transistor/one-bit EEPROM nonvolatile memory cell of claim 16 wherein drain side hot carrier injection programming the three-dimensional three-transistor/one-bit EEPROM nonvolatile memory cell comprises the steps of:
applying a very large select gating signal to the gates of the first and second three-dimensional high voltage NMOS gating transistors to activate the first and second three-dimensional high voltage NMOS gating transistors,
applying a very large programming voltage level to the local source line and local bit line and thus to the drain of the three-dimensional charge-retaining transistor,
and
applying a ground reference voltage level (0.0V) to the control gate and the source of the three-dimensional charge-retaining transistor.

24. A three-dimensional NAND-based nonvolatile programmed logic device (PLD) comprising:
a first and second three-dimensional charge-retaining transistors arranged in a series string such that one of the charge-retaining transistors functions as a select gate transistor to prevent leakage current through the charge-retaining transistors when the charge-retaining transistors is not selected for determining a logic state,
wherein the a three-dimensional NAND-based NOR nonvolatile PLD cell is associated with a local bit line that is formed as a first active layer heavily doped with the impurity of a first conductivity type diffused below the first three-dimensional charge-retaining transistor and a local source line formed as a second active layer heavily doped with the impurity of the first conductivity type diffused below the second three-dimensional charge-retaining transistor and in parallel with the local bit line, and
wherein a primary input line is in communication with a control gate of the first three-dimensional charge-retaining transistor and inverse primary input line is in communication with a control gate of the second three-dimensional charge-retaining transistor for determining a logic state of the first and second three-dimensional charge-retaining transistors.

25. The three-dimensional NAND-based NOR nonvolatile PLD of claim 24 wherein,
the first three-dimensional charge-retaining transistors comprises:
a first drain diffusion heavily doped with the impurity of the first conductivity type cylindrically formed on the local bit line,
a first bulk diffusion lightly doped with an impurity of a second conductivity type cylindrically formed on the first drain diffusion,
a first source diffusion heavily doped with the impurity of the first conductivity type cylindrically formed on the first bulk diffusion,
a first charge retaining insulating layer formed of an insulating material to surround the first bulk diffusion, and
a first polycrystalline silicon layer formed to surround the first charge retaining layer to form the control gate of the first three-dimensional charge-retaining transistor and is extended to form a primary input line that conducts operating voltages to the control gate;
the second three-dimensional charge-retaining transistors comprises:
a second source diffusion heavily doped with the impurity of the first conductivity type cylindrically formed on the local source line,
a second bulk diffusion lightly doped with the impurity of the second conductivity type cylindrically formed on the second source diffusion,
a second drain diffusion heavily doped with the impurity of the first conductivity type cylindrically formed on the first bulk diffusion,
a second charge retaining insulating layer formed of the insulating material to surround the first bulk diffusion, and
a second polycrystalline silicon layer formed to surround the second charge retaining layer to form the control gate of the second three-dimensional charge-retaining transistor and is extended to form a inverse primary line that conducts operating voltages to the control gate; and
wherein the first drain diffusion and the second source diffusion are connected solely with a conductive layer to merge the first drain diffusion and the second source diffusion.

26. The three-dimensional NAND-based NOR nonvolatile PLD of claim 25 wherein the first and second three-dimensional charge-retaining transistors are programmed to a first threshold voltage level to represent a primary logic state and a second threshold voltage level to represent an inverse logic state wherein one of the three-dimensional charge-retaining transistors is programmed to the primary logic state and the other of the three-dimensional charge-retaining transistors is programmed to the inverse logic state.

27. The three-dimensional NAND-based NOR nonvolatile PLD of claim 26 wherein the first voltage threshold level is approximately +1.0V and second voltage threshold is approximately −2.0V.

28. The three-dimensional NAND-based NOR nonvolatile PLD of claim 26 wherein the first voltage threshold level is the programmed threshold voltage level and second voltage threshold is erased threshold voltage level.

29. The three-dimensional NAND-based NOR nonvolatile PLD of claim 28 wherein programming a selected charge-retaining transistor to the first threshold voltage level comprises the steps of:
applying a very large programming voltage level to the control gate of the selected charge retaining transistor;
applying a charge-retaining transistor activation voltage level to the control gate of an unselected three-dimensional charge-retaining transistor; and
applying a ground reference voltage level (0.0V) local bit line and local source lines of the selected charge-retaining transistors.

30. The three-dimensional NAND-based NOR nonvolatile PLD of claim 28 wherein inhibiting programming a selected charge-retaining transistor comprises the steps of:
applying a charge-retaining transistor activation voltage level to the control gates of first and second three-dimensional charge-retaining transistors; and
applying a programming inhibit voltage level to the bit lines and the source lines of the first and second charge-retaining transistors

31. The three-dimensional NAND-based NOR nonvolatile PLD of claim 30 wherein the very large programming voltage level is approximately 18.0V and the programming inhibit voltage level is approximately (9.0V).

32. The three-dimensional NAND-based NOR nonvolatile PLD of claim 30 wherein the first and second charge retaining transistors are one level polycrystalline silicon, charge-trapping, SONOS transistors.

33. The three-dimensional NAND-based NOR nonvolatile PLD of claim 28 wherein erasing the first and second charge-retaining transistors to the second threshold voltage level comprises the steps of:
applying the ground reference voltage level (0.0V) to the control gates of the first and second three-dimensional charge-retaining transistors; and
applying very large erase voltage level to the bit lines and source lines connected to the first and second three-dimensional charge-retaining transistors.

34. The three-dimensional NAND-based NOR nonvolatile PLD of claim 33 wherein inhibiting erasing of the first and second three-dimensional charge-retaining transistors comprises the steps of:
applying an erase inhibit voltage level to the control gates of the first and second three-dimensional charge-retaining transistors.

35. The three-dimensional NAND-based NOR nonvolatile PLD of claim 34 wherein the erase inhibit voltage level is approximately 9.0V and the very large erase voltage level is approximately 18.0V.

36. A three-dimensional NAND-based NOR flash nonvolatile reconfigurable switching circuit comprising:
a three-dimensional switching transistor having a source connected to a first interconnect conductor and a drain connected to a second interconnect conductor to selectively transfer a logic state signal between the first interconnect conductor and the second logic interconnect conductor; and
a switch control circuit connected to a gate of the three-dimensional switching transistor selectively activates or deactivates the three-dimensional switching transistor to determine if the first interconnect conductor is to be connected to the second interconnect conductor based on a program state of the switch control circuit.

37. The three-dimensional NAND-based NOR flash nonvolatile reconfigurable switching circuit of claim 36 wherein if the three-dimensional switching transistor is activated, the first logic value signal from the first interconnect conductor is transferred to the second interconnect conductor and if the three-dimensional switching transistor is deactivated, first the logic value signal from the first interconnect conductor is not transferred to the second interconnect conductor.

38. The three-dimensional NAND-based NOR flash nonvolatile reconfigurable switching circuit of claim 36 wherein the switch control circuit comprises:
a three-dimensional NAND-based NOR nonvolatile memory cell having a pair of serially connected three-dimensional charge-retaining transistors connected such that a drain a first charge retaining transistor of the pair of three-dimensional charge-retaining transistors is connected to a write bit line, a source of a second charge retaining transistor of the pair of three-dimensional charge-retaining transistors is connected to a write source line, and source of the first three-dimensional charge-retaining transistor and the drain of second three-dimensional charge-retaining transistor are solely connected together;
a three-dimensional select gating transistor connected between the three-dimensional NAND-based NOR flash nonvolatile reconfigurable switching circuit and the three-dimensional switching transistor for preventing damage to the three-dimensional switching transistor from a vary large erasing voltage level or a very large programming voltage level applied to the three-dimensional NAND-based NOR flash nonvolatile reconfigurable switching circuit; and
wherein a gate of the first charge retaining transistor pair of serially connected three-dimensional charge-retaining transistors is connected to a primary input line and the gate of the second charge retaining transistor pair of serially connected three-dimensional charge-retaining transistors is connected to a inverse primary input line.

39. The three-dimensional NAND-based NOR flash nonvolatile reconfigurable switching circuit of claim 38 wherein the three-dimensional select gating transistor has a drain connected to the source of the three-dimensional charge-retaining transistor and a drain of the second three-dimensional charge-retaining transistor, a source connected to a gate of the three-dimensional switching transistor, and a gate connected to a select gating terminal.

40. The three-dimensional NAND-based NOR flash nonvolatile reconfigurable switching circuit of claim 38 wherein the switching transistor and the two select gating transistor are NMOS transistors.

41. The three-dimensional. NAND-based NOR flash nonvolatile reconfigurable switching circuit of claim 36 wherein erasing the first and second pair of three-dimensional charge-retaining transistors to have a threshold voltage level of an erased threshold voltage level comprises the step of:
applying a very large erasing voltage level between the control gate and the drain of the first three-dimensional charge-retaining transistor and a source of the second three-dimensional charge-retaining transistor.

42. The three-dimensional NAND-based NOR flash nonvolatile reconfigurable switching circuit of claim 41 wherein the erased threshold voltage level is −2.0V.

43. The three-dimensional NAND-based NOR flash nonvolatile reconfigurable switching circuit of claim 41 wherein applying the very large erasing voltage level between the control gate and the drain of the first three-dimensional charge-retaining transistor and a source of the second three-dimensional charge-retaining transistor comprises applying a ground reference voltage level (0.0V) to the primary input line and inverse primary input line and a very large erasing voltage to the write bit line and the write source line and thus to the drain of the first three-dimensional charge-retaining transistor and a source of the second three-dimensional charge-retaining transistor.

44. The three-dimensional NAND-based NOR flash nonvolatile reconfigurable switching circuit of claim 43 wherein the very large negative erasing voltage level that is approximately 18.0V.

45. The three-dimensional NAND-based NOR flash nonvolatile reconfigurable switching circuit of claim 36 wherein programming one selected charge retaining transistor of the pair of three-dimensional charge-retaining transistors to have a threshold voltage level of a programmed threshold voltage level comprises:
applying a very large programming voltage level between the control gate and the drain or source of the one selected charge retaining transistor of the pair of three-dimensional charge-retaining transistors.

46. The three-dimensional NAND-based NOR flash nonvolatile reconfigurable switching circuit of claim 45 wherein the programmed threshold voltage level is approximately 0.7V with a variation of +/−0.5V for applications having voltage level of the power supply voltage source (VDD) of approximately 1.2V and is assigned to be approximately 1.0V with a variation of +/−0.5V for application having the voltage level of the power supply voltage source (VDD) of approximately 1.5V.

47. The three-dimensional NAND-based NOR flash nonvolatile reconfigurable switching circuit of claim 45 wherein applying a very large programming voltage level between the control gate and the drain or source of the one selected charge retaining transistor of the pair of three-dimensional charge-retaining transistors comprises applying a very large positive programming voltage level to the word line which is connected to the control gate of the one selected charge retaining transistor and applying a ground reference voltage level to the drains of each of the three-dimensional charge-retaining transistors pair of the three-dimensional charge-retaining transistors having the one selected charge retaining transistor.

48. The three-dimensional NAND-based NOR flash nonvolatile reconfigurable switching circuit of claim 47 wherein the very large positive programming voltage level that is from approximately +15.0V to approximately +20.0V and applying the voltage level of the ground reference voltage level to the drain lines connected to the pair of the three-dimensional charge-retaining transistors having the one selected charge retaining transistor, to a triple P-type well into which the switch control circuit is formed and to the select line and thus the gates of the first and second select gating transistors.

49. The three-dimensional NAND-based NOR flash nonvolatile reconfigurable switching circuit of claim 47 wherein programming one selected charge retaining transistor of the pair of three-dimensional charge-retaining transistors further comprises inhibiting programming of the three three-dimensional charge-retaining transistors not being programmed comprising applying an moderate programming inhibit voltage level to the primary input line or inverse primary input line which is not connected to the control gate of the one selected charge retaining transistor and applying a large programming inhibit voltage level to the drain lines not connected to the pair of three-dimensional charge-retaining transistors including the one selected charge retaining transistor.

50. The three-dimensional NAND-based NOR flash nonvolatile reconfigurable switching circuit of claim 49 wherein the moderate programming inhibit voltage level is approximately +9.0V and the large programming inhibit voltage level is approximately +18.0V.

51. The three-dimensional NAND-based NOR flash nonvolatile reconfigurable switching circuit of claim 36 wherein operating the three-dimensional NAND-based NOR flash nonvolatile reconfigurable switching circuit comprises the steps of:
applying an operate select voltage level to the first primary input line and inverse primary input line and thus to the control gates of the first and second three-dimensional charge-retaining transistors such that those of the first and second three-dimensional charge-retaining transistors that are erased will be turned on and those of the first and second three-dimensional charge-retaining transistors that are programmed will not be turned on;
applying a switching transistor activation voltage level to the write bit line;
applying a ground reference voltage level to the write source line; and
applying a select gating signal to the select gating terminal thus to the gates of the select gate transistor to turn on the select gate transistor.

52. The three-dimensional NAND-based NOR flash nonvolatile reconfigurable switching circuit of claim 51 wherein the operate select voltage level is approximately the power supply voltage level and the switching transistor activation voltage level is approximately the voltage level of the power supply voltage source plus a differential voltage level.

53. The three-dimensional NAND-based NOR flash nonvolatile reconfigurable switching circuit of claim 52 wherein the select gating signal is switching transistor activation voltage level plus a threshold voltage level of a transistor.

54. The three-dimensional NAND-based NOR flash nonvolatile reconfigurable switching circuit of claim 51 wherein if the first three-dimensional charge-retaining transistor programmed to the programmed threshold voltage level and the second three-dimensional charge-retaining transistor is erased to the erased threshold voltage level, the three-dimensional switching transistor is activated and the first interconnect conductor is connected to the second interconnect conductor.

55. The three-dimensional NAND-based NOR flash nonvolatile reconfigurable switching circuit of claim 51 wherein if the first charge retaining transistor is erased to the erased threshold voltage level and the second three-dimensional charge-retaining transistor is programmed to the programmed threshold voltage level, the three-dimensional switching transistor is deactivated and the first interconnect conductor is not connected to the second interconnect conductor.

56. A three-dimensional NAND-based NOR flash field programmable gate array (FPGA) device comprising:
a plurality of interconnect conductors for transferring selected logic value signals between one interconnect conductor and at least one other interconnect conductor; and
a plurality of reconfigurable switch node circuits arranged in rows and columns, wherein each reconfigurable switch node circuit is connected to a grouping of the interconnect conductors to connect one of the interconnect conductors to at least one other of the grouping of interconnect conductors and wherein each of the reconfigurable switch node circuits comprises:
a plurality of three-dimensional NAND-based NOR flash nonvolatile reconfigurable switching circuits, wherein each of the three-dimensional NAND-based NOR flash nonvolatile reconfigurable switching devices comprising:
a three-dimensional switching transistor having a source connected to one interconnect conductor and a drain connected to another interconnect conductor to selectively transfer a logic state signal between one interconnect conductor and another logic interconnect conductor, and
a switch control circuit connected to a gate of the three-dimensional switching transistor selectively activates or deactivates the three-dimensional switching transistor to determine if the one interconnect conductor is to be connected to the other interconnect conductor based on a program state of the switch control circuit.

57. The three-dimensional NAND-based NOR flash FPGA device of claim 56 wherein if one or more three-dimensional NAND-based NOR flash nonvolatile reconfigurable switching circuits are activated, the one logic value signal from the one interconnect conductor is transferred between the other interconnect conductor and if one or more three-dimensional NAND-based NOR flash nonvolatile reconfigurable switching circuits are deactivated, the one logic value signal from the one interconnect conductor is not transferred between the other interconnect conductor.

58. The three-dimensional NAND-based NOR flash FPGA device of claim 56 wherein the further comprising a plurality of write bit lines and source bit lines wherein each write bit line and write source line is associated with one column of reconfigurable switch node circuits and connected to one three-dimensional NAND-based NOR flash nonvolatile reconfigurable switching circuit of each reconfigurable switch node circuit on the associated column and in communication with one switch control circuit of each reconfigurable switch node circuit for transferring voltages for erasing, programming, and determining a connection state for determining if interconnect conductors connected to the one switch control circuit are to be connected.

59. The three-dimensional. NAND-based NOR flash FPGA device of claim 58 wherein the switch control circuit of each of the three-dimensional NAND-based NOR flash nonvolatile reconfigurable switching circuits comprises:
a three-dimensional NAND-based NOR nonvolatile memory cell having a pair of serially connected three-dimensional charge-retaining transistors connected such that a drain of a first charge retaining transistor of the pair of three-dimensional charge-retaining transistors is connected to a write bit line, a source of a second charge retaining transistor of the pair of three-dimensional charge-retaining transistors is connected to a write source line, and source of the first three-dimensional charge-retaining transistor and the drain of second three-dimensional charge-retaining transistor are solely connected together;
a three-dimensional select gating transistor connected between the three-dimensional NAND-based NOR flash nonvolatile reconfigurable switching circuit and the three-dimensional switching transistor for preventing damage to the three-dimensional switching transistor from a vary large erasing voltage level or a very large programming voltage level applied to the three-dimensional NAND-based NOR flash nonvolatile reconfigurable switching circuit; and
wherein a gate of the first charge retaining transistor pair of serially connected three-dimensional charge-retaining transistors is connected to a primary input line and the gate of the second charge retaining transistor pair of serially connected three-dimensional charge-retaining transistors is connected to a inverse primary input line.

60. The three-dimensional NAND-based NOR flash FPGA device of claim 59 wherein the three-dimensional select gating transistor has a drain connected to the sources of the first three-dimensional charge-retaining transistor and the drain of the second three-dimensional charge-retaining transistor, a source connected to a gate of the switching transistor, and a gate connected to a select gating terminal.

61. The three-dimensional NAND-based NOR flash FPGA device of claim 60 wherein the switching transistors and the select gating transistors are NMOS transistors.

62. The three-dimensional NAND-based NOR flash FPGA device of claim 60 wherein erasing the selected pairs of three-dimensional charge-retaining transistors to have a threshold voltage level of an erased threshold voltage level comprises the steps of:
applying the ground reference voltage level to selected primary input lines and inverse primary input lines and thus the control gate of the three-dimensional charge-retaining transistors of each of the plurality NAND-like NOR flash memory cells; and
applying a very large erasing voltage level to write bit lines and write source lines and thus to the drains of each of the selected first three-dimensional charge-retaining transistors and the sources of each of the selected second three-dimensional charge-retaining transistors.

63. The three-dimensional NAND-based NOR flash FPGA device of claim 62 wherein the erased threshold voltage level is −2.0V.

64. The three-dimensional NAND-based NOR flash FPGA device of claim 62:
wherein the very large erasing voltage level is from approximately 18.0V, and
wherein the first voltage control circuit applies the ground reference voltage level to the select gating terminals and thus the gates of the select gating transistors.

65. The three-dimensional NAND-based NOR flash FPGA device of claim 62 wherein programming one selected charge retaining transistor of the pair of three-dimensional charge-retaining transistors of each of the plurality of switch control circuits to have a threshold voltage level of a programmed threshold voltage level comprises:
applying a very large positive programming voltage level to write bit lines and write source lines and thus to the drains and sources of the selected three-dimensional charge-retaining transistors; and
applying the ground reference voltage level to the primary input line or the inverse primary input line of the one selected charge retaining transistor of the pair of three-dimensional charge-retaining transistors of each of the switch control circuits.

66. The three-dimensional NAND-based NOR flash FPGA device of claim 65 wherein the programmed threshold voltage level is greater than the voltage level of the power supply voltage source.

67. The three-dimensional NAND-based NOR flash FPGA device of claim 65:
wherein the very large positive-programming voltage level is approximately +18.0V.

68. The three-dimensional NAND-based NOR flash FPGA device of claim 67 wherein in programming one selected charge retaining transistor of the pair of three-dimensional charge-retaining transistors of each of the plurality of switch control circuits further comprises the step of inhibiting programming of the three three-dimensional charge-retaining transistors not being programmed in the pair of three-dimensional charge-retaining transistors of selected switch control circuits, wherein inhibiting programming comprises the steps of:
applying a moderate programming inhibit voltage level to the primary input lines or inverse primary input lines not connected to the control gate of the one selected charge retaining transistor of pair of three-dimensional charge-retaining transistors of the selected switch control circuits.

69. The three-dimensional NAND-based NOR flash FPGA device of claim 68 wherein the moderate programming inhibit voltage level is approximately +9V.

70. The three-dimensional NAND-based NOR flash FPGA device of claim 60 wherein operating selected three-dimensional NAND-based NOR flash nonvolatile reconfigurable switching circuits comprises the steps of:
applying an operate select voltage level to the first primary input line and inverse primary input line and thus to the control gates of the first and second three-dimensional charge-retaining transistors such that those of the first and second three-dimensional charge-retaining transistors that are erased will be turned on and those of the first and second three-dimensional charge-retaining transistors that are programmed will not be turned on;
applying a switching transistor activation voltage level to the write bit line,
applying aground reference voltage level to the write source line; and
applying a select gating signal to the select gating terminal thus to the gates of the select gate transistor to turn on the select gate transistor.

71. The three-dimensional NAND-based NOR flash FPGA device of claim 70 wherein the operate select voltage level is approximately the voltage level of the power supply voltage source.

72. The three-dimensional NAND-based NOR flash FPGA device of claim 71 wherein the switching transistor activation voltage level is the operate voltage level is the voltage level of the power supply voltage source plus a threshold voltage level of a transistor.

73. The three-dimensional NAND-based NOR flash FPGA device of claim 71 wherein the select gating signal is set to be greater than a voltage level of the power supply voltage source plus twice the threshold voltage level of a transistor.

74. The three-dimensional NAND-based NOR flash FPGA device of claim 70 wherein if the first three-dimensional charge-retaining transistor programmed to the programmed threshold voltage level and the second three-dimensional charge-retaining transistor is erased to the erased threshold voltage level, the three-dimensional switching transistor is activated and the first interconnect conductor is connected to the second interconnect conductor

75. The three-dimensional NAND-based NOR flash FPGA device of claim 70 wherein if the first charge retaining transistor is erased to the erased threshold voltage level and the second three-dimensional charge-retaining transistor is programmed to the programmed threshold voltage level, the three-dimensional switching transistor is deactivated and the first interconnect conductor is not connected to the second interconnect conductor.
